(19) United States
(12) Patent Application Publication
(10) Pub. No.: US 2014/0302636 A1
(43) Pub. Date: Oct. 9, 2014

(54) METHOD FOR PRODUCING A MULTI-BRANCHED STRUCTURE COMPOUND ENCAPSULATING AN IRIDIUM PHOSPHORESCENT COMPOUND

(71) Applicant: Konica Minolta Inc., Tokyo (JP)

(72) Inventors: Hideo TAKA, Tokyo (JP); Hiroshi KITA, Tokyo (JP)

(21) Appl. No.: 14/311,487

(22) Filed: Jun. 23, 2014

Related U.S. Application Data
(63) Continuation of application No. 10/572,660, filed on Dec. 28, 2006.

(30) Foreign Application Priority Data
Sep. 26, 2003 (JP) 2003-334909

(51) Int. Cl. H01L 51/00

(52) U.S. Cl. CPC H01L 51/0007
USPC 438/99

(57) ABSTRACT

A method to produce a multi-branched structure compound encapsulating an iridium phosphorescent compound including the following sequential steps: (i) dissolving a multi-branched structure compound and an iridium phosphorescent compound in a first solvent; (ii) adding a second solvent to encapsulate the iridium phosphorescent compound into the multi-branched structure compound; and (iii) separating and purifying the multi-branched structure compound encapsulating the iridium phosphorescent compound.

### CROSS-REFERENCE TO RELATED APPLICATIONS

This application is a continuation application of application Ser. No. 10/572,660 filed on Dec. 28, 2006, which is the United States national phase application of International application PCT/JP2004/013716 filed on Sep. 14, 2004. The entire contents of each of application Ser. No. 10/572,660 and International application PCT/JP2004/013716 are incorporated by reference herein.

### FIELD OF THE INVENTION

The present invention relates to a multi-branched structure compound as an organic electroluminescent light emission material, an organic electroluminescent element, hereinafter sometimes referred to as an organic EL element, using the multi-branched structure compound, a display and a illuminating device.

### BACKGROUND OF THE INVENTION

Hitherto, electroluminescent display (ELD) is known as alight emission type electron displaying device. As the constitutional component of the ELD, an inorganic electroluminescent element and an organic electroluminescent element are employed. The inorganic electroluminescent element is used for a flat-shaped light source; high voltage alternative electric current is necessary for driving such the light emitting element.

On the other hand, the organic electroluminescent element is an element constituted by a light emission layer containing a light emission compound provided between a cathode and an anode, in which an electron and a positive hole are injected into the light emission layer so as to form exciton by recombination of them and emits light by deactivation of the exciton (fluorescent light or phosphorescent light). Such the element is noted from the viewpoint of that the element can emit light by applying a low voltage of from several volt to several tens of volts, the element has wide viewing angle and high visibility because the element is self light emission type, and space saving and portability since the element is a thin type complete solid state element.

In the development of the organic electroluminescent element for coming practical use, an organic electroluminescent element capable of emitting high luminance light with high efficiency and having long life is demanded (cf. Patent Documents 1 through 6, for example).

Recently, an example of phosphorescent dopant for the organic electroluminescent element showing high light emission efficiency is reported, which has an oligophenylene moiety having a substituent group for raising the light emission efficiency by inhibiting concentration quenching caused by nearing the light emission substances with together (cf. Non-patent Document 3, for example). It is supposed that the concentration quenching caused by nearing the phosphorescent dopant is inhibited by preventing the nearing among the dopant by introducing a bulky substituent into the phosphorescent dopant.

Moreover, a light emission compound so called a dendrimer in which the substituent is multi-branched to form a tree-like structure having a substituent is recently beginning to be proposed for inhibiting the concentration quenching (cf. Non-patent Documents 1 through 3, for example).
[Patent Document 1] Japanese Patent Publication Open to Public Inspection (hereafter referred to as JP-A) No. 2001-181616
[Patent Document 2] JP-A No. 2001-247859
[Patent Document 3] JP-A No. 2002-83684
[Patent Document 4] JP-A No. 2002-175884
[Patent Document 5] JP-A No. 2002-338588
[Patent Document 6] JP-A No. 2003-7469
[Non-patent Document 1]
Applied Physics Letters, 80, p. 2645
[Non-patent Document 2]
IDW02 Preprints p. 1124
[Non-patent Document 3] Preprints for 50^{th} Lecture

Meeting of Applied Physics

The molecular structure of conventional dendrimer type light emission compound is restricted because the structure of the substituent of the light emission compound is made up to branched tree-like structure, and the light emission compounds include a compound in which any branched tree-like structured substituent cannot be formed.

Moreover, in the case of a full color organic electroluminescent element, the light mission compounds having the branched tree-like structured substituent should be individually synthesized for each of the colors. In such the case, considerable troubles are necessary for synthesizing each of the light emitting compounds and the cost is increased accompanied with such the synthesizing troubles.

The present invention is attained on such the background, and an object of the invention is to provide an organic electroluminescent element which can be easily produced and has high light emitting efficiency and long life, an organic electroluminescent element containing a multi-branched structure compound, a display or a lightening apparatus employing such the element and a method for producing the multi-branched structure compound.

### SUMMARY OF THE INVENTION

The object of the present invention is attained by the following structures.

(1) A multi-branched structure compound encapsulating a light emitting material for an organic electroluminescent element.

(2) The multi-branched structure compound of Item (1) having a substructure which exhibits an positive hole transporting property.

(3) The multi-branched structure compound of Item (1) or (2) having a substructure which exhibits an electron transporting property.

(4) The multi-branched structure compound of any one of Items (1) to (3), wherein the light emitting material for the organic electroluminescent element is a fluorescent compound.

(5) The multi-branched structure compound of any one of Items (1) to (3), wherein the light emitting material for the organic electroluminescent element is a phosphorescent compound.

(6) An organic electroluminescent element comprising at least one organic compound layer between an anode and a cathode, wherein

at least one of the organic compound layer comprises the multi-branched structure compound of any one of Items (1) to (5).

(7) The organic electroluminescent element of Item (6) emitting white light.

(8) A display comprising the organic electroluminescent element of Item (6) or (7).

(9) An illuminating device comprising the organic electroluminescent element of Item (6) or (7).

(10) A display comprising the illuminating device of Item (9) and a liquid crystal element as a display member.

(11) A method to produce a multi-branched structure compound comprising the step of:

mixing a light emitting material for an organic electroluminescent element and the multi-branched structure compound in a solvent to encapsulate the light emitting material for an organic electroluminescent element in the a multi-branched structure compound.

(12) The method of Item (11), wherein

the light emitting material for the organic electroluminescent element has a higher affinity to the multi-branched structure compound than to the solvent.

(13) The method of Item (11) or (12), wherein

the multi-branched structure compound has a substructure which exhibits an positive hole transporting property.

(14) The method of any one of Items (11) to (13), wherein

the multi-branched structure compound has a substructure which exhibits an electron transporting property.

(15) The method of any one of Items (11) to (14), wherein

the light emitting material for the organic electroluminescent element is a fluorescent compound.

(16) The method of any one of Items (11) to (15), wherein

the light emitting material for the organic electroluminescent element is a phosphorescent compound.

### BRIEF DESCRIPTION OF THE DRAWINGS

FIG. 1 is a schematic illustration of an example of a display employing an organic EL element of the present invention.

FIG. 2 is a schematic illustration of a display section.

FIG. 3 is a schematic illustration of pixels.

FIG. 4 is a schematic illustration of a passive matrix full color display.

FIG. 5 is a schematic illustration of an illuminator.

FIG. 6 is a cross-sectional view of an illuminator.

### DESCRIPTION OF THE PREFERRED EMBODIMENTS

The invention is described in detail below.

It has been found in the present investigation by the inventors that the organic electroluminescent element having high light emitting efficiency and long life can be produced by encapsulating an organic luminescence material in a multi-branched compound.

In the invention, the close contact of the light emission materials is inhibited so as to be in a substantially dispersed state by encapsulating an organic electroluminescent material in a multi-branched structure compound. Therefore, the concentration quenching can be inhibited so as to improve the efficiency and the life of light emission.

The above-described effects can be obtained by a very simplified method in which the organic electroluminescent light emission material is only encapsulated into the multi-branched structure compound. Consequently, time and cost for synthesizing the organic electroluminescent light emission material having the multi-branched tree-like structure substituent can be reduced. Specifically, in the case of using plural organic electroluminescent light emission materials such as a full color display or illuminating device, the time for production and the cost can be considerably reduced by the use of the multi-branched structure compound encapsulating the electroluminescent light emission material.

The multi-branched structure compound for encapsulating the organic electroluminescent light emission material is a compound in which a three dimensionally extended structure is formed by bonding multi-branched structural bodies on a core bonding group as the central core, different from a straight-chain type polymer extended in one dimensional direction and a pendant (graft) type polymer partially having a branched structure.

The core bonding group is a bonding group to be the central core, which has 2 to 6 bonding arms. The multi-branched structural substance is formed by bonding branched structural units each having three or four bonding arms. The branched structural units forming the multi-branched structural substance may be entirely the same or different in each of the generations.

The core bonding group may be the same as the branched structural unit.

In the branched structural substance, when the branched structural units directly bonded with the core group are referred to as the first generation and the branched structural units each bonded to the first generation branched structural units are referred to as the second generation, the multi-branched structural units of the multi-branched structure compound of the invention is preferably constituted at least by two generations of the structural units, more preferably constituted by from two to ten generations of the repeating units. It is specifically preferable that the compound is constituted by two to five generations of the repeating units. By the use of such the multi-branched structure compound, the organic electroluminescent light emission material can be easily encapsulated, the concentration quenching inhibiting effect can be enhanced and the light emitting efficiency and the life time can be improved.

The multi-branched structure compound for encapsulating the organic electroluminescent light emission material according to the invention preferably has a substructure exhibiting a positive hole transport ability. By the use of the multi-branched structure compound having such the structure, transfer of positive holes to the encapsulated light emission material for the organic electroluminescent element is carried out efficiently and the light emitting efficiency can be further improved.

A substructure having a positive hole transport property represents a substructure which has a function to convey positive holes. In a broad sense, a substructure exhibiting a hole injection property or an electron blocking property is also included in the substructure exhibiting a hole transport property. The substructure exhibiting a hole transport property is not specifically limited in the present invention, and usable is a substructure of a known material which has been commonly used for a hole injection-transport material, or a material used in a hole injection layer or in a hole transport layer of EL elements.

A substructure exhibiting a hole transport property represents a substructure having a function of injection or transportation of holes, or a function of electron blocking, and may be an organic compound or an inorganic compound. Examples of a substructure include: a triazole derivative, an oxydiazole derivative, an imidazole derivative, a polyarylalkane derivative, a pyrazoline derivative, a pyrazolone derivative, a phenylenediamine derivative, an arylamine derivative, an amino substituted chalcone derivative, an oxazole derivative, a styrylanthracene derivative, a fluorenone derivative, a hydrazone derivative, a stilbene derivative, a silazane derivative and an aniline-containing copolymer. More preferable is a substructure of a triarylamine derivative or a carbazole derivative.

A phenyl group may be cited as a typical example of an aryl group which forms a triarylamine derivative, however, other examples include aromatic hydrocarbon residues such as a naphthyl group, an anthryl group, an azulenyl group, and a fluorenyl group; hetero aromatic residues such as a furyl group, a thienyl group, a pyridyl group and an imidazolyl group, which may form a condensed hetero aromatic residue via condensation with another aromatic ring. Examples of a preferable aryl group which form the triarylamine portion includes: a phenyl group, a naphthyl group, a fluorenyl group and a thienyl group.

In the present invention, as a specifically preferable substructure exhibiting a hole transport property, a carbazole derivative is cited, and most preferably cited is a substructure represented by Formula (1) or Formula (2) which will be shown below, whereby a further higher emission efficiency is obtained.

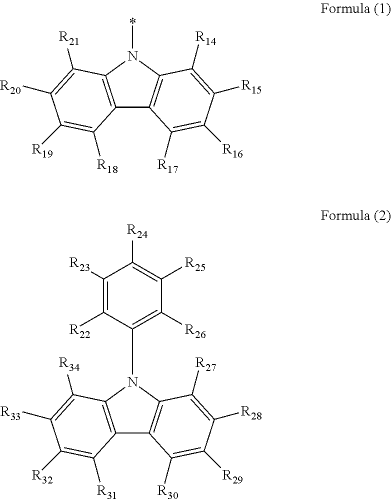

In above mentioned Formula (1), R14-R21 each independently represent a hydrogen atom, an alkyl group or a cycloalkyl group, provided that adjacent groups of R14-R21 may be joined to form a ring.

In above mentioned Formula (2), R22-R30 each independently represent a hydrogen atom, an alkyl group or a cycloalkyl group, and R31-R34 each independently represent a hydrogen atom, a single bond, an alkyl group or a cycloalkyl group, provided that one of R31-R34 represents a single bond, and that adjacent groups of R22-R34 may be joined to form a ring.

Examples of a substructure having a hole transport function are shown below (one portion of each of these substructures serves as a bond), however the aspects of the present invention are not limited thereto.

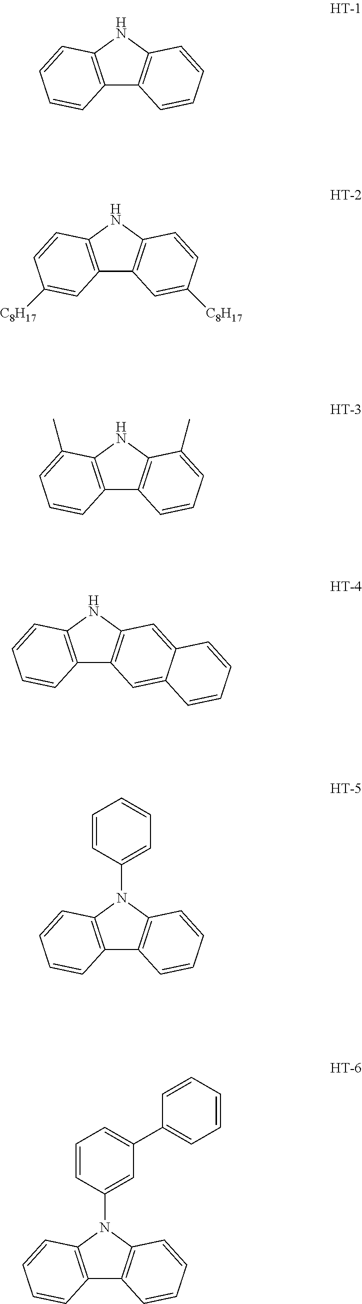

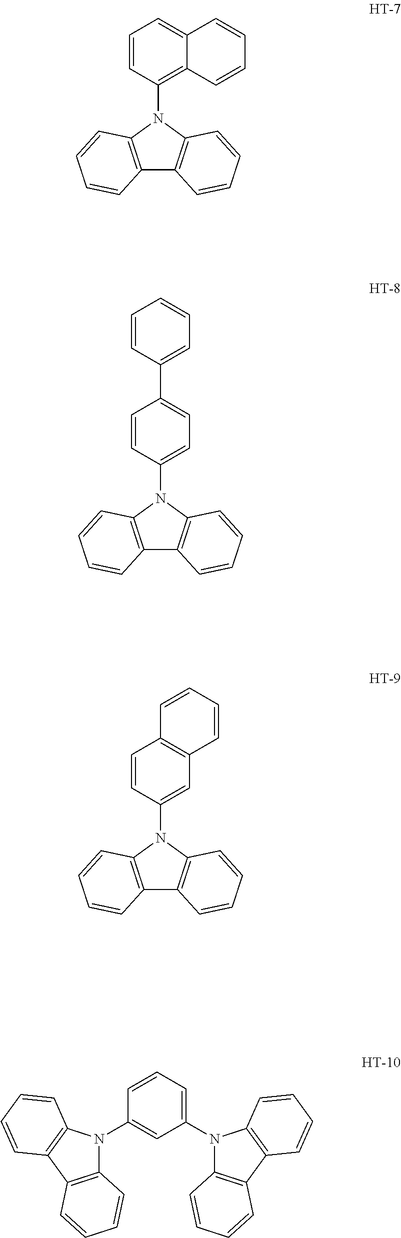 [SMILES: c1ccc2c(-n3c4ccccc4c4ccccc43)cccc2c1 ; c1ccc(-c2ccc(-n3c4ccccc4c4ccccc43)cc2)cc1 ; c1ccc2cc(-n3c4ccccc4c4ccccc43)ccc2c1 ; c1cc(-n2c3ccccc3c3ccccc32)cc(-n2c3ccccc3c3ccccc32)c1]

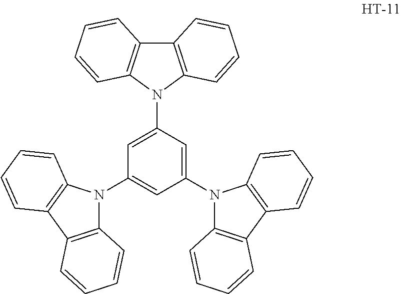 [SMILES: c1ccc2c(c1)c1ccccc1n2-c1cc(-n2c3ccccc3c3ccccc32)cc(-n2c3ccccc3c3ccccc32)c1]

The multi-branched structure compound for encapsulating the organic electroluminescent light emission material according to the invention preferably has a substructure exhibiting an electron transport ability. By the use of the multi-branched structure compound having such the structure, transfer of electrons to the encapsulated light emission material for the organic electroluminescent element is carried out efficiently and the light emitting efficiency can be further improved.

A substructure having an electron transport ability represents a substructure having a function to transport electrons. In a broad sense, a substructure having an electron injecting ability or a positive hole blocking ability is also included in the substructure having an electron transport ability. A substructure having an electron transport ability is usable when it has a function to convey electrons injected from the cathode to the emission layer, and the substructure of a compound which has been commonly used for an electron transport layer is employable.

Examples of a substructure having an electron transport ability include substructures of, for example: a triarylborane derivative, a fluorine-substituted triarylamine derivative, a silole derivative, an azacarbazole derivative, a phenanthroline derivative, a styryl derivative, nitro-substituted fluorene derivative, a diphenylquinone derivative, a thiopyran dioxide derivative, carbodiimide, fluolenylidenemethane derivative, an anthraquinodimethane derivative, an anthron derivative and an oxydiazole derivative. Also, usable as a substructure having a electron transport ability include, for example: a substructure of a thiadiazole derivative obtained by replacing an oxygen atom of the oxydiazole ring of an oxydiazole derivative with a sulfur atom; and a substructure of a quinoxaline derivative which has a quinoxaline ring known as an electron withdrawing group.

Further, examples of a substructure having an electron transport ability include substructures of metal complexes of 8-quinolinol derivative, for example, tris(8-quinolinol)aluminum (Alq), tris(5,7-dichloro-8-quinolinol) aluminum, tris(5,7-dibromo-8-quinolinol)aluminum, tris(2-methyl-8-quinolinol)aluminum, tris(5-methyl-8-quinolinol)aluminum and bis(8-quinolinol)zinc (Znq); and metal complexes in which the central metal atom of the above metal complexes is replaced with, for example, In, Mg, Cu, Ca, Sn, Ga, or Pb. In addition, examples of a substructure having an electron transport ability include substructures of, for example: metal free phthalocyanine, metal phthalocyanine, or those phthalocyanines of which ends are substituted with an alkyl group or an sulfonic acid group.

Preferable examples include: substructures of a triarylborane derivative or a heteroaromatic ring containing nitrogen. As a heteroaromatic ring containing nitrogen, more preferable are those having two or more hetero atoms, of which examples include: a pyrazine ring, a pyrimidine ring, a phenanthroline ring, a pyridoindole ring, a dipyridopyrrole ring, a diazafluorene ring, a phenathiazin ring, a thiazole ring, and condensed aromatic residues in which the above mentioned rings are further condensed with other aromatic rings; and hydrocarbon residues replaced with an electron withdrawing group (for example, a pentafluorophenyl group and 2,4,6-tricyanophenyl group). Specifically preferable are, for example, a pentafluorophenyl group, a triarylborane residue, a pyridoindole ring, a thiazole ring and a condensed aromitic residue having a substructure of one of the above groups. Thereby higher luminous efficiency is attained.

A phenyl group may be cited as a typical example of an aryl group which forms a triaryborane derivative, however, other examples include aromatic hydrocarbon residues such as a naphthyl group, an anthryl group, an azulenyl group, and a fluorenyl group; and hetero aromatic residues such as a furyl group, a thienyl group, a pyridyl group and an imidazolyl group, each of which may form a condensed hetero aromatic residue via condensation with another aromatic ring.

The triarylborane derivative tends to be unstable because of the electron deficiency in nature, and the atom in the aryl group adjacent to the atom which is directly bonded to the boron atom is often introduced with a substituent for stabilization, example of which include: trimesitylborane in which a methyl group is introduced into the benzene ring combined with the boron atom, and tris(diisopropyl)borane introduced with an isopropyl group. When a triarylborane structure is contained as a ligand, the aryl group bonded to the boron atom is preferably introduced with a substituent at the atom adjacent to the atom directly bonded to the boron atom. Examples of the substituent include: a methyl group, a fluoromethyl group, a trifluoromethyl group and an isopropyl group.

Examples of a substructure having an electron transport function will be shown below (one part of each substructure serves as a bond), however the aspects of the present invention are not limited thereto.

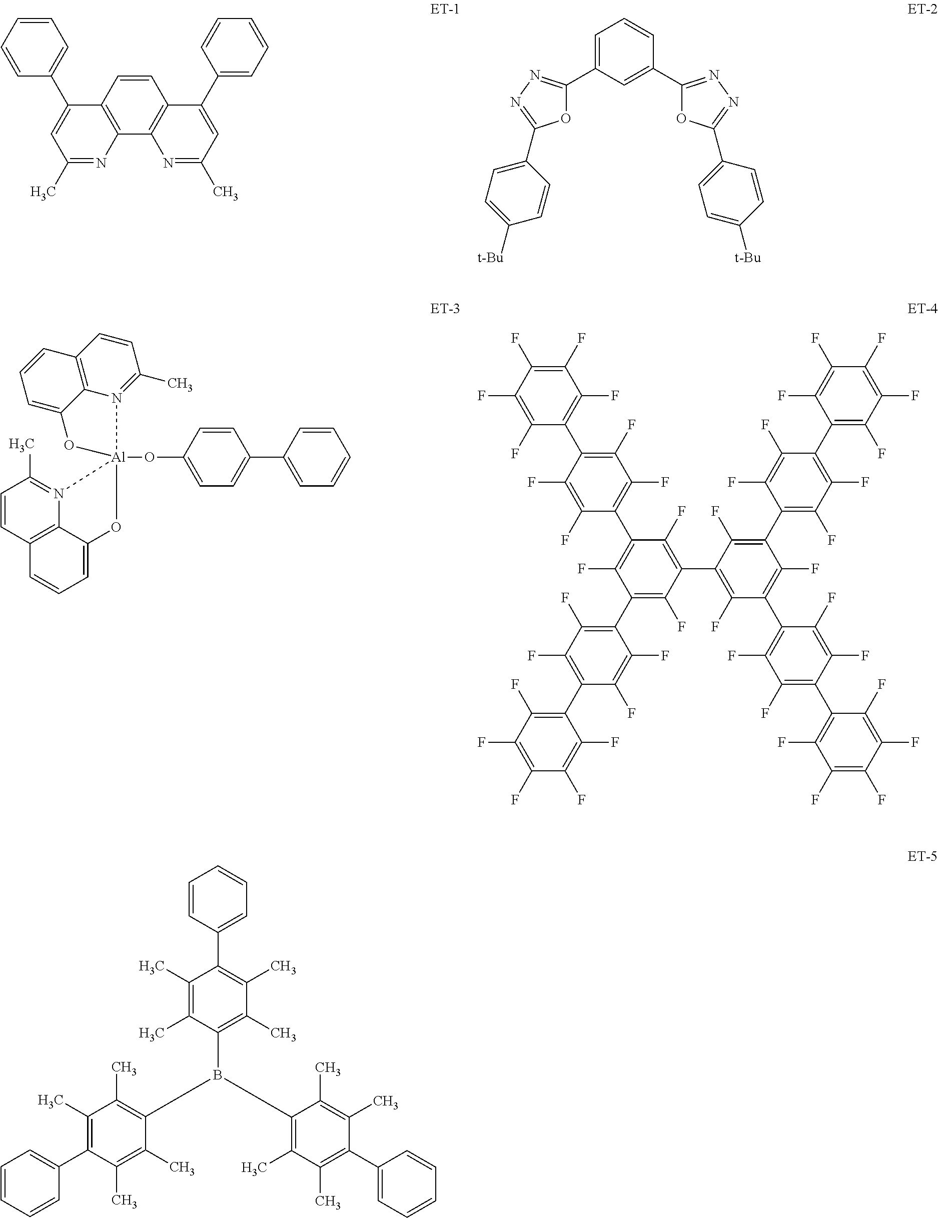

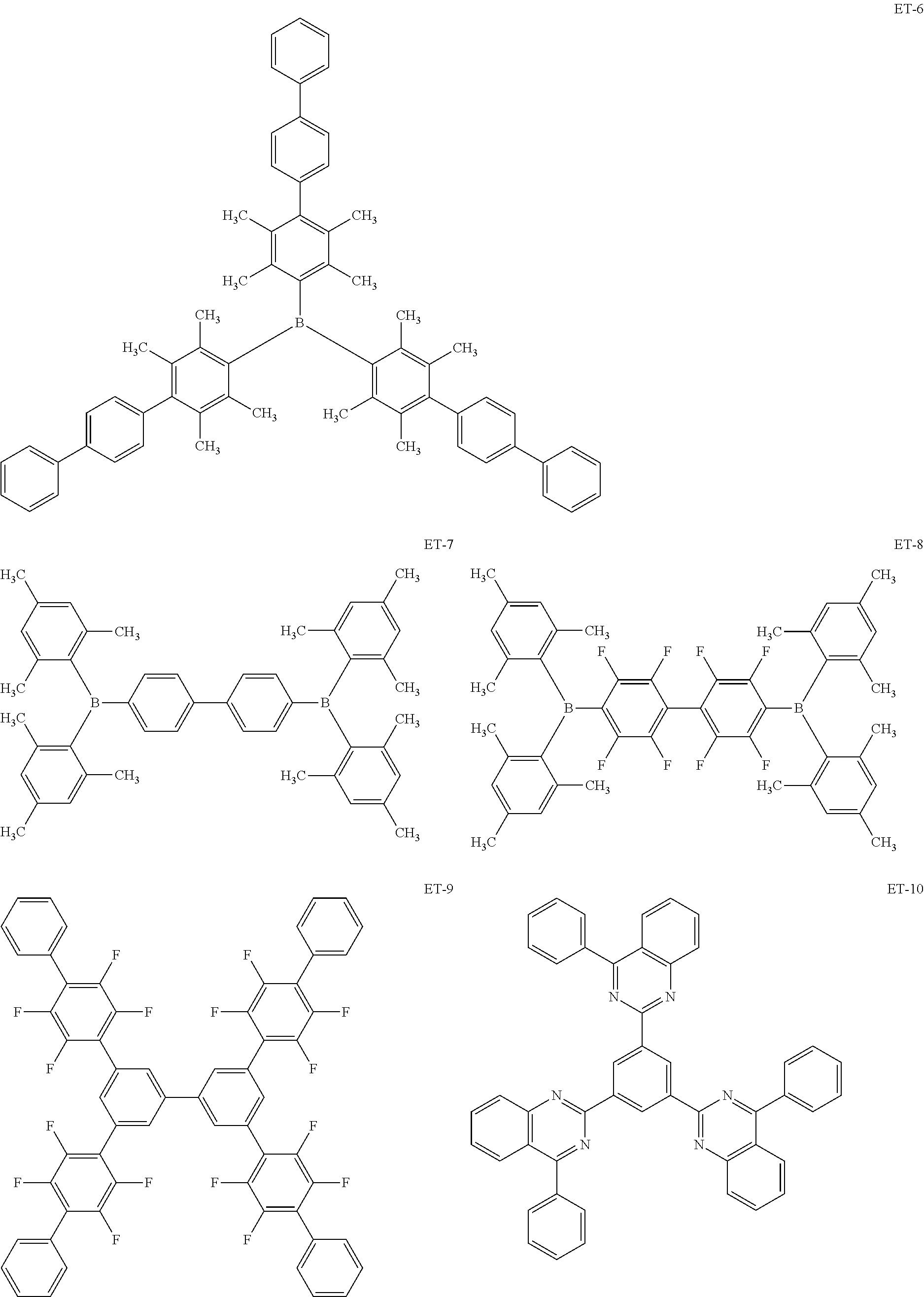

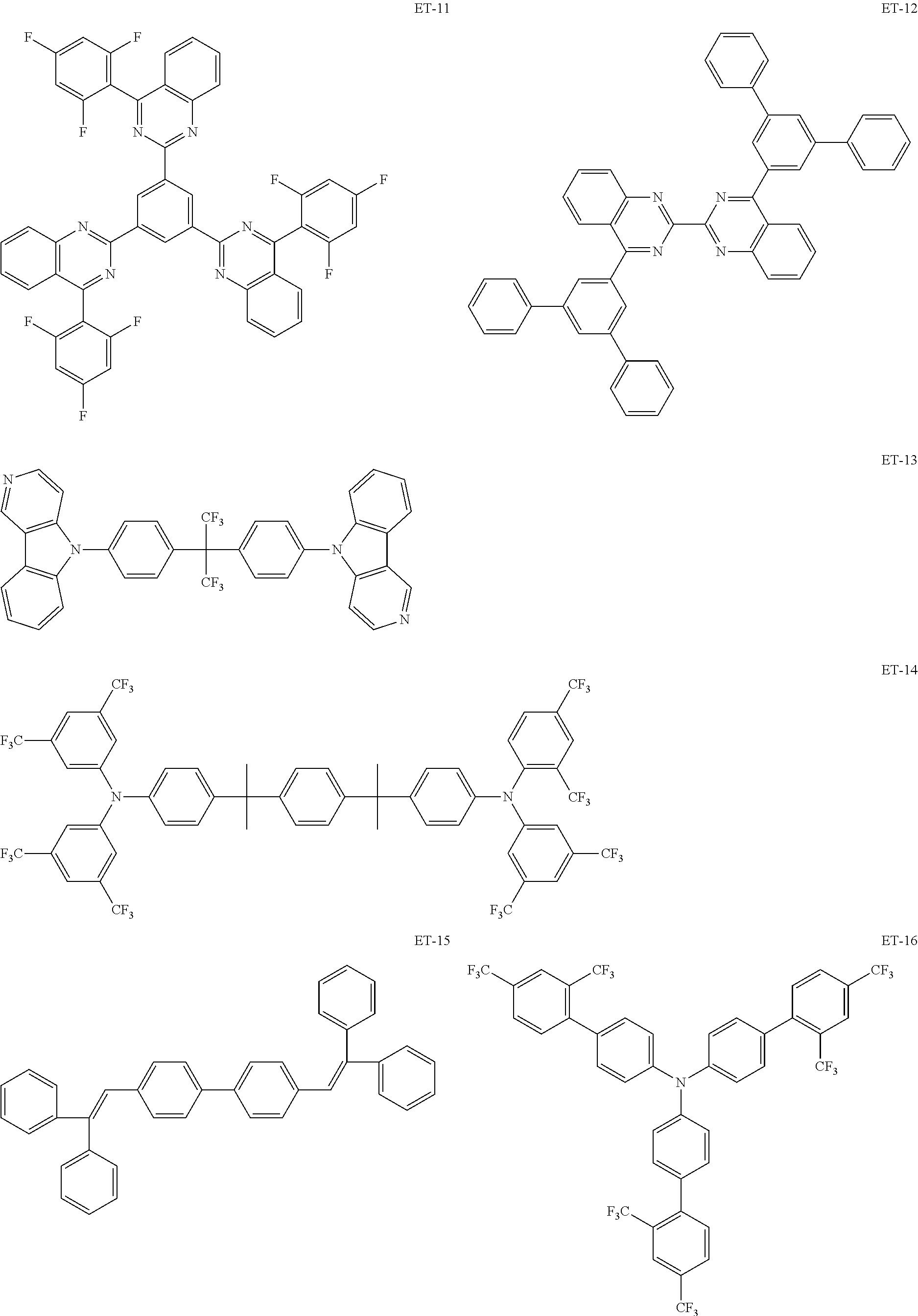

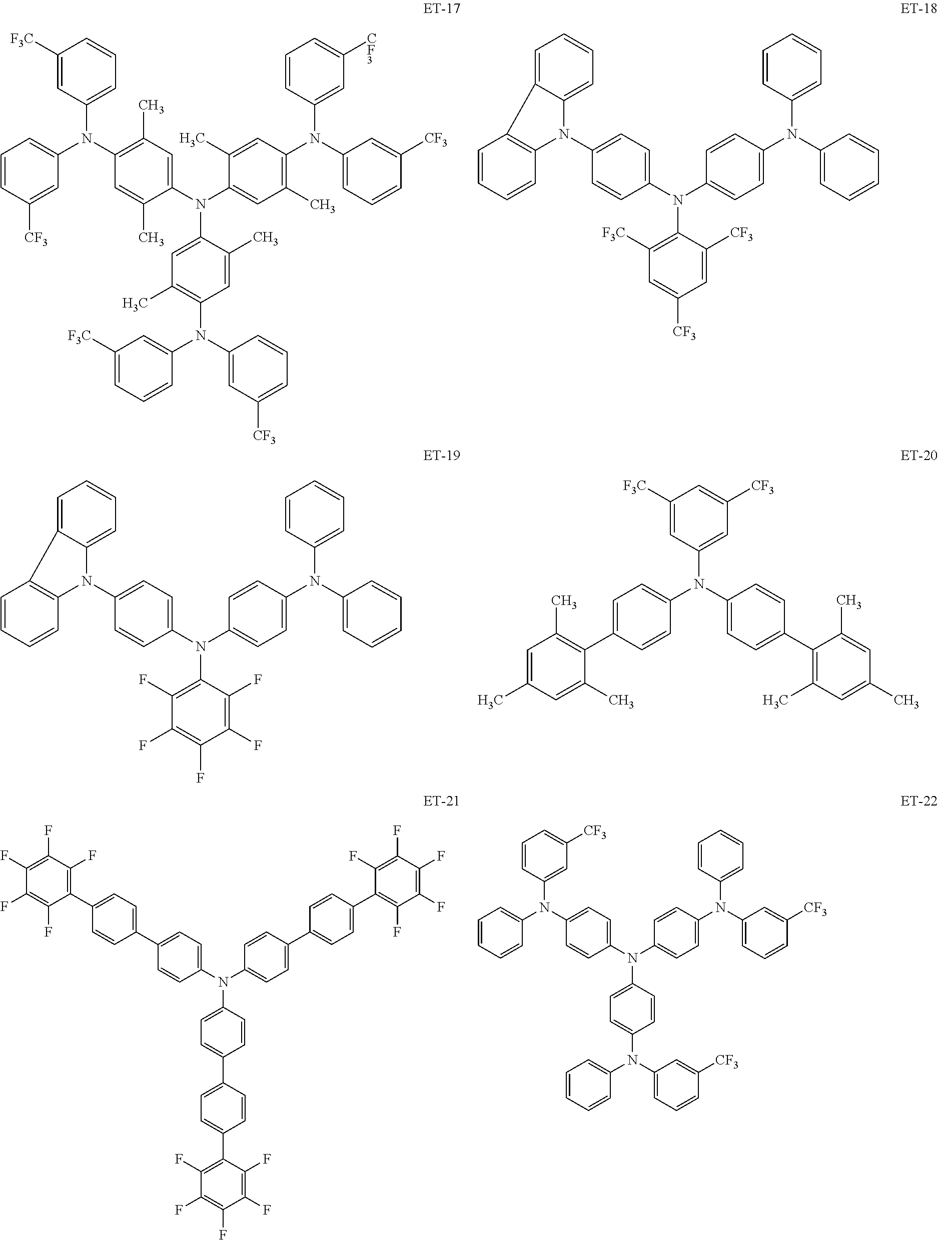

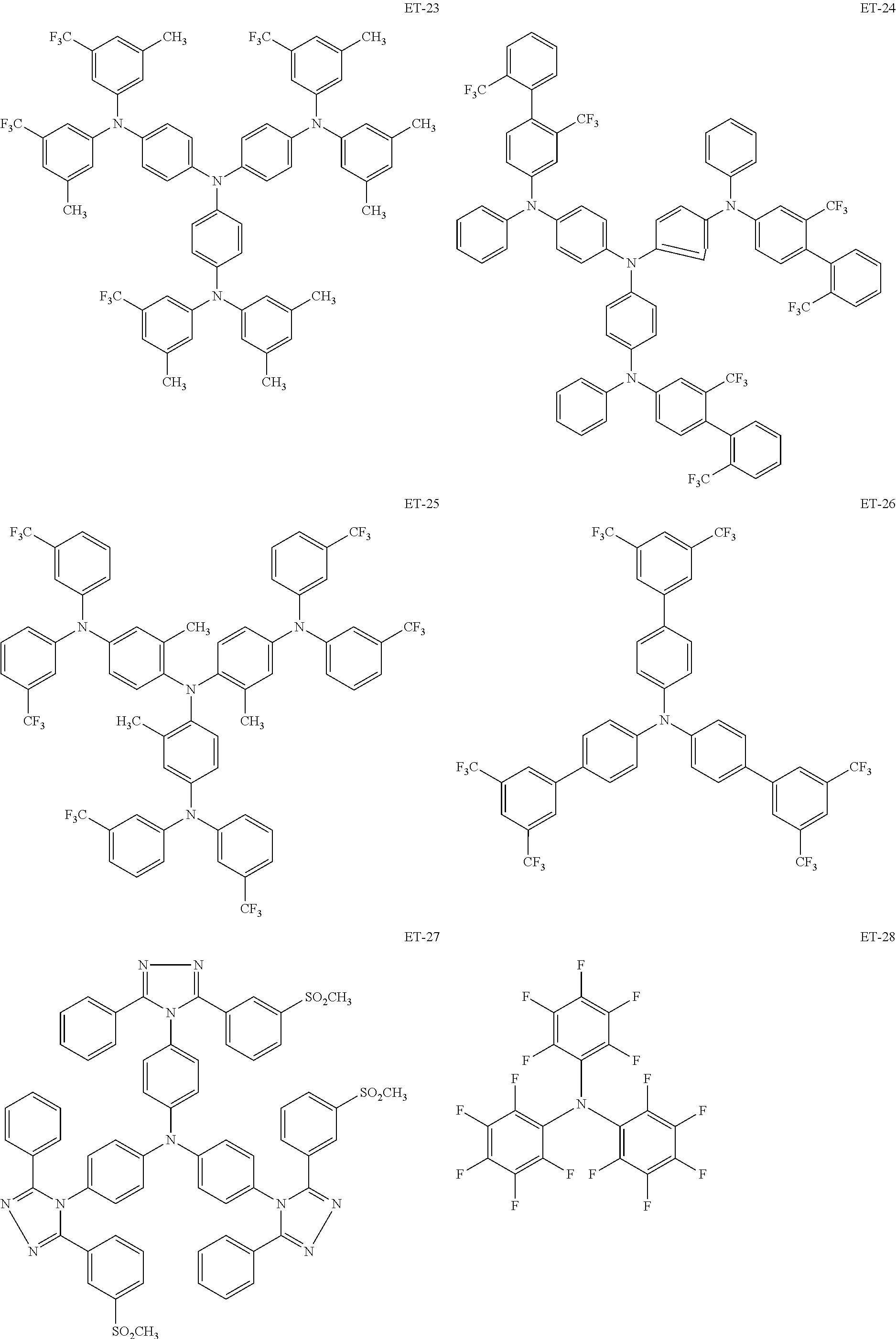

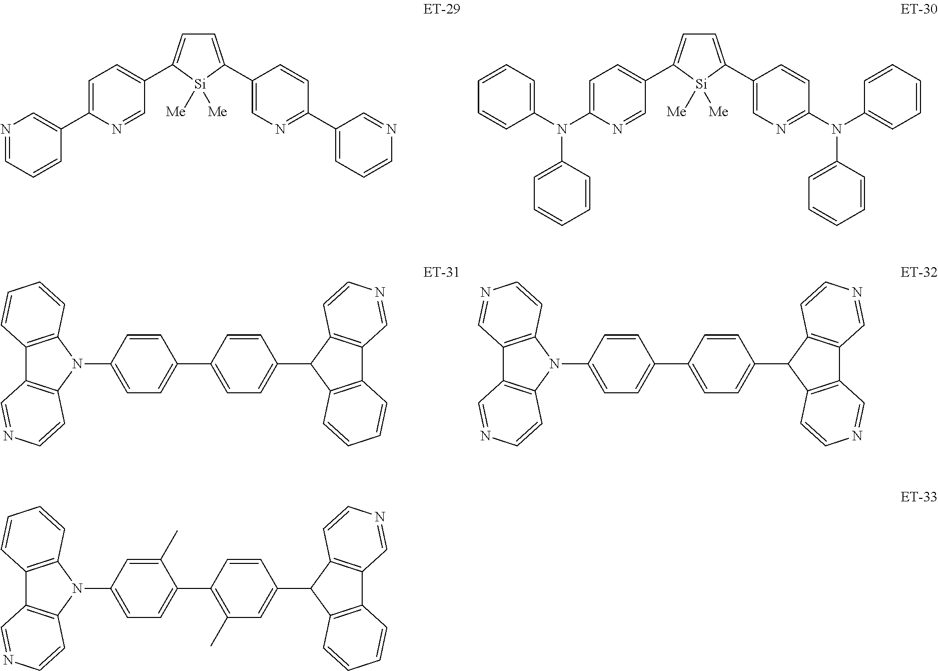 [SMILES: C[Si]1(C)C(c2ccc(-c3cccnc3)nc2)=CC=C1c1ccc(-c2cccnc2)nc1 ; C[Si]1(C)C(c2ccc(N(c3ccccc3)c3ccccc3)nc2)=CC=C1c1ccc(N(c2ccccc2)c2ccccc2)nc1 ; c1ccc2c(c1)-c1cnccc1C2c1ccc(-c2ccc(-n3c4ccccc4c4cnccc43)cc2)cc1 ; c1cc2c(cn1)-c1cnccc1C2c1ccc(-c2ccc(-n3c4ccncc4c4cnccc43)cc2)cc1 ; Cc1cc(C2c3ccccc3-c3cnccc32)ccc1-c1ccc(-n2c3ccccc3c3cnccc32)cc1C]

Examples of a core linkage group will be shown below, however, the aspects of the present invention is not limited thereto.

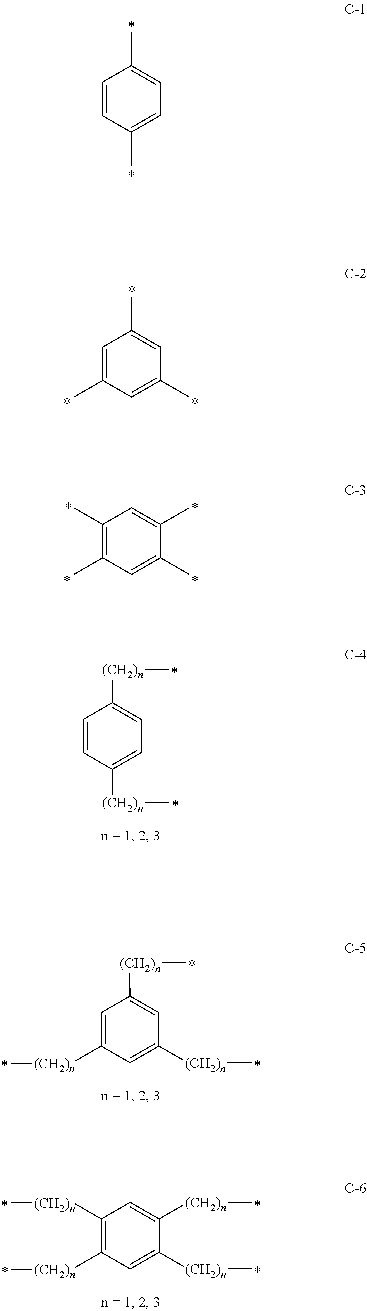

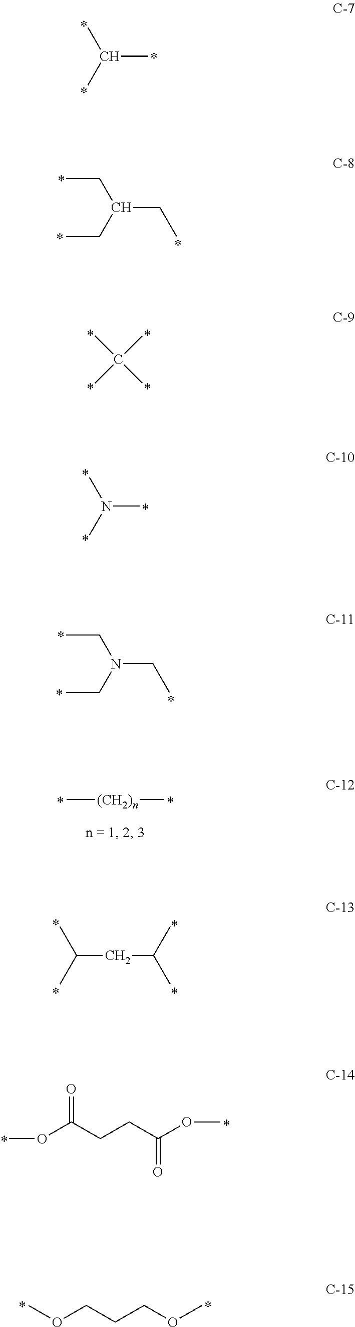

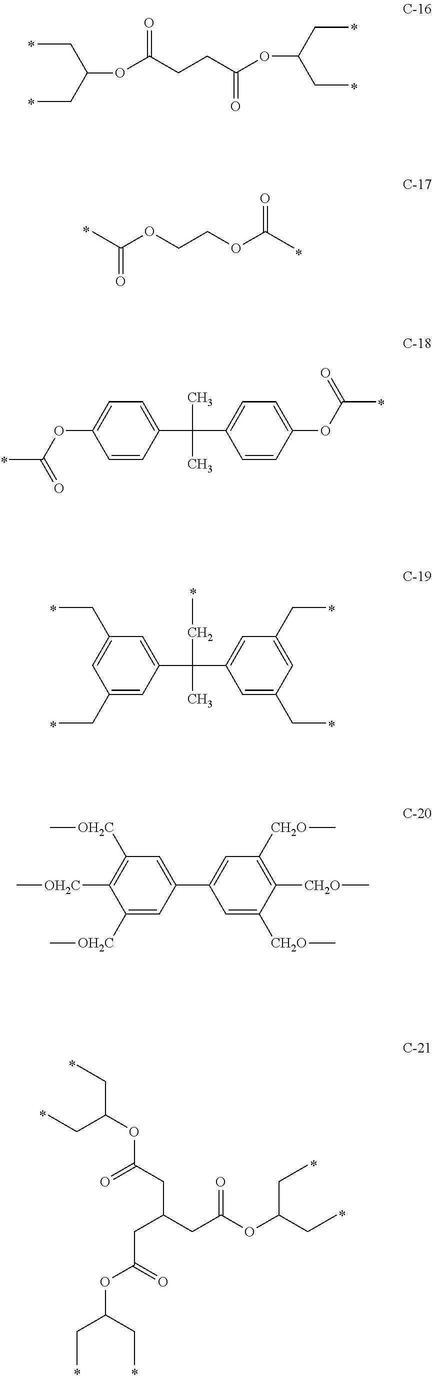

Examples of a multi-branched structure compound will be shown below, however, the aspects of the present invention is not limited thereto.

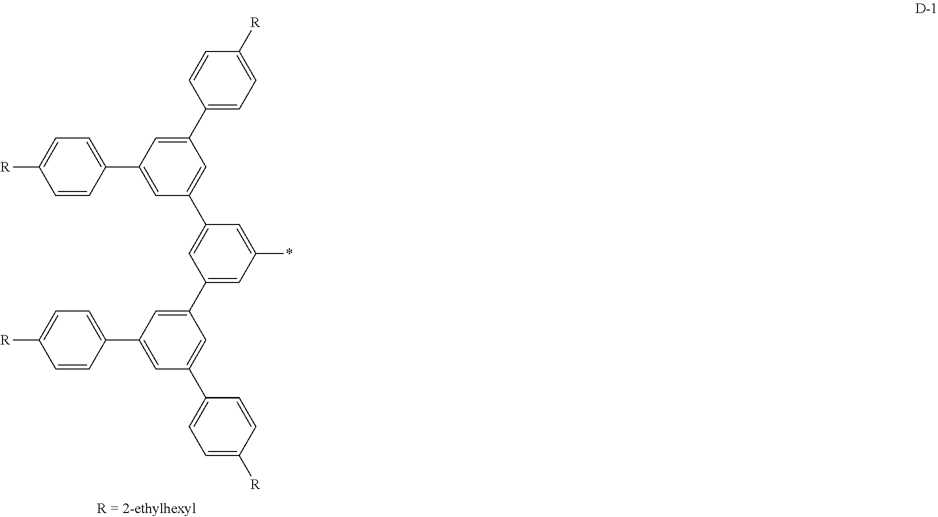

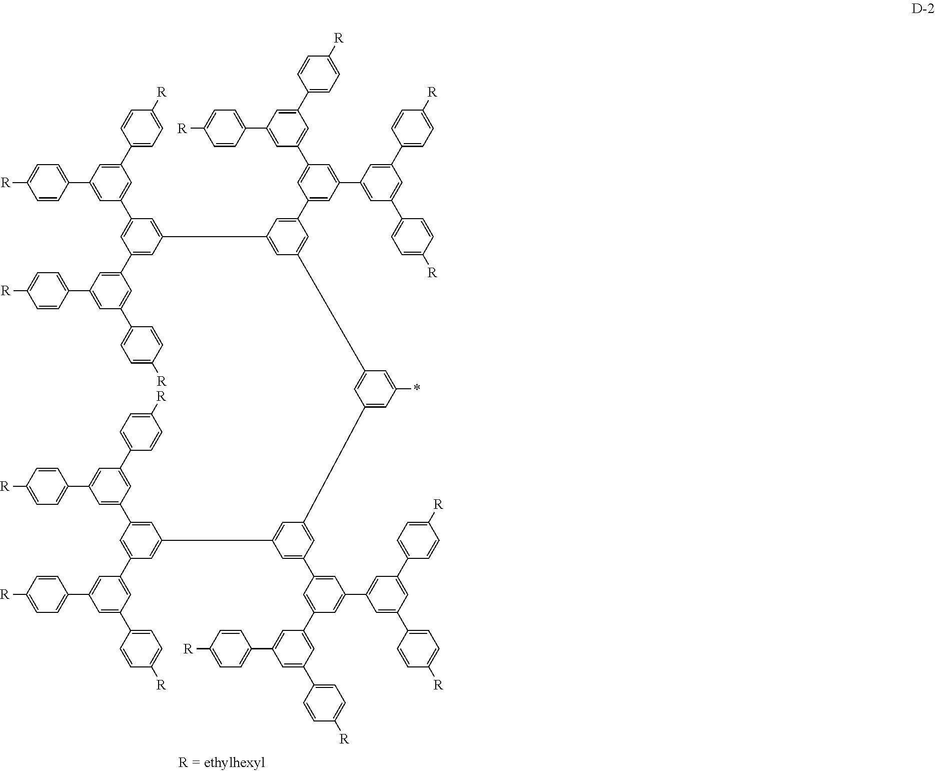

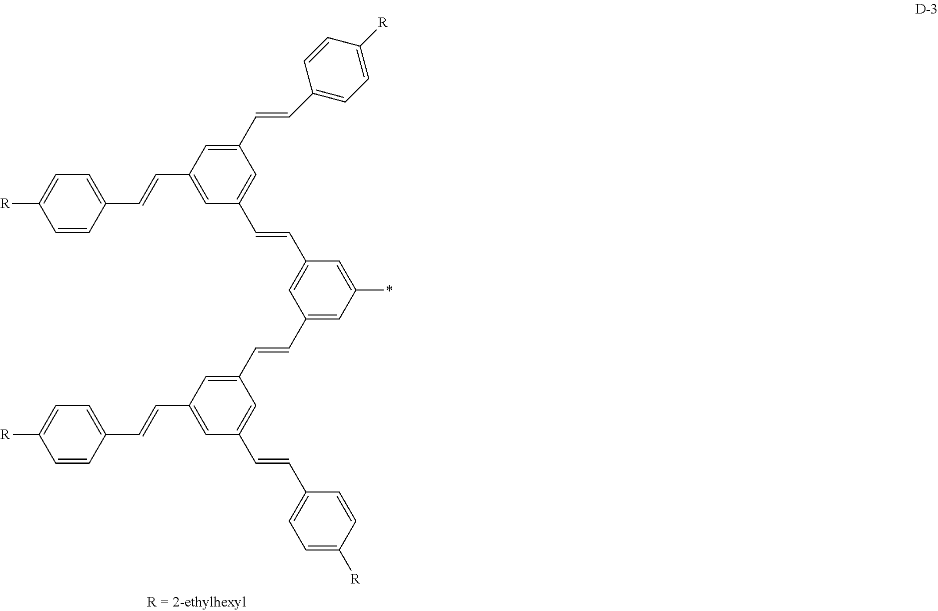

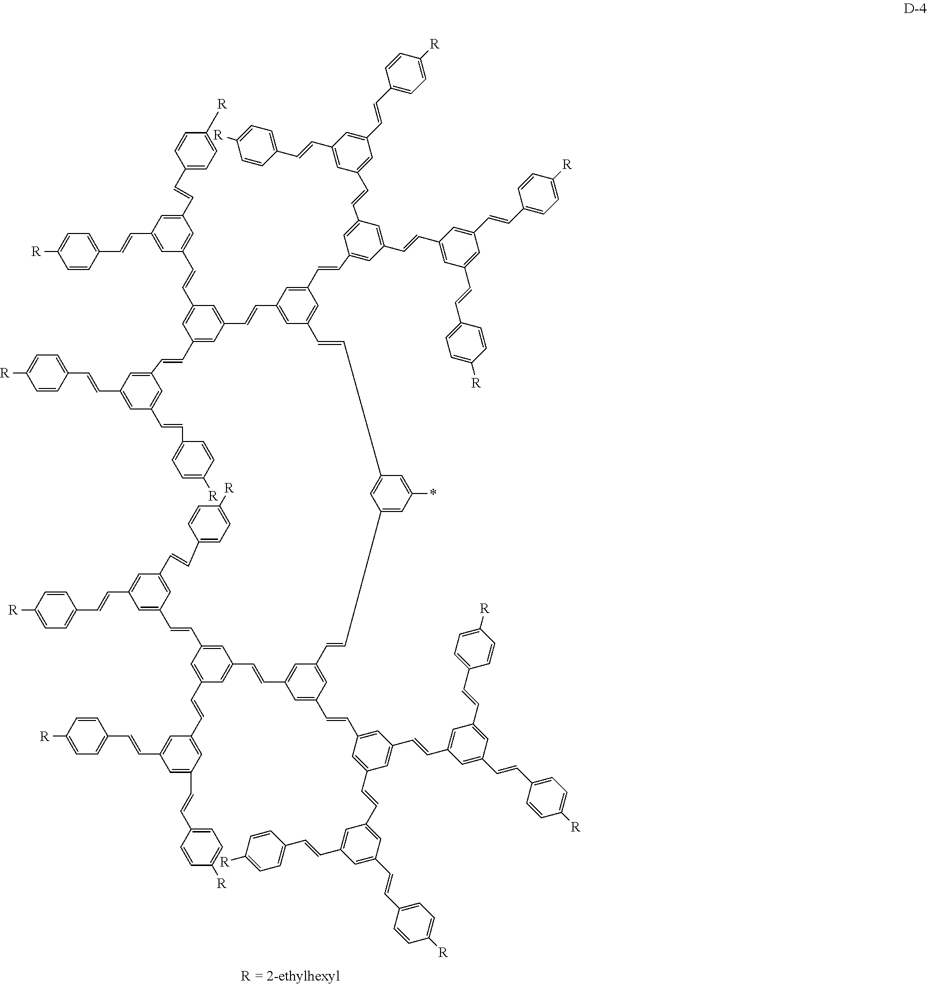

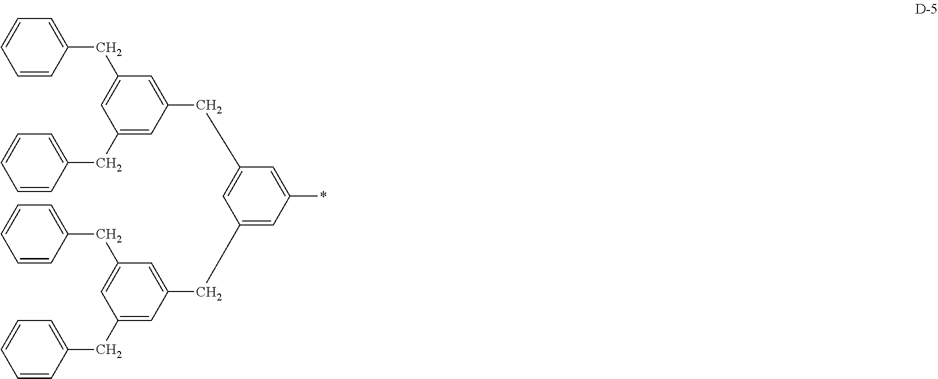 [SMILES: *c1cc(Cc2cc(Cc3ccccc3)cc(Cc3ccccc3)c2)cc(Cc2cc(Cc3ccccc3)cc(Cc3ccccc3)c2)c1]

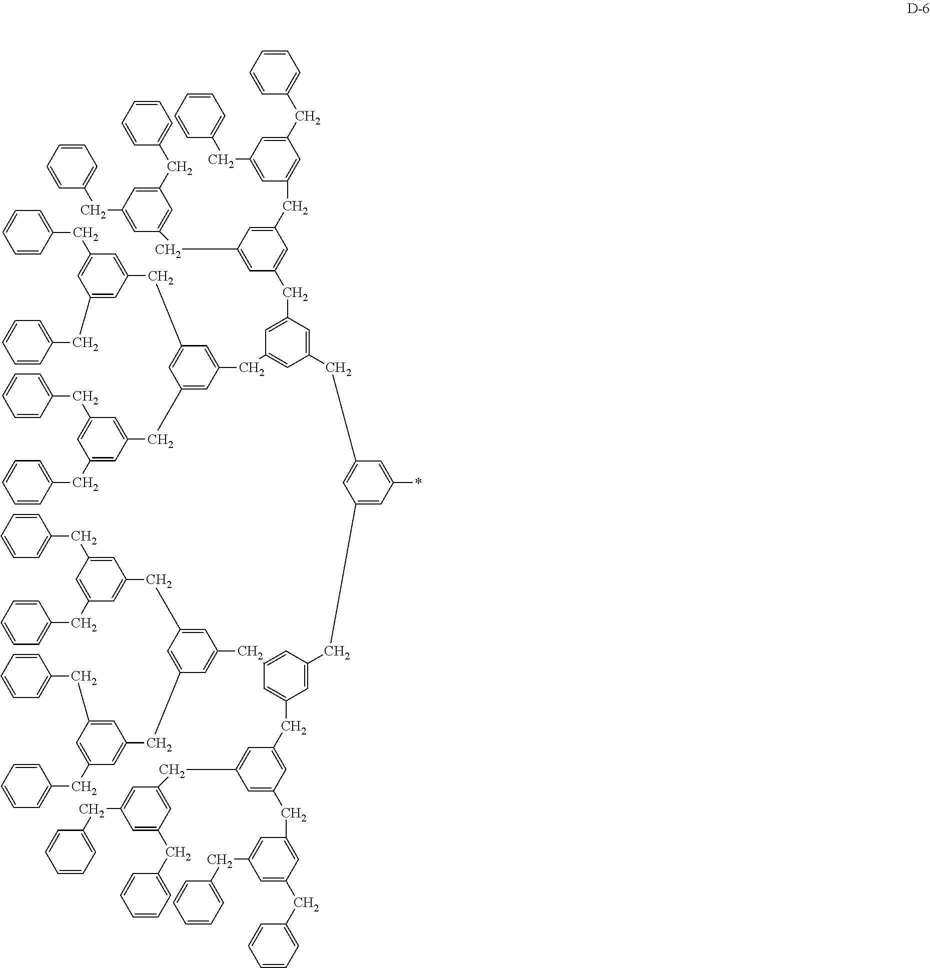 [SMILES: *c1cc(Cc2cc(Cc3cc(Cc4cc(Cc5ccccc5)cc(Cc5ccccc5)c4)cc(Cc4cc(Cc5ccccc5)cc(Cc5ccccc5)c4)c3)cc(Cc3cc(Cc4cc(Cc5ccccc5)cc(Cc5ccccc5)c4)cc(Cc4cc(Cc5ccccc5)cc(Cc5ccccc5)c4)c3)c2)cc(Cc2cc(Cc3cc(Cc4cc(Cc5ccccc5)cc(Cc5ccccc5)c4)cc(Cc4cc(Cc5ccccc5)cc(Cc5ccccc5)c4)c3)cc(Cc3cc(Cc4cc(Cc5ccccc5)cc(Cc5ccccc5)c4)cc(Cc4cc(Cc5ccccc5)cc(Cc5ccccc5)c4)c3)c2)c1]

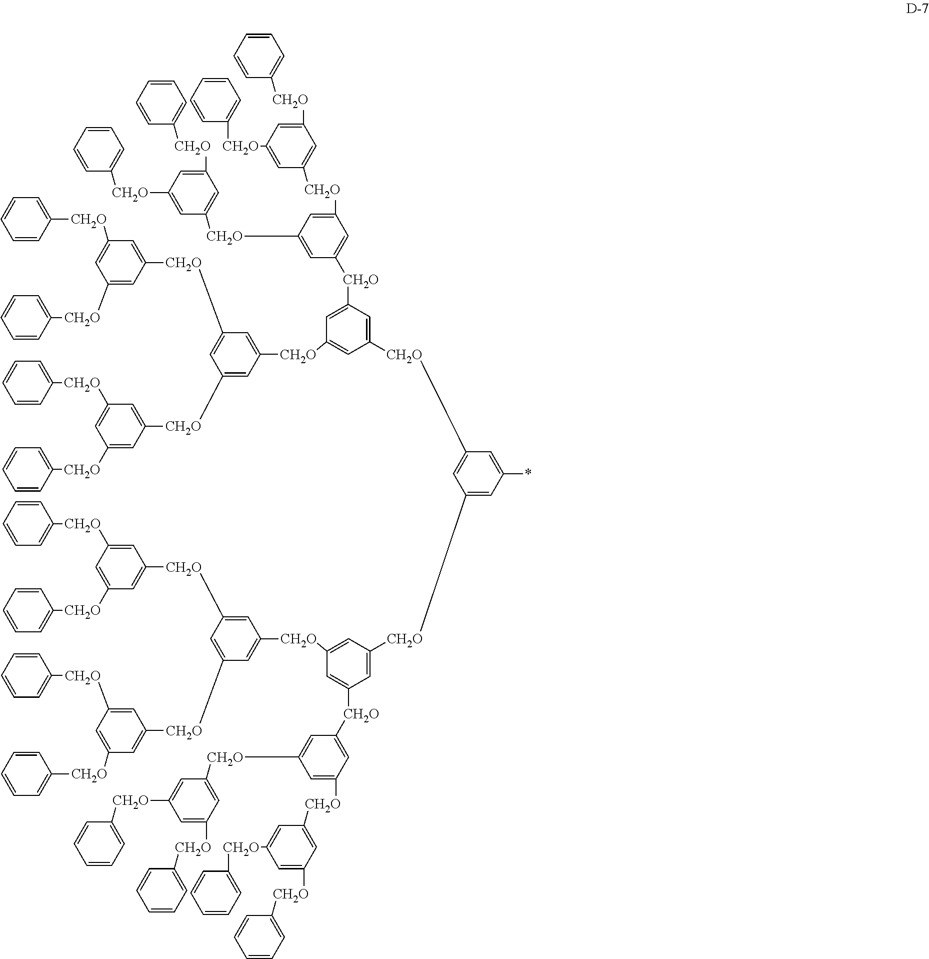

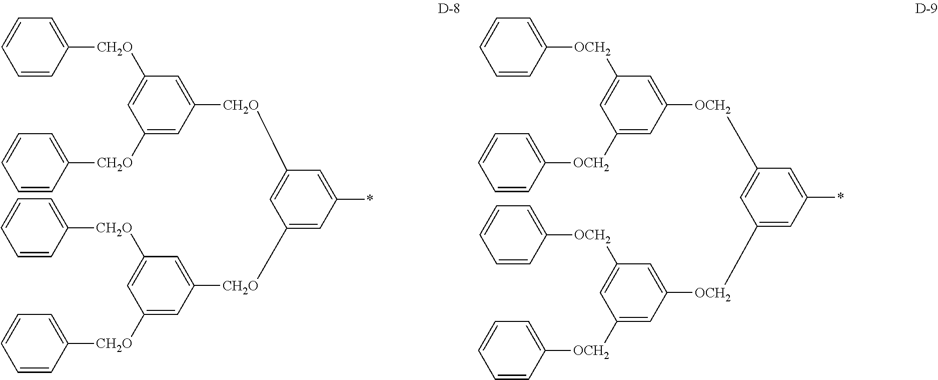

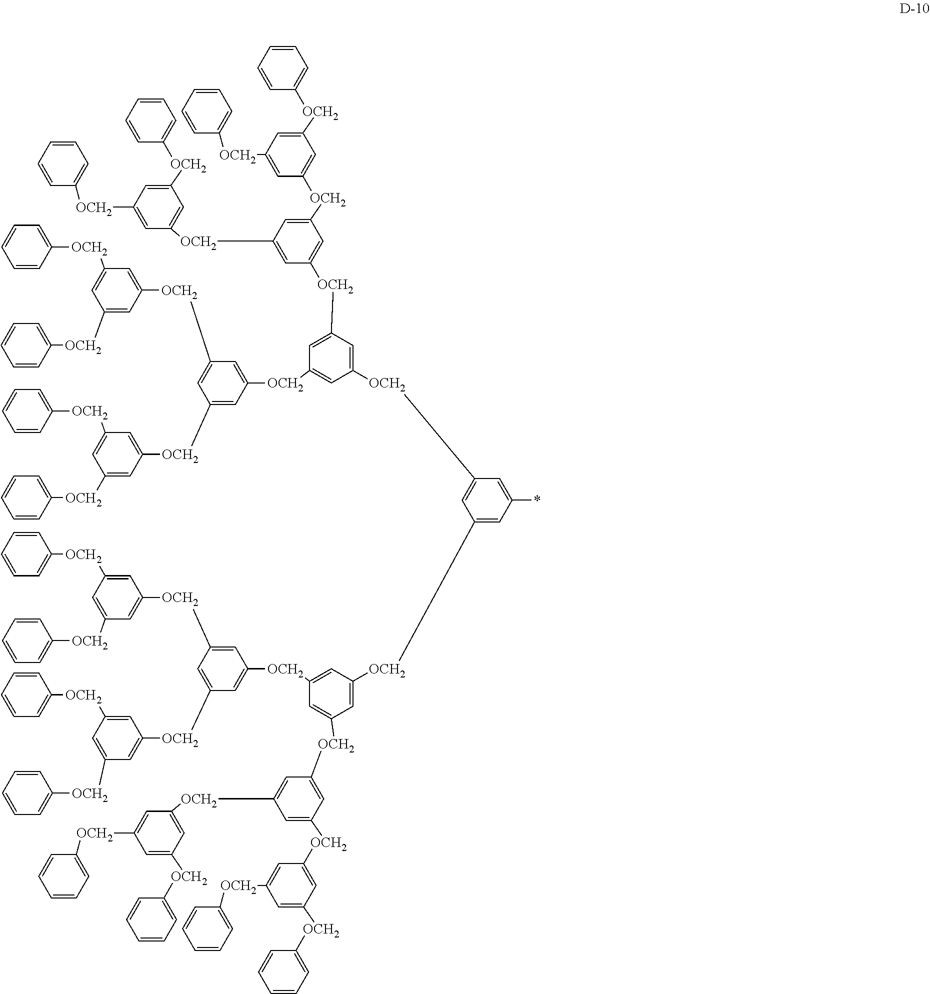

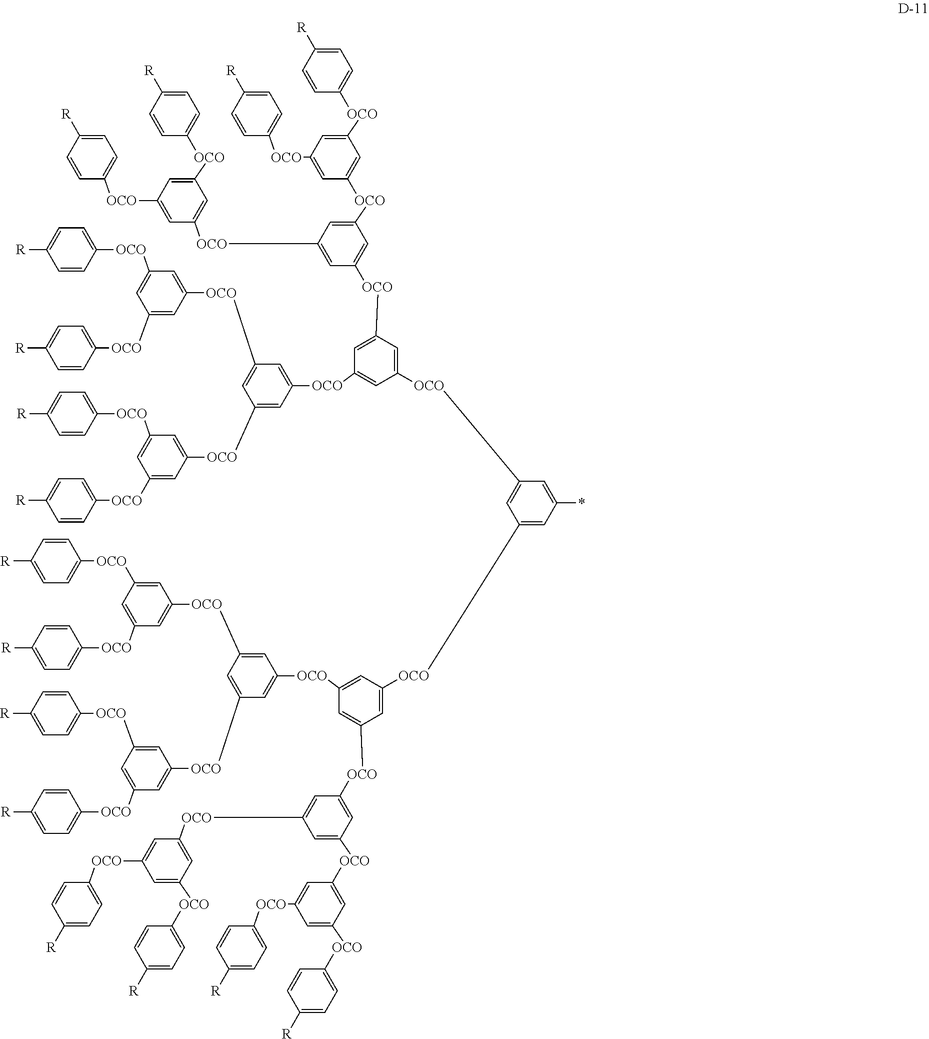

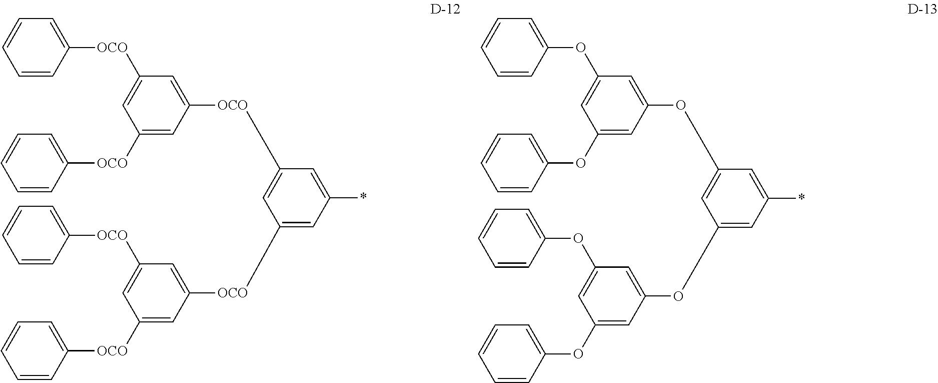

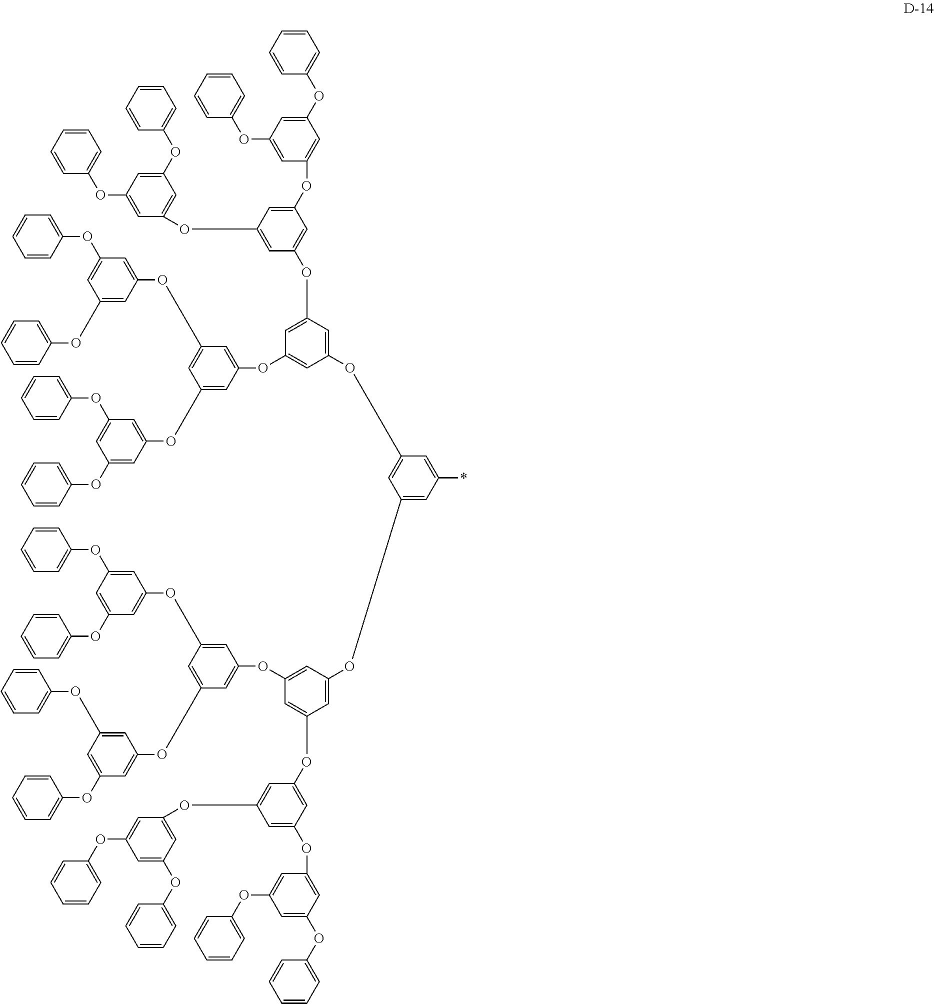 [SMILES: *c1cc(Oc2cc(Oc3cc(Oc4cc(Oc5ccccc5)cc(Oc5ccccc5)c4)cc(Oc4cc(Oc5ccccc5)cc(Oc5ccccc5)c4)c3)cc(Oc3cc(Oc4cc(Oc5ccccc5)cc(Oc5ccccc5)c4)cc(Oc4cc(Oc5ccccc5)cc(Oc5ccccc5)c4)c3)c2)cc(Oc2cc(Oc3cc(Oc4cc(Oc5ccccc5)cc(Oc5ccccc5)c4)cc(Oc4cc(Oc5ccccc5)cc(Oc5ccccc5)c4)c3)cc(Oc3cc(Oc4cc(Oc5ccccc5)cc(Oc5ccccc5)c4)cc(Oc4cc(Oc5ccccc5)cc(Oc5ccccc5)c4)c3)c2)c1]

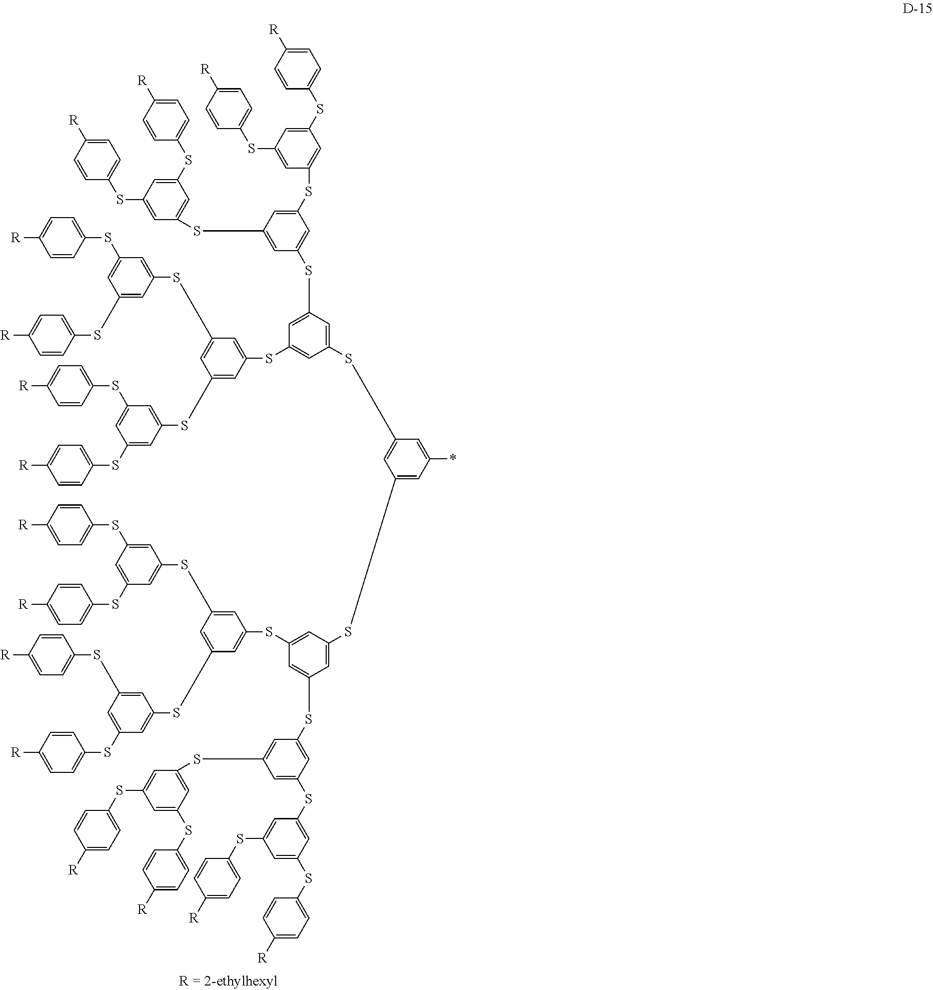

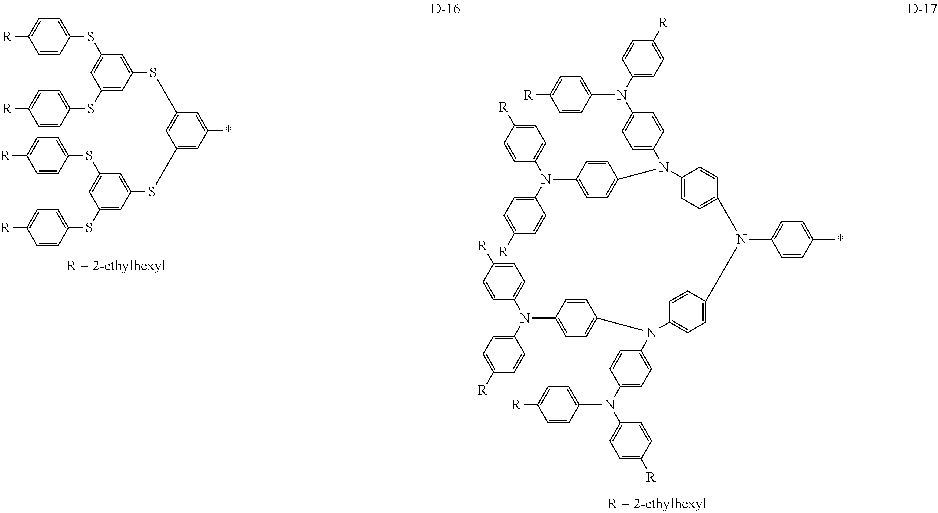

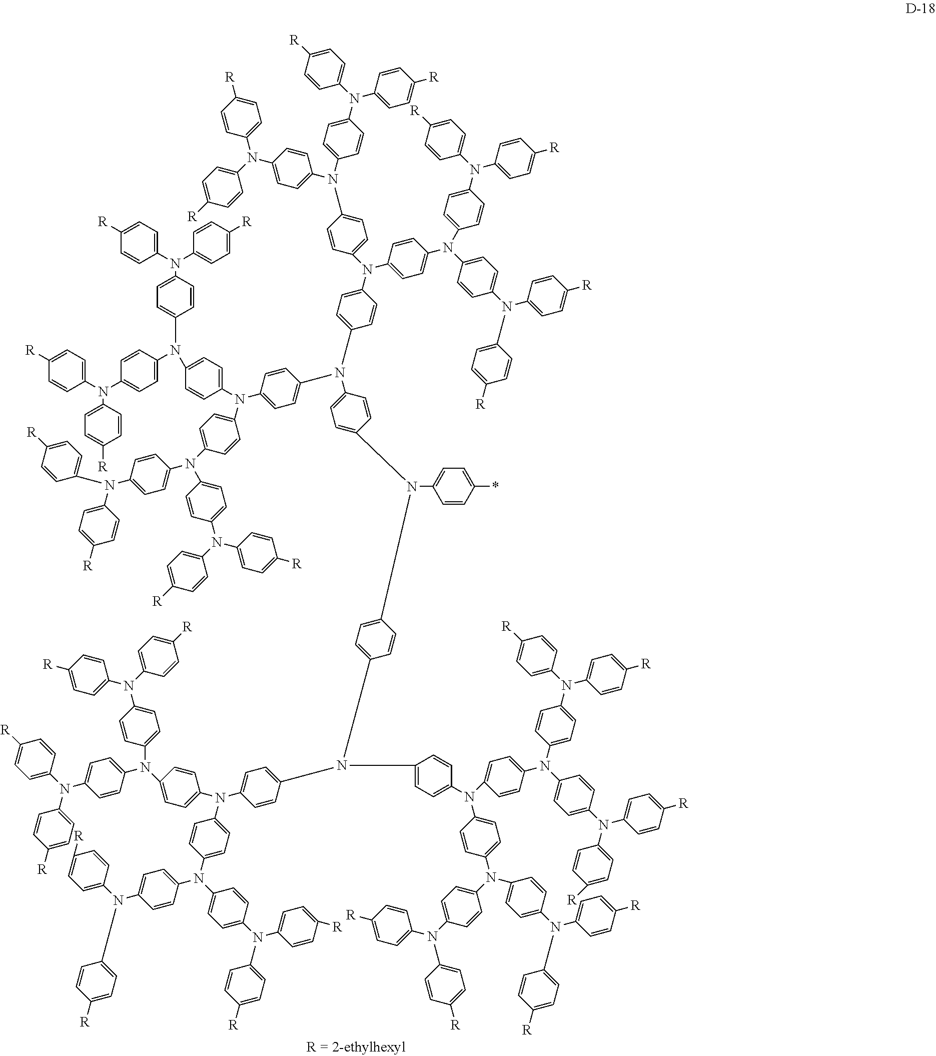

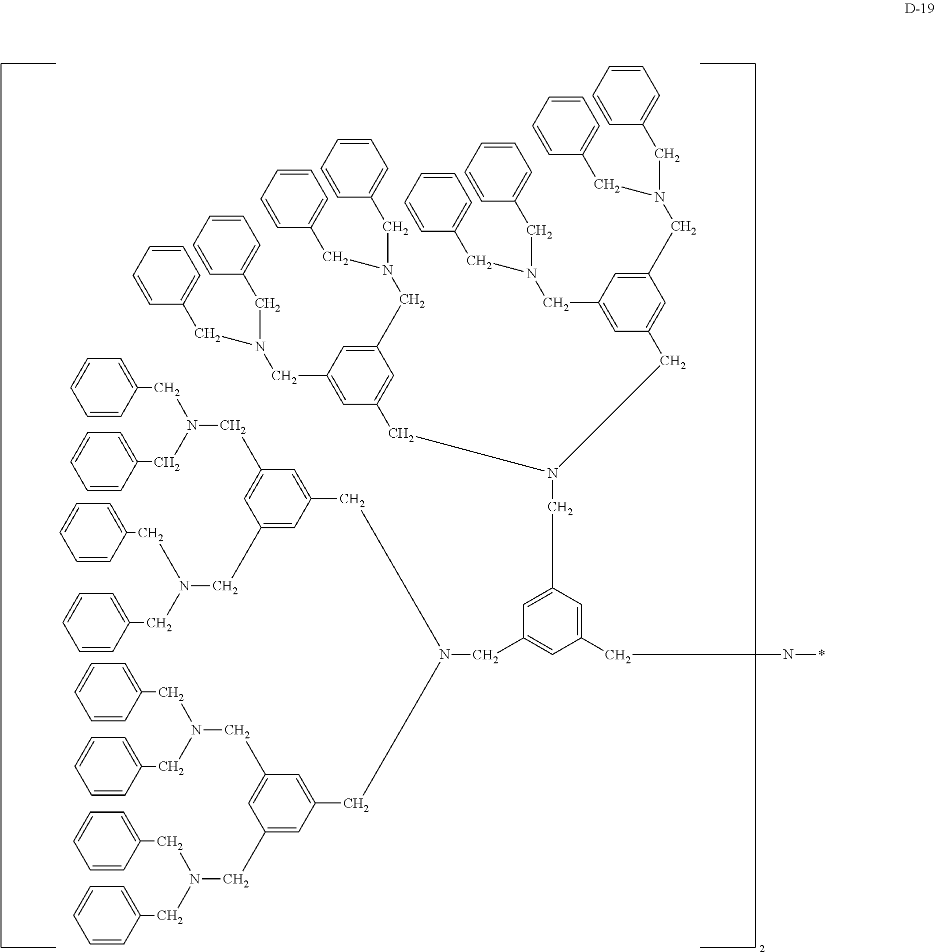

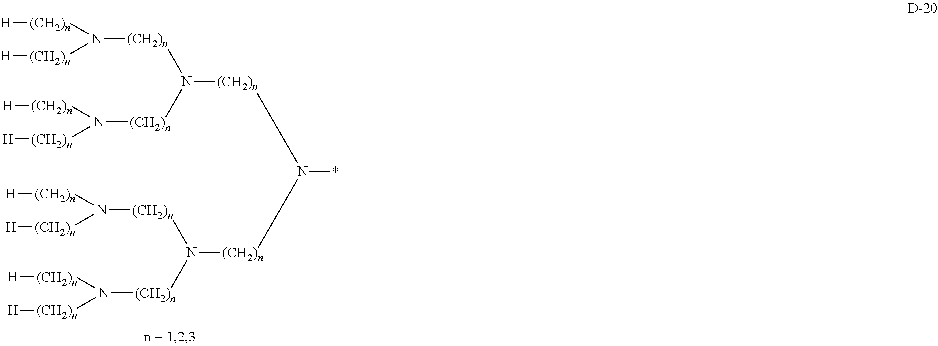

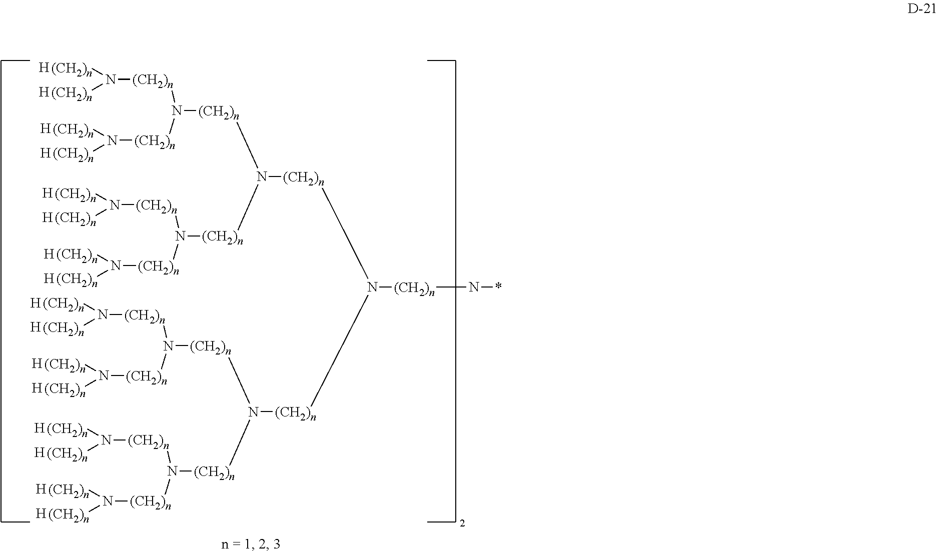

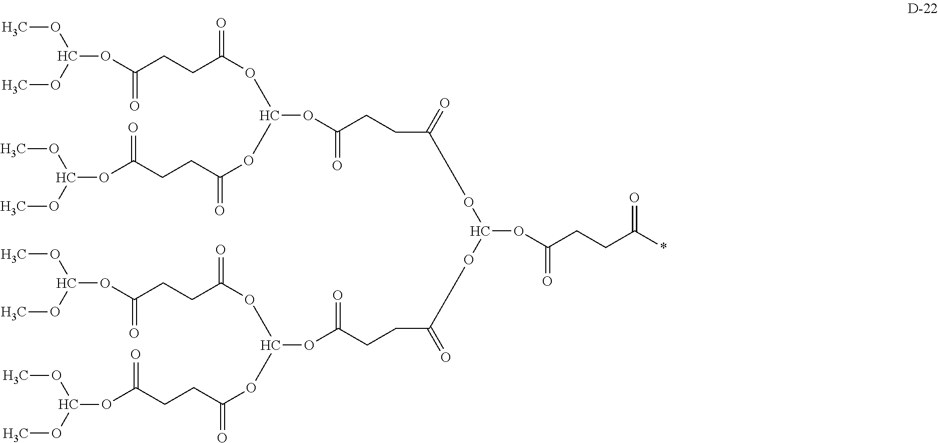 [SMILES: *C(=O)CCC(=O)OC(OC(=O)CCC(=O)OC(OC(=O)CCC(=O)OC(OC)OC)OC(=O)CCC(=O)OC(OC)OC)OC(=O)CCC(=O)OC(OC(=O)CCC(=O)OC(OC)OC)OC(=O)CCC(=O)OC(OC)OC]

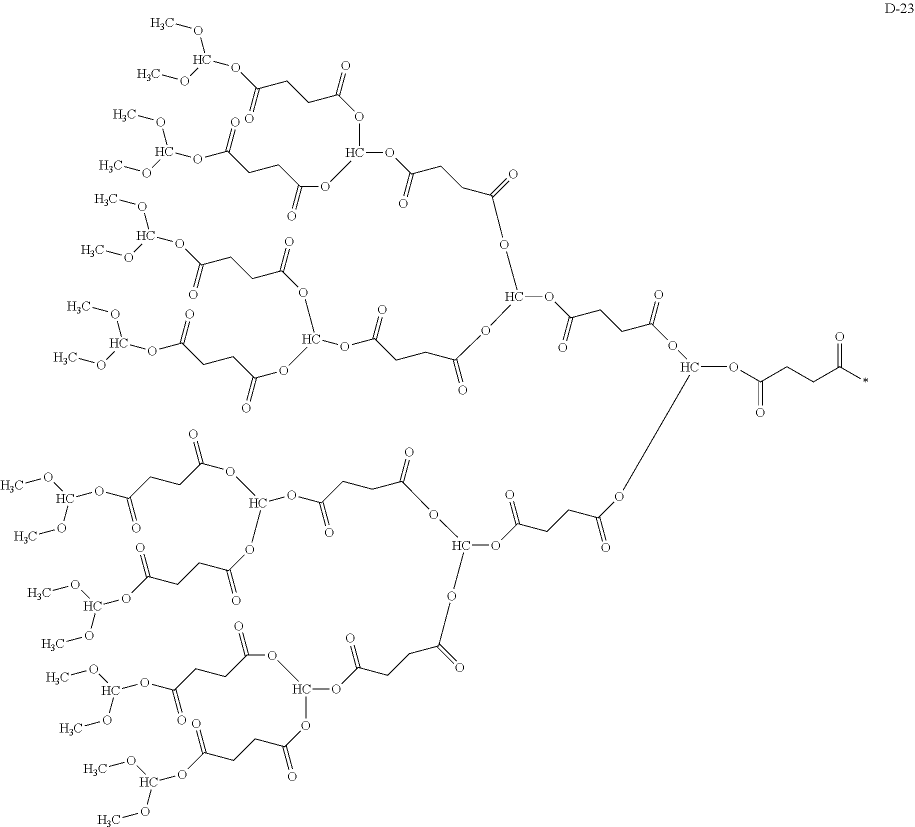 [SMILES: *C(=O)CCC(=O)OC(OC(=O)CCC(=O)OC(OC(=O)CCC(=O)OC(OC(=O)CCC(=O)OC(OC)OC)OC(=O)CCC(=O)OC(OC)OC)OC(=O)CCC(=O)OC(OC(=O)CCC(=O)OC(OC)OC)OC(=O)CCC(=O)OC(OC)OC)OC(=O)CCC(=O)OC(OC(=O)CCC(=O)OC(OC(=O)CCC(=O)OC(OC)OC)OC(=O)CCC(=O)OC(OC)OC)OC(=O)CCC(=O)OC(OC(=O)CCC(=O)OC(OC)OC)OC(=O)CCC(=O)OC(OC)OC]

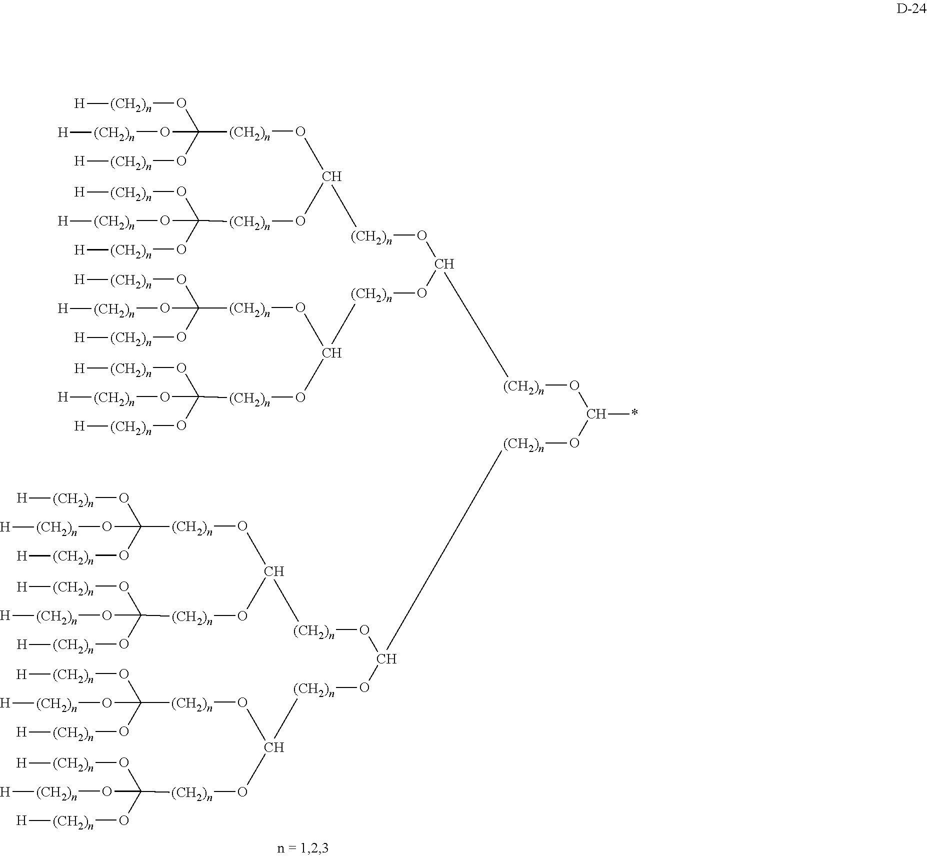

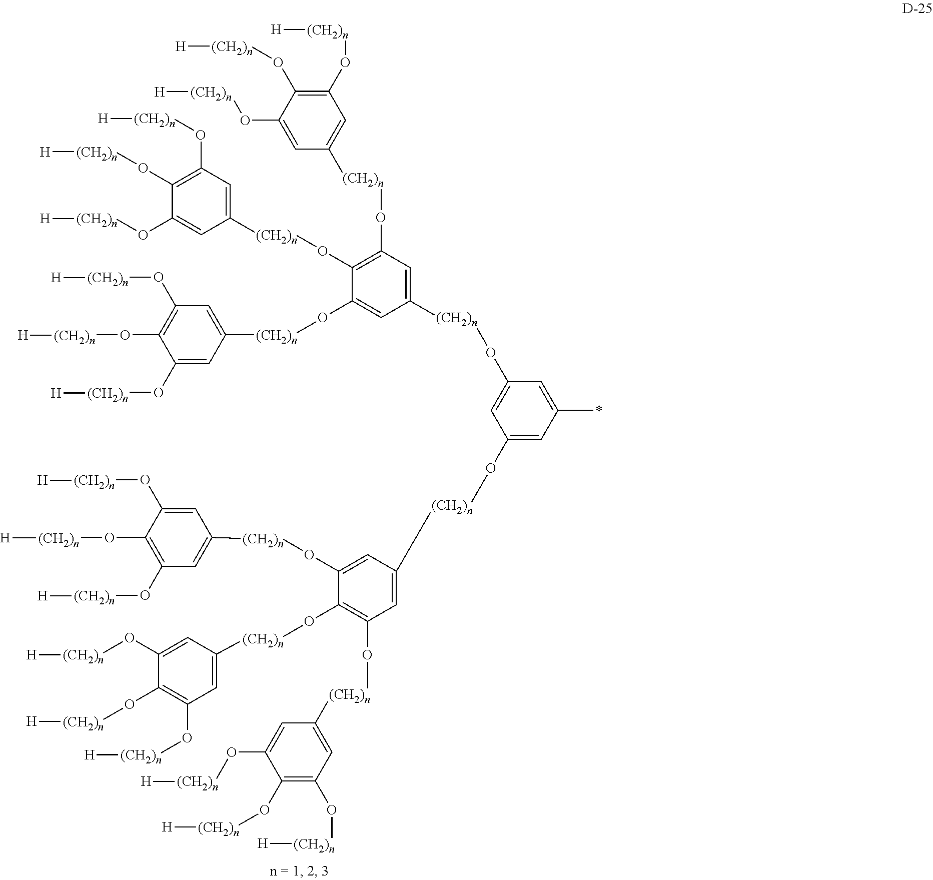

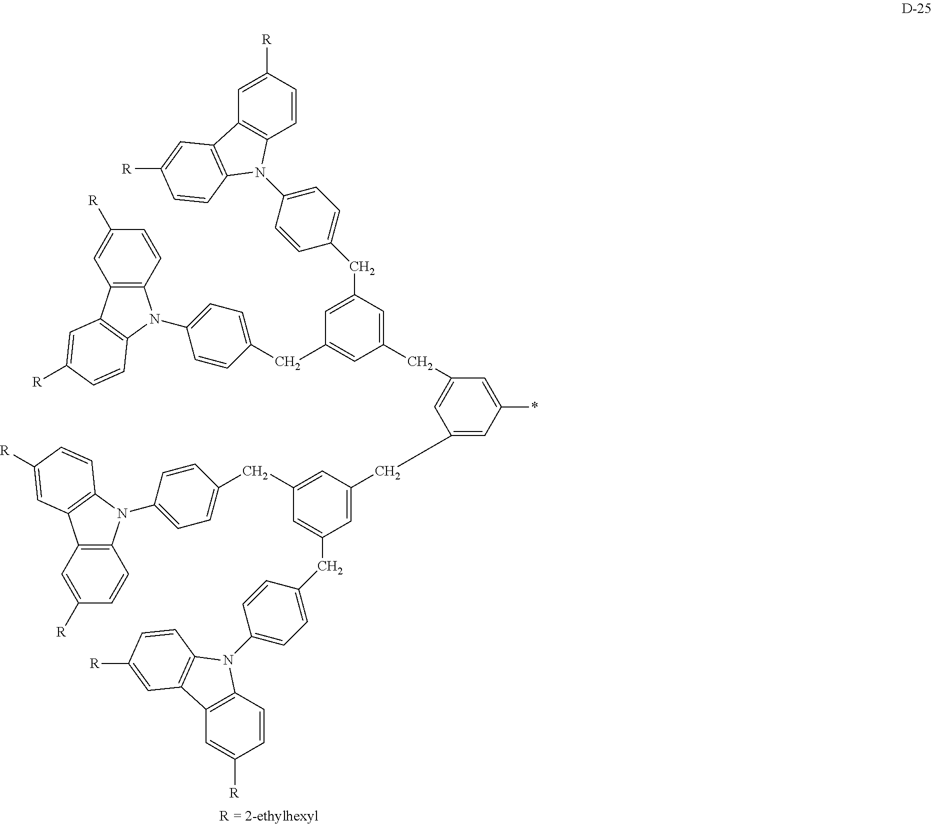

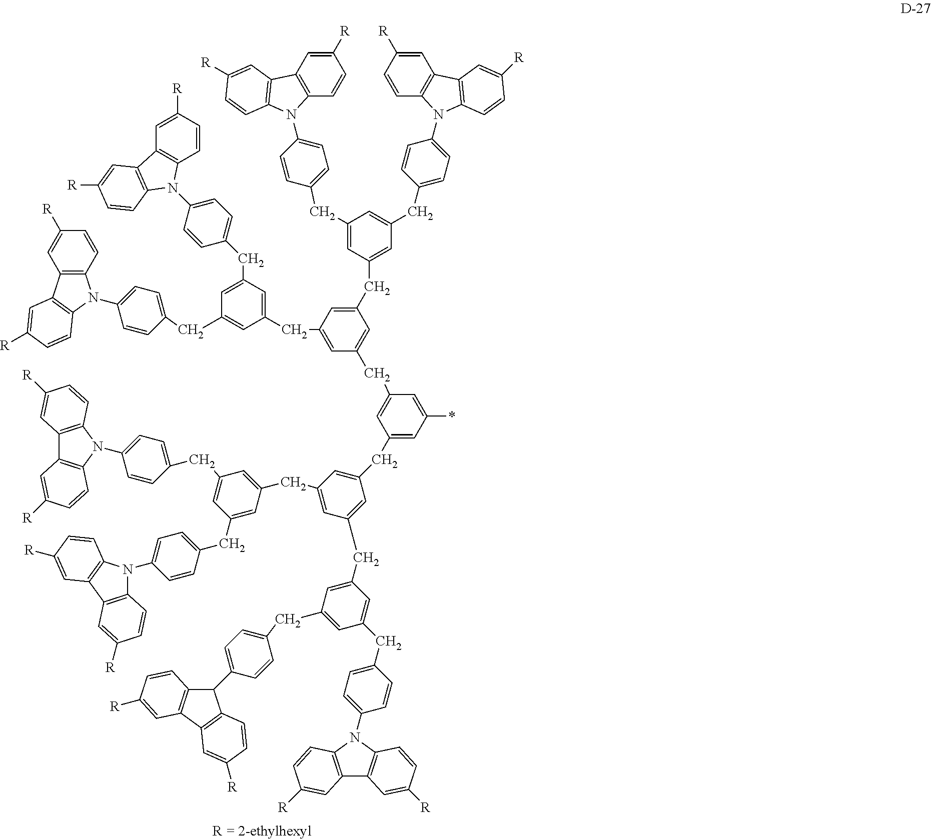

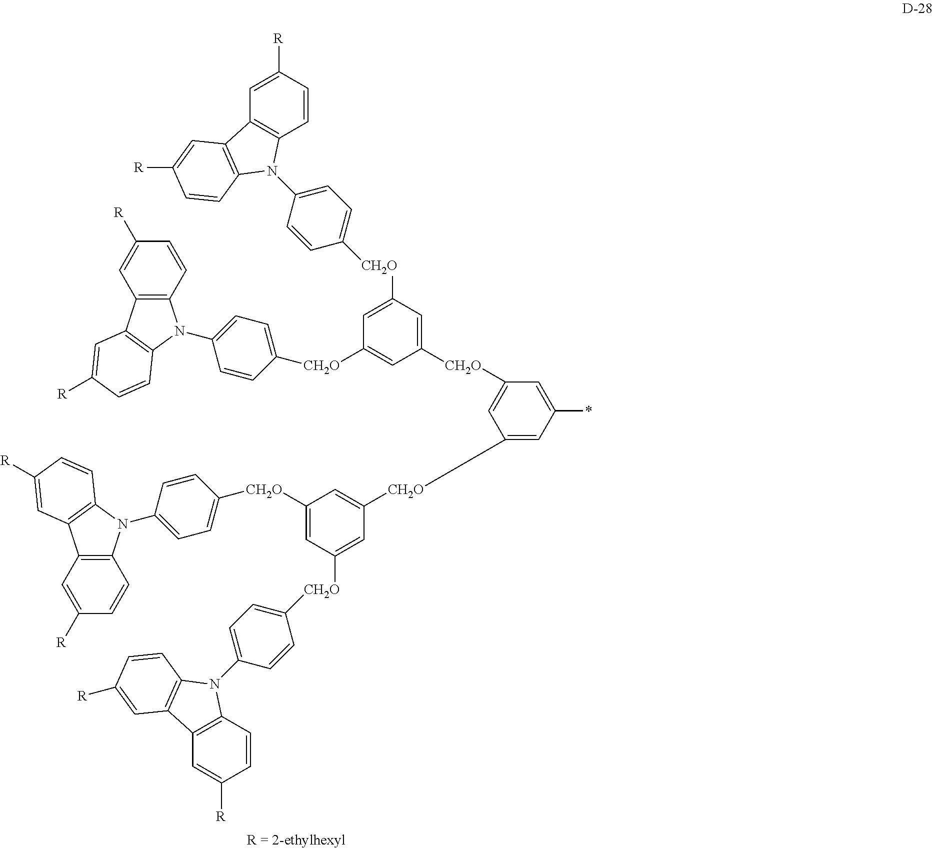

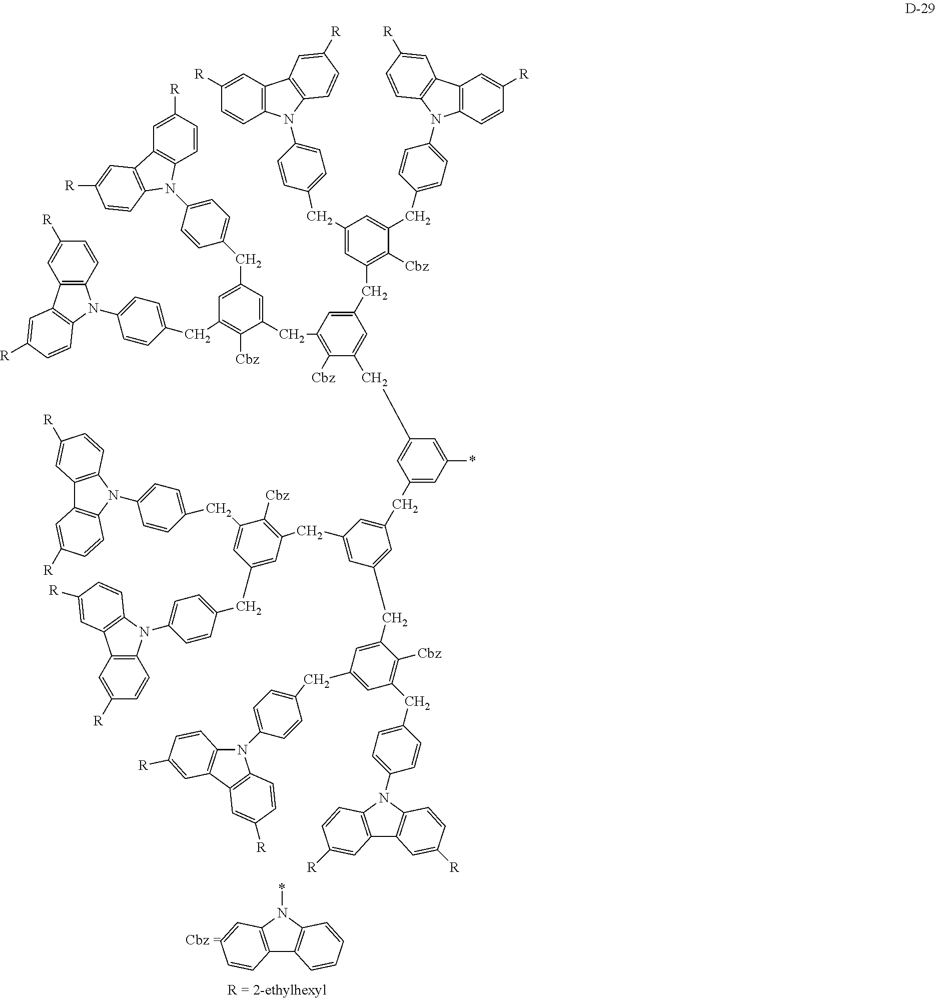

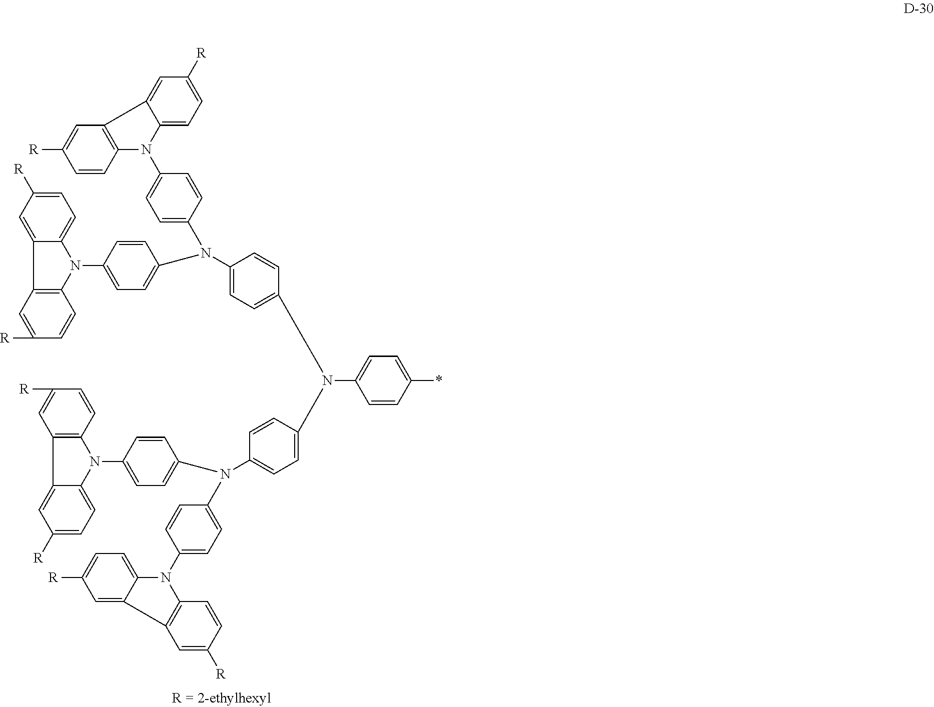

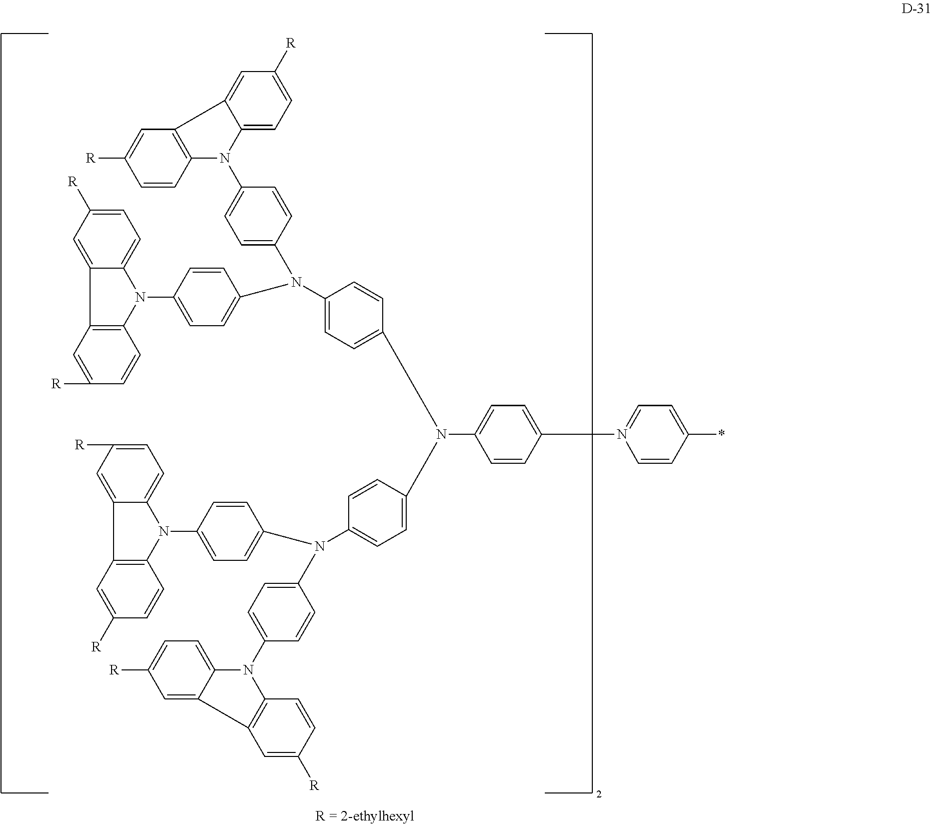

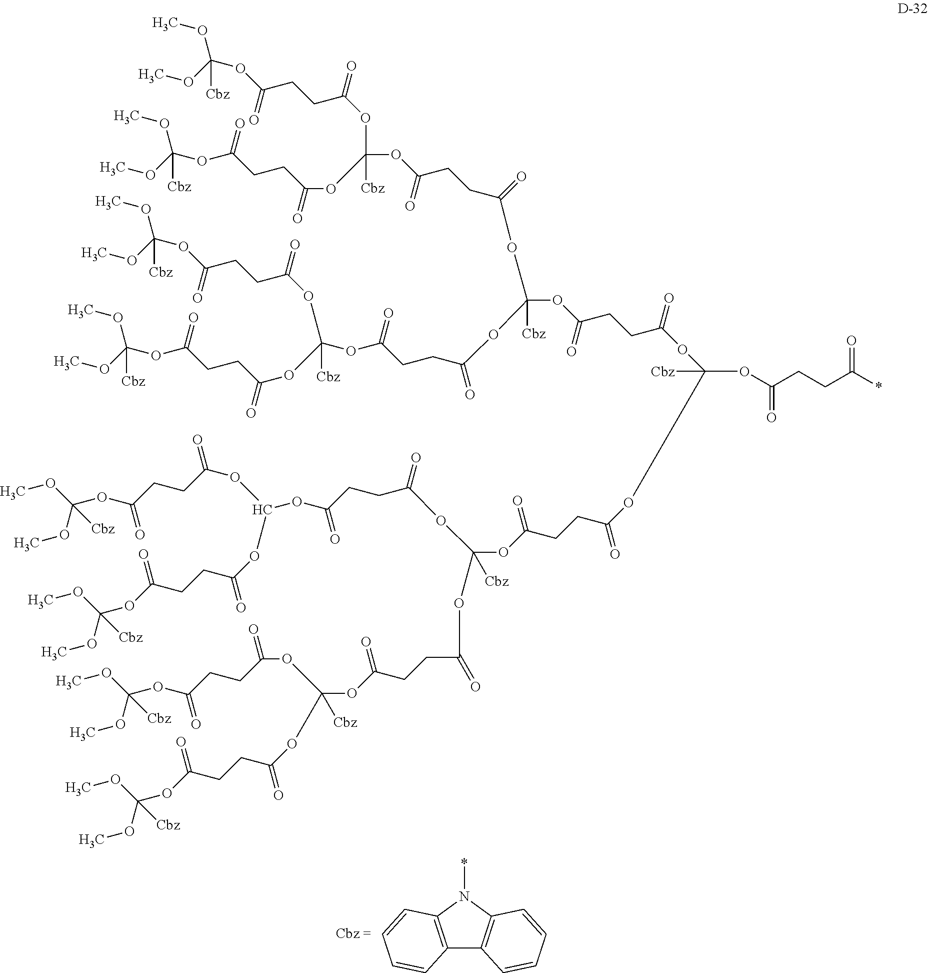

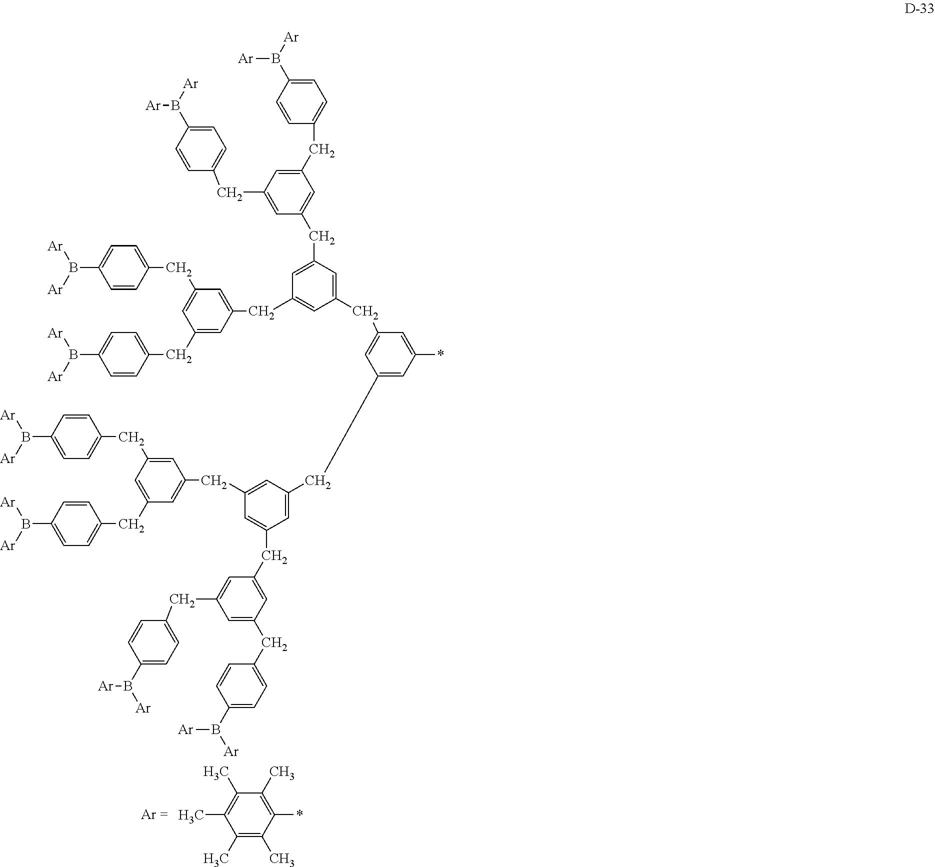

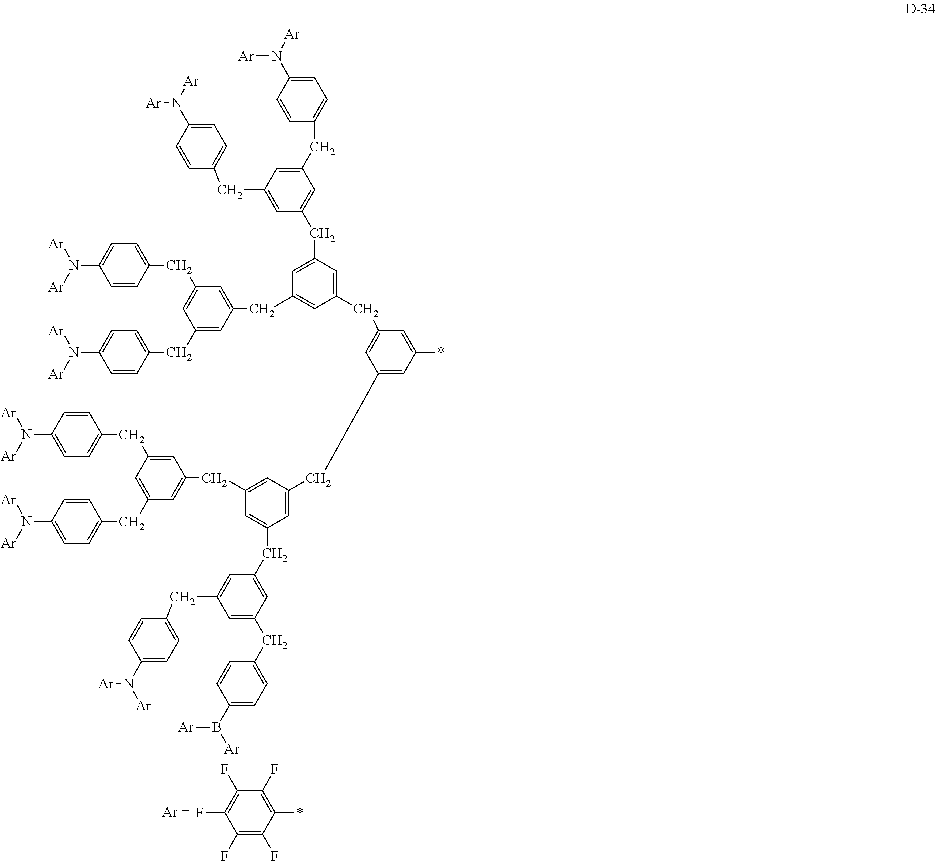

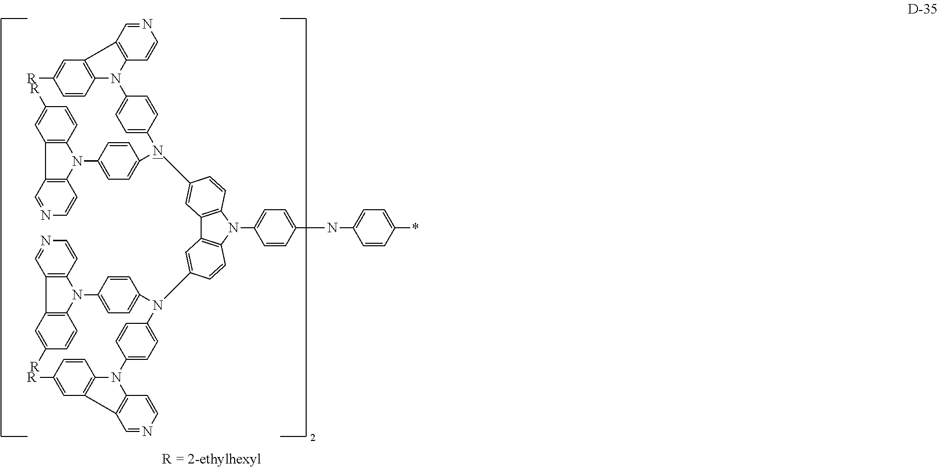

The synthesizing method of the typical example of the multi-branched structure compound for encapsulating the organic electroluminescent light emission material according to the invention is described below but the embodiment of the invention is not limited to the description.

The synthesizing method of dendrimer described in J. M. J. Frechet et al., J. Am. Chem. Soc., Vol. 12, p. 7638, 1990 and F. Zeng et al., Chem. Rev., vol. 97, p. 1681, 1997, can be applied for synthesizing the multi-branched structure compound. Moreover, the compound can be synthesized by known method using a building blocking agent put on the market by reagent makers.

The synthesis of the dendrimer is carried out by a procedure in which a low molecular weight monomer is successively bonded. The synthesizing method can be roughly classified into a divergent method and a convergent method. In the former method, molecules are bonded to a molecule to be core in order of generation for forming the branched structure. In the later method, it is usual that the branched structure is preliminary formed and bonded to the molecule to be core at the last step, but a method other than the above may be applied.

The synthesizing method of D-1 and D-30 by the convergent method is described below.

### 1. Precursor of Encapsulation Type Multi-Branched Structure Compound PD-1 (Branched Structural Substance D-1, Core Bonding Group C-2)

Four point six grams (20 mmoles) of 4-(2-ethylhexyl)-phenylboric acid and 3.2 g (10 moles) of 1,3,5-tribromobenzene were dissolved in 200 ml of toluene, and 4.6 g (4.0 mmoles) of tetrakistriphenylphosphine palladium [Pd(PPh₃)₄] and 50 ml of a 2M-aqueous solution of sodium carbonate were added to the resultant solution and refluxed for 24 hours by heating. After completion of reaction, the reacting liquid was subjected to extraction by tetrahydrofuran (THF) and the organic layer was dried by anhydrous magnesium sulfate. The solvent was removed by distillation under reduced pressure and the resultant product was isolated and purified by silica gel chromatography using an elutriant of 1:1 mixture of hexane and toluene. Thus 3.3 g of Precursor 1 was obtained in a yield of 61%. In 150 ml of anhydrous THF, 3.2 g (6.0 mmoles) of Precursor 1 was dissolved and lithiated using 4.1 ml (6.6 mmoles) of a 1.6 M-hexane solution of n-butyl lithium in nitrogen atmosphere at −78° C. and stirred for 30 minutes. To the reacting liquid, 10 ml of THF containing 0.73 g (7 moles) of trimethyl borate was gradually dropped and stirred for 2 hours and further stirred for 5 hours while the temperature was gradually restored until room temperature. The reaction was stopped by adding 50 ml of distillated water and the reacting liquid was subjected to extraction by THF and the organic layer was dried by anhydrous magnesium sulfate. The solvent was removed from the resultant liquid by distillation under reduced pressure and the product was isorated and purified by silica gel chromatography using THF as an elutriant. Thus 3.1 g of Precursor 2 was obtained in a yield of 98%. Two point nine grams (5.5 mmoles) of Precursor 2 was reacted in the same manner. Thus 1.8 g of the objective compound D-1 was obtained in a yield of 65%. After that, boric acid reagent prepared from D-1 by the foregoing method was reacted with 1,3,5-tribromobenzene and the product was separated and purified through a column charged with Sephadex-G25, manufactured by Aldrich Co., Ltd., using HFIP as an elutriant. Thus 1.1 g of a precursor of encapsulation type multi-branched structure compound DP-1 was obtained in a yield of 60%.

### 2. Precursor of Encapsulation Type Multi-Branched Structure Compound PD-7 (Branched Structural Substance D-17, Core Bonding Group C-10)

Into 1,000 ml of methylene chloride, 19.7 g (50 mmoles) of bis(4-(2-ethylhexyl)phenyl)amine, 10.3 g (25 mmoles) of boric acid reagent prepared from tri(4-bromophenyl)amine by the foregoing method, 9.1 g (50 mmoles) of copper(II) acetate and 10 g of 0.4 nm molecular sieve were added and 10 g (0.1 moles) of triethylamine was added while stirring. The resultant mixture was reacted for 48 hours at room temperature, and then 100 ml of 2-N hydrochloric acid was added to the reacting liquid. The product was extracted by methylene chloride and the organic layer was dried by anhydrous sodium sulfate. The solvent was removed by distillation and the product was dried under reduced pressure. The dried product was isolated and purified by silica gel chromatography using a mixture of 1:1 of hexane and toluene as an elutriant. Thus 21.6 g of Precursor 3 obtained in a yield of 78%. Eleven point zero grams (10 mmoles) of a boric acid reagent prepared by the foregoing method was reacted in the same manner with 0.9 g (5 moles) of 4-bromoaniline to form a boric acid reagent Precursor 4. Thus 7.5 g (3.4 mmoles) of Precursor 4 was obtained. On the other hand, 6.4 g (3 mmoles) of Precursor 5 was obtained by using 4.3 g (4 moles) of 1,4-diaminobenzene in place of the 4-bromoaniline. Six point seven grams (3 moles) of Precursor 4 and 3.2 g (1.5 mmoles) of Precursor 5 were reacted and the product was separated and purified through a column charged with Sephadex-G25, manufactured by Aldrich Co., Ltd., using HFIP as an elutriant. Thus 6.3 g of a precursor of encapsulation type multi-branched structure compound PD-7 was obtained in a yield of 65%.

### 3. Precursor of Encapsulation Type Multi-Branched Structure Compound PD-2 (Branched Structure Substance D-30, Core Bonding Group C-5)

Seven point eight grams (20 mmoles) of 3,6-bis(ethylhexyl)carbazole was reacted with 10.8 g (10 mmoles) of a boric acid reagent prepared from tri(4-bromophenyl)amine by the forgoing method in the same manner as in the foregoing PD-7 precursor, and then further reacted with 4-bromoaniline. Thus 10.0 g (4.5 mmoles) of Precursor 6 was obtained. Six point seven grams (3.0 mmoles) of Precursor 6 was dissolved in 500 ml of THF and lithiolated using 2.1 ml of 1.6 M hexane solution (3.3 mmoles) of n-butyl lithium in nitrogen atmosphere at −78° C. and stirred for 30 minutes. To the reacting liquid, 0.36 g (1.0 mmoles) of 1,3,5-tribromobenzene dissolved in 5 ml of THF was gradually dropped. The liquid was stirred for 2 hours and then the temperature of the liquid was gradually restored until room temperature. The reaction was stopped by adding 50 ml of distillated water and the product was extracted by THF. The organic layer was dried by anhydrous magnesium sulfate. The dried product was separated and purified by a column charged with Sephadex-G25, manufactured by Aldrich Co., Ltd., using TFH as an elutriant. Thus 5.3 g of a precursor of encapsulation type multi-branched structure compound PD-2 was obtained in a yield of 81%.

### 4. Precursor of Encapsulation Type Multi-Branched Structure Compound PD-11 (Branched Structural Substance D-28, Core Bonding Group C-8)

Seven point eight grams (20 mmoles) of 3,6-bis(2-ethylexyl)carbazole and 4.4 g (20 mmoles) of 4-iodotoluene were dissolved in 10 ml of anhydrous dimethylacetoamide and 5 mg of copper powder and 3.0 g (22 mmoles) of potassium carbonate were added, and the refluxed for 40 hours by heating. The reacting liquid was restored until room temperature and 500 ml of distillated water was added, and subjected to extraction by toluene. The organic layer was dried by anhydrous magnesium sulfate. The solvent was removed under reduced pressure and the product was isolated and purified by silica gel chromatography using an elutriant of a 7:3 mixture of hexane and toluene. Thus 5.6 g of Precursor 7 was obtained in a yield of 58%. Four point eight grams (10 mmoles) of Precursor 7 and 3.9 g (22 moles) of N-bromosuccinimde were dissolved in 50 ml of methylene chloride and stirred for 24 hours. To the resultant liquid, 100 ml of 1N-sodium thiosulfate aqueous solution was added and the liquid was subjected to extraction by methylene chloride. The organic layer was dried by anhydrous magnesium sulfate. The solvent was removed from the product, and the product was separate and purified by silica gel chromatography using an elutriant of a 7:3 mixture of hexane and toluene. Thus 5.4 g of Precursor 8 was obtained in a yield of 97%. In 20 ml of toluene, 5.0 g (9 mmoles) of Precursor 8 and 0.9 g (4.5 mmoles) of 5-dihydroxybrormobenzene were dissolved and 5 ml of 6N-sodium hydroxide methanol solution was added and the resultant solution was refluxed for 10 hours by heating. After completion of the designated time, the temperature of the reacting liquid was restored until room temperature and the solvent was removed by distillation. The resultant mixture was dissolved by adding 100 ml of toluene and 50 ml of distillated water and subjected to extraction by toluene. The organic layer was dried by anhydrous magnesium sulfate. The solvent was removed by distillation under reduced pressure and the product was separated and purified by silica gel chromatography using an elutriant of a 6:4 mixture of hexane and toluene. Thus 4.0 g of Precursor 9 was obtained in a yield of 78%. Three point four grams (3 mmoles) of Precursor 9 was dissolved in 100 ml of anhydrous THF and lithiolated by 2.1 ml of 1.6 M-hexane solution of n-butyl lithium (3 mmoles) at −78° C. under nitrogen stream and stirred for 30 minutes. The resultant solution was gradually dropped into 50 ml of a THF solution of 0.3 g (1 mmole) of 1,3-dibromo-2-bromomethylropane previously cooled at −78° C. The temperature of the reacting liquid was gradually restored until room temperature after stirring for 2 hours and then 100 ml of distillated water was added to stop the reaction. The resultant liquid was subjected to extraction by THF and the organic layer was dried by anhydrous magnesium sulfate. The dried product was separated and purified by a column charged with Sephadex-G25, manufactured by Aldrich Co., Ltd., using TFH as an elutriant. Thus 2.5 g of a precursor of encapsulation type multi-branched structure compound PD-11 was obtained in a yield of 76%.

The molecular weight of the multi-branched structure compound according to the invention is preferably from 1,000 to 100,000, and more preferably from 2,000 to 50,000. By making the molecular weight within the above range, the solubility of the compound into a solvent is ensured and the viscosity of the solution is made suitable for easily forming the organic layer of the organic EL element when the organic layer is formed by a coating method.

Though any compound employed as the light emission material of the conventional organic electroluminescent element may be applied for the organic electroluminescent light emission material relating to the invention, the use of a fluorescent compound or a phosphorescent compound is specifically preferable. Further high light emitting efficiency can be obtained by the use of such the compounds.

The fluorescent compound is an organic compound having high fluorescent quantum efficiency in a solution state or a compound having a partial structure of rare earth metal complex type fluorescent substance. The fluorescent quantum efficiency is preferably not less than 10%, and specifically preferably not less than 30%. Examples of compound having high quantum efficiency include coumaline type dyes, pyrane type dyes, cyanine type dyes, croconium type dyes, squalium type dyes, oxobenzanthracene type dyes, fluorescein type dyes, rhodamine type dyes, pyrylium type dyes, perylene type dyes, stilbene type dyes and polythiophene type dyes. Compounds each having such the dye as the partial structure are employable.

Examples of the fluorescent compound are shown below but the aspects of the present invention is not limited thereto.

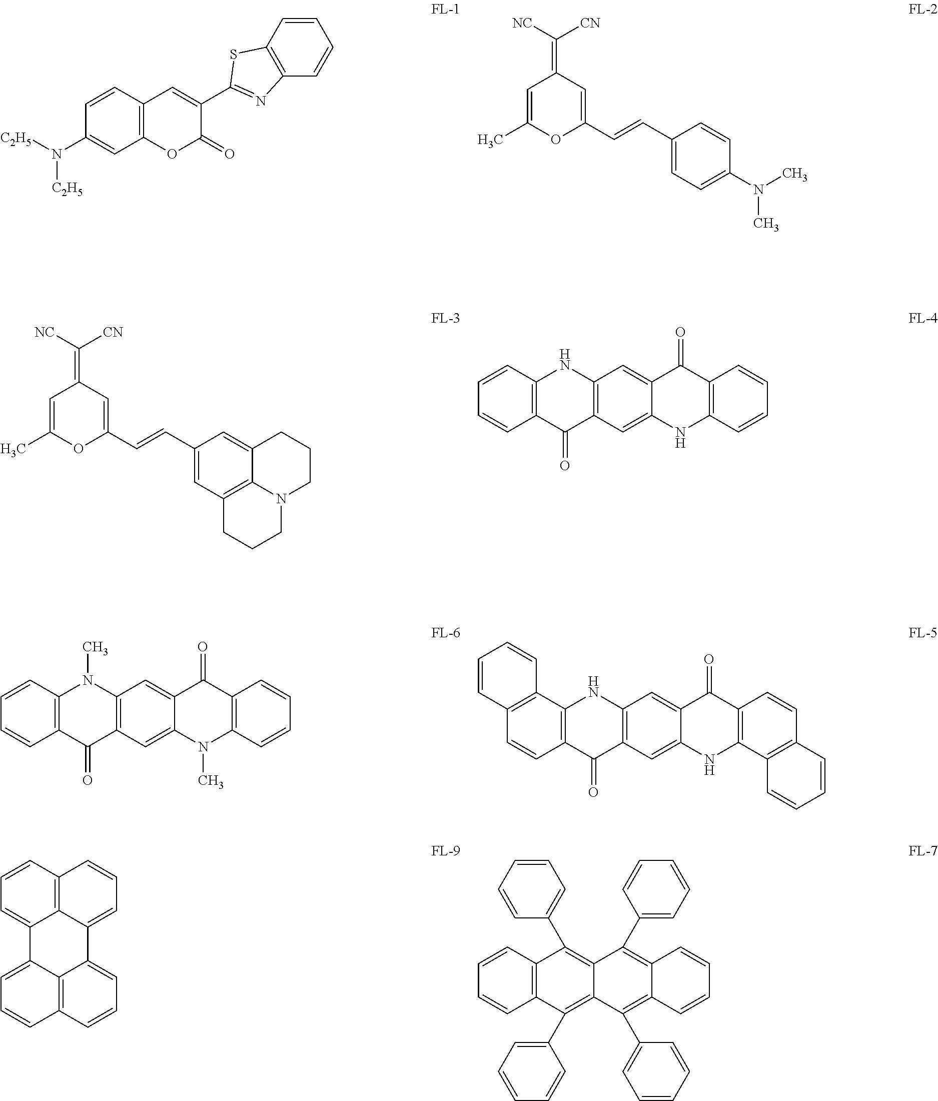

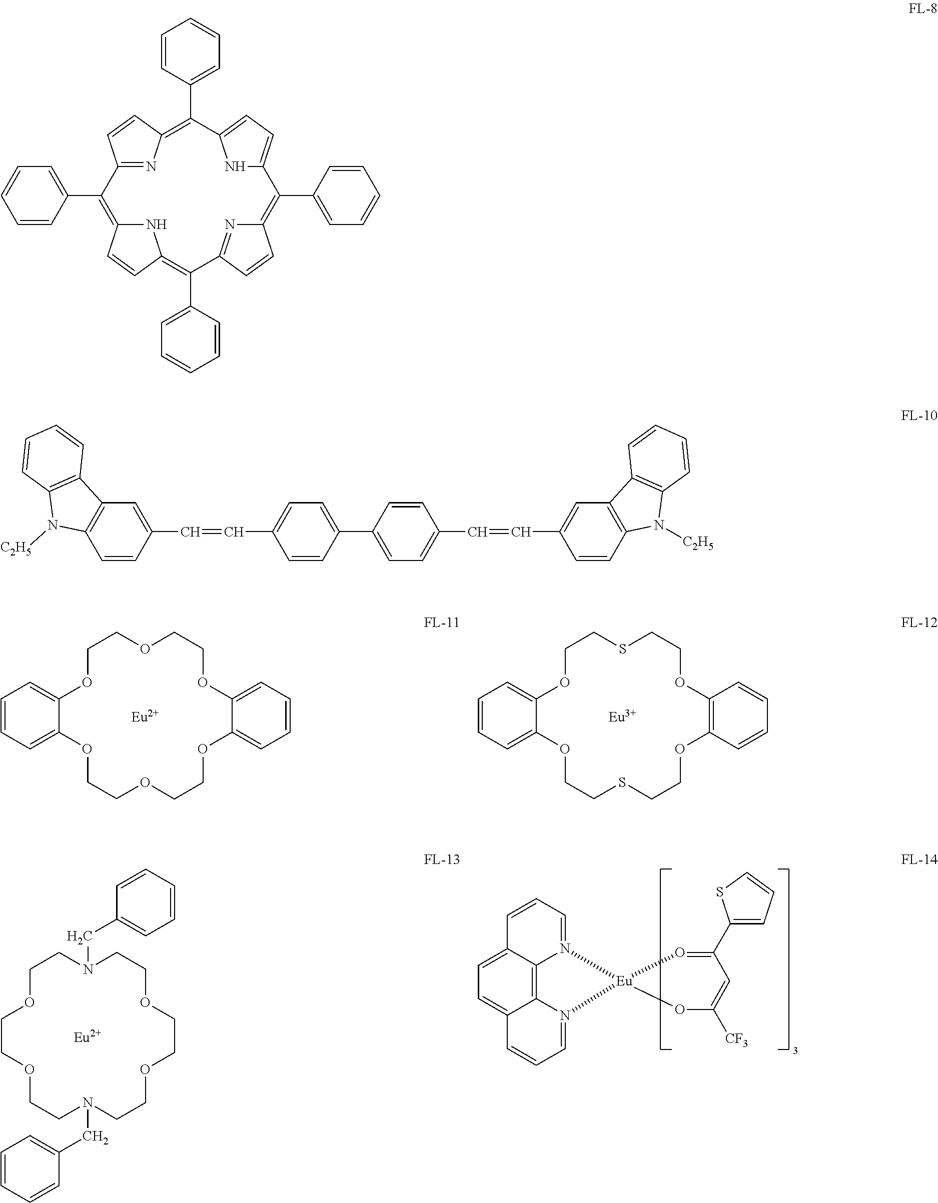

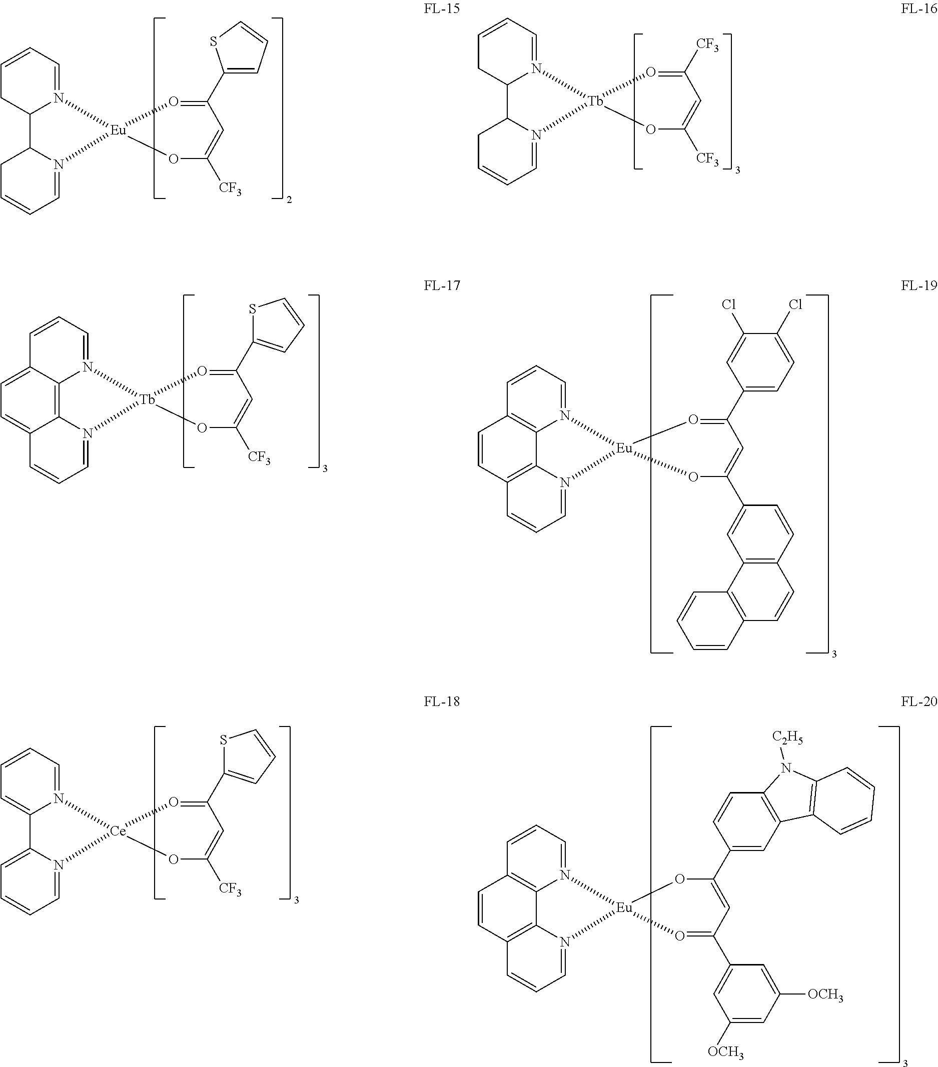

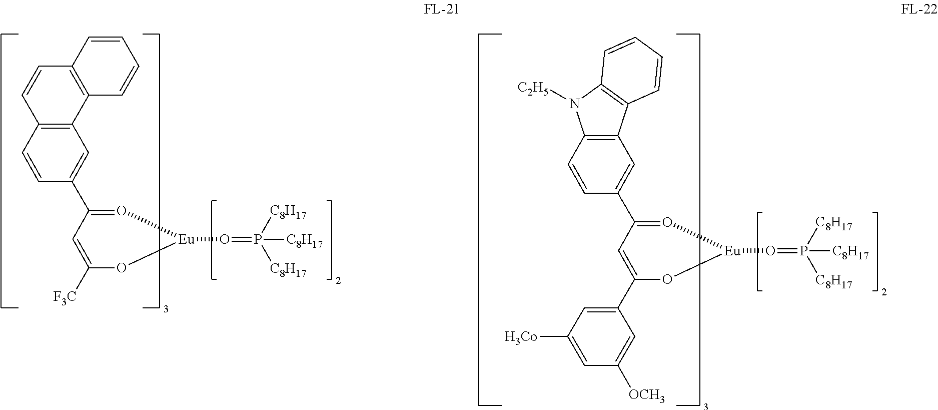

A phosphorescent compound is a compound having a substructure which emits light from the excited triplet. The phosphorescent quantum yield at 25° C. of the phosphorescent compound is not less than 0.001. The phosphorescent quantum yield is preferably not less than 0.01 and more preferably not less than 0.1.

The phosphorescent quantum yield can be measured according to a method described in the fourth edition “Jikken Kagaku Koza 7”, Bunko II, page 398 (1992) published by Maruzen. The phosphorescent quantum yield in a solution can be measured employing various kinds of solvents, and usable in the present invention is a phosphorescent compound which gives a phosphorescent quantum yield which falls in the above-described range in any one of the arbitrary solutions.

The phosphorescent compound is preferably an organometallic complex, whereby a further improved light emission efficiency is obtained.

The phosphorescent compound of the present invention is preferably an organometallic complex containing a metal of Group 8 of the periodic table, and is more preferably an iridium compound, an osmium compound, a platinum compound (a platinum complex), a rhodium compound, a palladium compound, a ruthenium compound or a rare earth compound, of these, the most preferable is an iridium compound, whereby a further improved light emission efficiency is obtained.

Examples of a phosphorescent compound will be listed below, however, the present invention is not limited thereto.

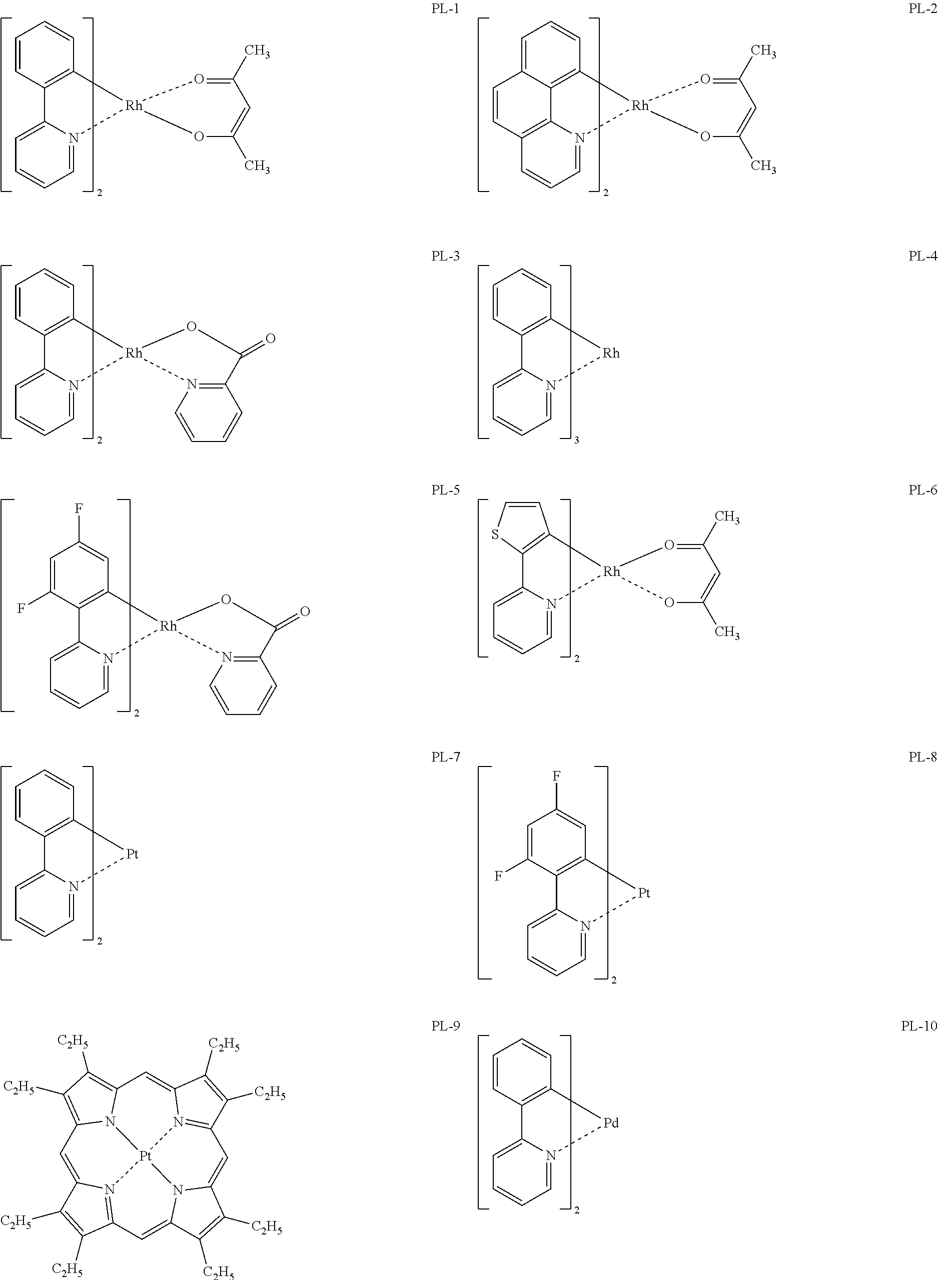

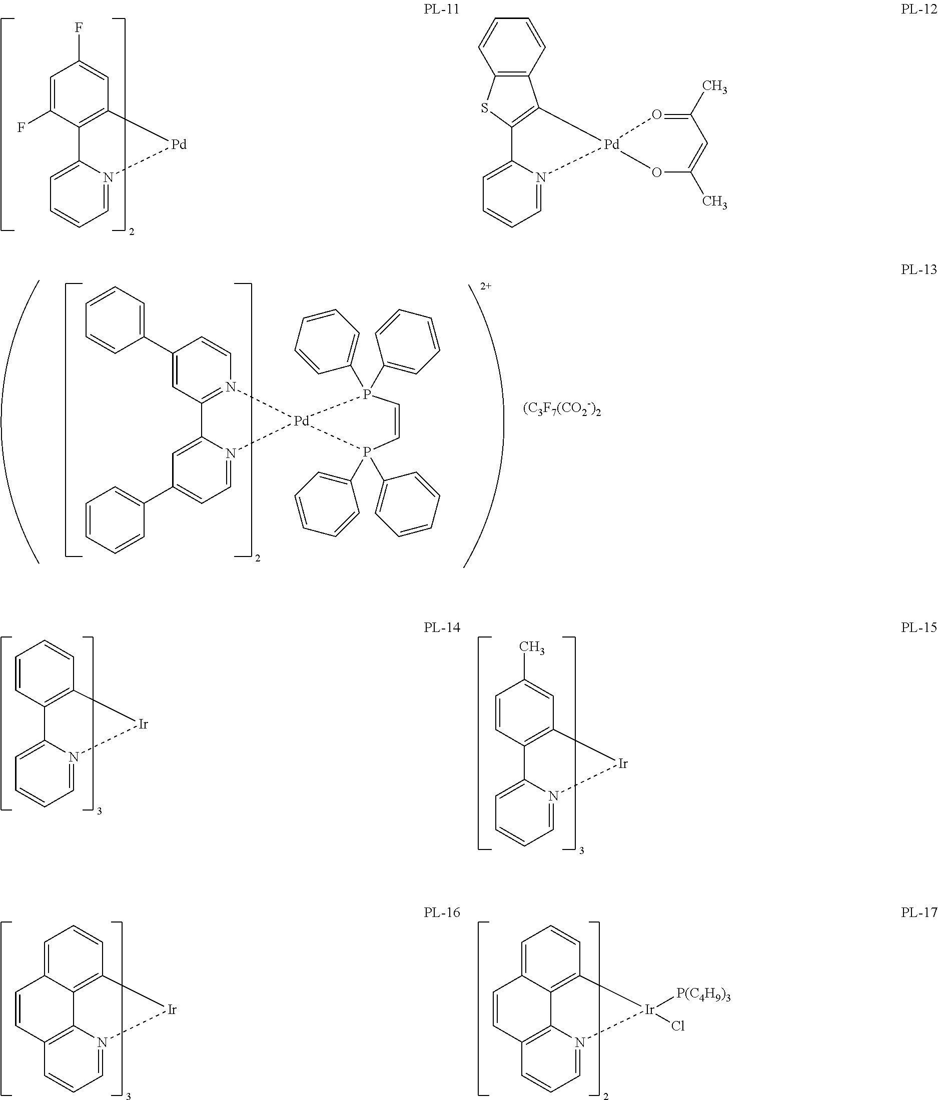

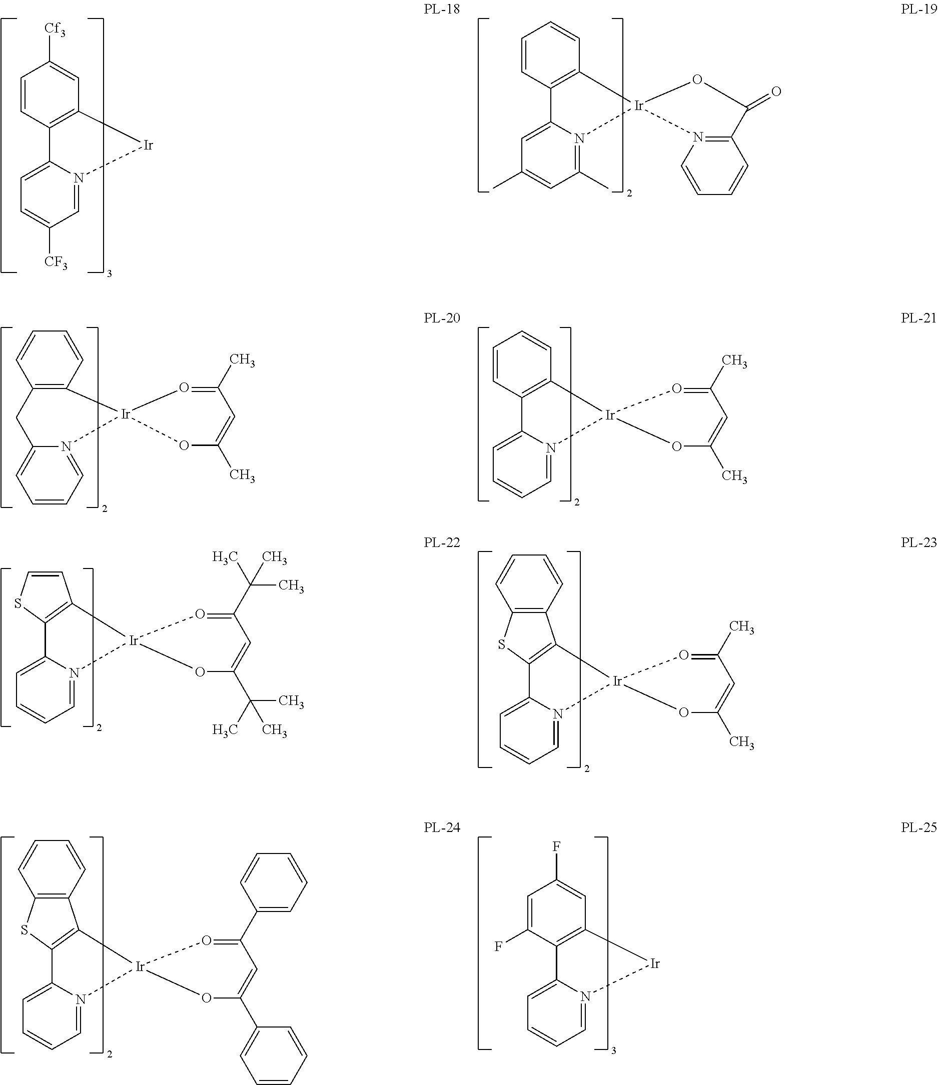

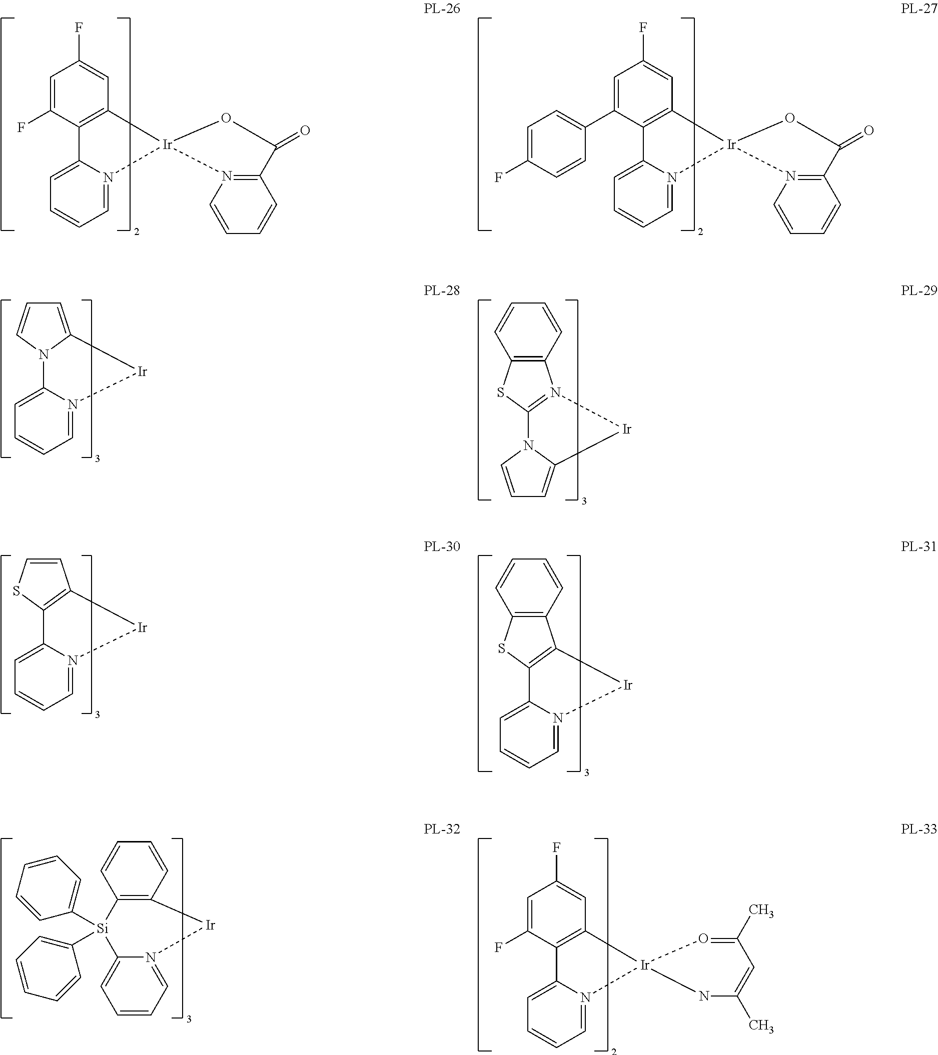

The producing method of the multi-branched structure compound encapsulating the organic electroluminescent light emission material is described below.

In the multi-branched structure compound encapsulating the organic electroluminescent light emission material according to the invention, the organic electroluminescent light emission material is encapsulated in the multi-branched structure compound by mixing them in a solvent. The concentration quenching of in the layer the encapsulated organic electroluminescent light emission material can be inhibited and the efficiency and the life of the light emission can be improved by using the multi-branched structure compound prepared by such the easy method in the organic electroluminescent element.

It is preferable in such the case that the affinity of the organic electroluminescent light emission material to the multi-branched structure compound is higher than that to the solvent. In such the condition, the organic electroluminescent light emission material can be easily encapsulated by the multi-branched structure compound so that the production can be easily carried out.

The method for encapsulating the organic electroluminescent light emission material by the multi-branched structure compound suitable for the use of the invention includes the following two ways.

### (1) Encapsulation in a Uniform Solution

In this method, the multi-branched structure compound and the organic electroluminescent light emission material are dissolved in a solvent meeting the later-mentioned condition and the solution is stirred for carrying out the encapsulating utilizing the affinity difference.

Regarding the solvent, it is important that the solvent can dissolve the both of the above components and the affinity between the multi-branched structure compound and the organic electroluminescent light emission material is higher than that between the organic electroluminescent light emission material and the solvent, and the solvent may be used singly or in combination of plural kinds corresponding to the solubility of each of the multi-branched structure compound and the organic electroluminescent light emission material.

### (2) Encapsulation in a Two Phase System

In this method, the encapsulation is carried out by utilizing the difference between the solubility of the multi-branched structure compound and that of the organic electroluminescent light emission material. The multi-branched structure compound is dissolved in a solvent meeting the later-mentioned condition and the organic electroluminescent light emission material is added into the solution. The encapsulation is progressed between the solid and liquid phases.

As the solvent, one is capable of dissolving only the multi-branched structure compound and not dissolving the organic electroluminescent light emission material is necessary. The solvent may be employed singly or in combination of plural kinds thereof corresponding to the solubility of each of the multi-branched structure compound and the organic electroluminescent light emission material. This method has an advantage that the progression of the reaction can be confirmed by disappearance of the organic electroluminescent light emission material.

Though it cannot be sweepingly decided that which of these methods is to be applied since the suitability of the method is largely depending on the properties of the multi-branched structure compound and the organic electroluminescent light emission material, the method (1) is suitable from the viewpoint of the easiness and time necessary for the operation.

The multi-branched structure compound is preferably contained in the light emitting layer since the light emitting efficiency can be further enhanced though the compound may be contained in any organic layer provided between the cathode and the anode.

In the specification of the present invention, examples of a substituent include: alkyl groups (for example, a methyl group and an ethyl group, a propyl group, an isopropyl group, a tert-butyl group, a pentyl group, a hexyl group, an octyl group, a dodecyl group, a tridecyl group, a tetradecyl group and a pentadecyl group); cycloalkyl groups (for example, a cyclopentyl group and a cyclohexyl group); alkenyl groups (for example, a vinyl group and an allyl group); alkynyl groups (for example, an ethynyl group and a propargyl group); aryl groups including those having a heteroatom (for example, a phenyl group, a naphthyl group, a pyridyl group, a thienyl group, a furyl group and a imidazolyl group); heterocycle groups (for example, a pyrrolidyl group, an imidazolisyl group, a morpholyl group and an oxazolisyl group); alkoxy groups (for example, a methoxy group, an ethoxy group, a propyloxy group, a pentyloxy group, a hexyloxy group, an octyloxy group and a dodecyl oxygroup); cycloalkoxy groups (for example, a cyclopentyloxy group and a cyclohexyloxy group); aryloxy groups including those having a heteroatom (for example, a phenoxy group, a naphthyloxy group, a pyridyloxy group and a thienyloxy group, etc.); alkylthio groups (for example, a methylthio group and an ethylthio group, a propylthio group, a pentylthio group, a hexylthio group, an octylthio group and a dodecylthio group); cycloalkylthio groups (for example, a cyclopentylthio group and a cyclohexylthio group); arylthio groups including those having a heteroatom (for example, a phenylthio group, a naphthylthio group, a pyridylthio group and a thienylthio group); alkoxycarbonyl groups (for example, a methyloxycarbonyl group, an ethyloxycarbonyl group, a butyloxycarbonyl group, an octyloxycarbonyl group and a dodecyloxycarbonyl group); aryloxycarbonyl groups including those having a heteroatom (for example, a phenyloxycarbonyl group, a naphthyloxycarbonyl group, a pyridyloxycarbonyl group and a thienyloxycarbonyl group); amino groups (for example, an amino group, an ethylamino group, a dimethylamino group, a butylamino group, a cyclopentylamino group, a 2-ethylhexylamino group, a dodecylamino group, an anilino group, a naphthylamino group and a 2-pyridylamino group); a fluorine atom; a chlorine atom; fluorohydrocarbon groups (for example, a fluoromethyl group, a trifluoromethyl group, a pentafluoroethyl group and a pentafluorophenyl group); and a cyano group. A plurality of these substituents may further be combined to form a ring or these substituents may be further substituted with the above substituents.

### <<Constituting Layer of Organic EL Element>>

Constituting layer of the organic EL element of the present invention will now be described.

Preferred examples of the constituting layers of the organic EL element of the present invention will be shown below, however, the present invention is not limited thereto.

(1): Anode/Light emitting layer/Cathode
(2): Anode/Light emitting layer/Cathode buffer layer/Cathode
(3): Anode/Anode buffer layer/Light emitting layer/Cathode buffer layer/Cathode
(4): Anode/Hole transport layer/Light emitting layer/Cathode
(5): Anode/Hole transport layer/Light emitting layer/Electron transport layer/Cathode
(6): Anode/Hole transport layer/Light emitting layer/Hole blocking layer/Electron transport layer/Cathode
(7): Anode/Hole transport layer/Electron blocking layer/Light emitting layer/Electron transport layer/Cathode
(8): Anode/Hole transport layer/Electron blocking layer/Light emitting layer/Hole blocking layer/Electron transport layer/Cathode
(9): Anode/Anode buffer layer/Hole transport layer/Electron blocking layer/Light emitting layer/Hole blocking layer/Electron transport layer/Cathode buffer layer/Cathode

### <<Anode>>

For the anode of the organic EL element, a metal, an alloy, or an electroconductive compound each having a high working function (not less than 4 eV), and mixture thereof are preferably used as the electrode material. Specific examples of such an electrode material include a metal such as Au, CuI and a transparent electroconductive material such as indium tin oxide (ITO), SnO₂, or ZnO. A material capable of forming an amorphous and transparent conductive layer such as IDIXO (In₂O₃—ZnO) may also be used. The anode may be prepared by forming a thin layer of the electrode material according to a depositing or spattering method, and by forming the layer into a desired pattern according to a photolithographic method. When required precision of the pattern is not so high (not less than 100 μm), the pattern may be formed by depositing or spattering of the electrode material through a mask having a desired form. When light is emitted through the anode, the transmittance of the anode is preferably 10% or more, and the sheet resistance of the anode is preferably not more than several hundred ohm/sq. The thickness of the layer is ordinarily within the range of from 10 nm to 1 μm, and preferably from 10 to 200 nm, although it may vary due to kinds of materials used.

### <<Cathode>>

On the other hand, for the cathode, a metal (also referred to as an electron injecting metal), an alloy, and an electroconductive compound each having a low working function (not more than 4 eV), and a mixture thereof are used as the electrode material. Specific examples of such an electrode material include sodium, sodium-potassium alloy, magnesium, lithium, a magnesium/copper mixture, a magnesium/silver mixture, a magnesium/aluminum mixture, magnesium/indium mixture, an aluminum/aluminum oxide (Al₂O₃) mixture, indium, a lithium/aluminum mixture, and a rare-earth metal. Among them, a mixture of an electron injecting metal and a metal higher in the working function than that of the electron injecting metal, such as the magnesium/silver mixture, magnesium/aluminum mixture, magnesium/indium mixture, aluminum/aluminum oxide (Al₂O₃) mixture, lithium/aluminum mixture, or aluminum is suitable from the view point of the electron injecting ability and resistance to oxidation. The cathode can be prepared forming a thin layer of such an electrode material by a method such as a deposition or spattering method. The sheet resistance as the cathode is preferably not more than several hundred ohm/sq, and the thickness of the layer is ordinarily from 10 to 1000 nm, and preferably from 50 to 200 nm. It is preferable in increasing the light emission efficiency that either the anode or the cathode of the organic EL element is transparent or semi-transparent. These layers may be provided between the anode and the light emitting layer or the hole transport layer, or between the cathode and the light emitting layer or the hole transport layer, as described above.

### <<Buffer Layer: Cathode Buffer Layer, Anode Buffer Layer>>

As a buffer layer, included are a cathode buffer layer and an anode buffer layer, each of which is provided if necessary.

The buffer layer is a layer provided between the electrode and an organic layer in order to reduce the driving voltage or to improve luminance. As the buffer layer there are a hole injecting layer (an anode buffer layer) and an electron injecting layer (a cathode buffer layer), which are described in “Electrode Material” pages 123-166, Div. 2 Chapter 2 of “Organic EL element and its frontier of industrialization” (published by NTS Corporation, Nov. 30, 1998) in detail.

The anode buffer layer is described in, for example, JP-A Nos. 9-45479, 9-260062, and 8-288069, and its examples include a phthalocyanine buffer layer represented by a copper phthalocyanine layer, an oxide buffer layer represented by a vanadium oxide layer, an amorphous carbon buffer layer, a polymer buffer layer employing and an electroconductive polymer such as polyaniline (emeraldine) and polythiophene. Of these, preferable is a buffer layer employing polydioxythiophene, whereby an organic EL element exhibiting higher luminance, higher luminous efficiency, and longer emission life is obtained.

The cathode buffer layer is described in, for example, JP-A Nos. 6-325871, 9-17574, and 10-74586, in detail, and its examples include a metal buffer layer represented by a strontium layer or an aluminum layer, an alkali metal compound buffer layer represented by a lithium fluoride layer, an alkali earth metal compound buffer layer represented by a magnesium fluoride layer, and an oxide buffer layer represented by an aluminum oxide layer.

The above buffer layer is preferably very thin and has a thickness of preferably from 0.1 to 100 nm depending on kinds of the material used.

The blocking layer is a layer provided if necessary in addition to the fundamental component layers as described above, and is for example a hole blocking layer as described in JP-A Nos. 11-204258, and 11-204359, and on page 237 of “Organic EL element and its frontier of industrialization” (published by NTS Corporation, Nov. 30, 1998).

The cathode buffer layer and the anode buffer layer can be formed by preparing a thin layer using a known method, for example, a vacuum deposition method, a spin coating method, a casting method, an ink-jet method and a LB method.

### <<Blocking Layer: Hole Blocking Layer, Electron Blocking Layer>>

The hole blocking layer is an electron transport layer in a broad sense, and is a material having an ability of transporting electrons, however, an extremely poor ability of transporting holes, which can increase a recombination probability of electrons and holes by transporting electrons while blocking holes.

A hole blocking layer is formed with a compound which has a role to block the positive holes migrated from the hole transport layer from reaching to the cathode and has a role to efficiently convey the electrons injected from the cathode to the light emitting layer. The properties desired for a material forming a hole blocking layer are: high mobility of electrons and low mobility of positive holes, as well as a larger ionization potential or a larger band gap than that of the compound contained in the light emitting layer, in order to efficiently trap positive holes in the light emitting layer. It is advantageous for attaining the effect of the present invention that at least one of the following compounds is employed as a hole blocking material, namely, a styryl compound, a triazole derivative, a phenanthroline derivative, an oxydiazole derivative and a boron derivative.

As other examples, the exemplified compounds disclosed in JP-A Nos. 2003-31367, 2003-31368, and Japanese Patent No. 2721441 are cited.

On the other hand, the electron blocking layer is an hole transport layer in a broad sense, and contains a material having an ability of transporting holes, however, an extremely poor ability of transporting electrons, which can increase a recombination probability of electrons and holes by transporting holes while blocking electrons.

The hole blocking layer and the electron blocking layer can be formed by preparing a thin layer using a known method, for example, a vacuum deposition method, a spin coating method, a casting method, an ink-jet method and a LB method.

### <<Light Emitting Layer>>

The light emitting layer of the present invention is a layer where electrons and holes, injected from electrodes, an electron transport layer or a hole transport layer, are recombined to emit light. The portions where light emits may be in the light emitting layer or at the interface between the light emitting layer and the layer adjacent thereto.

As a light emitting material to be used in the light emission layer, the above described multi-branched structure compounds of the present invention encapsulating an organic luminescence material can be employed, whereby an improved light emission efficiency and an improved emission life are obtained.

Also, as a light emitting material to be used in the light emission layer, in addition to the multi-branched structure compounds of the present invention, a well known fluorescent material or phosphorescent material is applicable.

The light emission of the phosphorescent compound is classified in two types in principle, one is an energy transfer type in which recombination of a carrier occurs on the host to which the carrier is transported to excite the host, the resulting energy is transferred to the phosphorescent compound, and light is emitted from the phosphorescent compound, and the other is a carrier trap type in which recombination of a carrier occurs on the phosphorescent compound which is a carrier trap material, and light is emitted from the phosphorescent compound. However, in each type, energy level of the phosphorescent compound in excited state is lower than that of the host in excited state.

As other examples of a phosphorescent compound used in the present invention is preferably a metal complex containing a metal of Group 8 of the periodic table, and is more preferably an iridium compound, an osmium compound, a platinum compound (a platinum complex) or a rhodium compound a palladium compound and a rare earth compound, and most preferably an iridium compound.

Examples of the phosphorescent compound used in the present invention will be listed below, however, the present invention is not limited thereto. These compounds can be synthesized according to a method described in Inorg. Chem., 40, 1704-1711.

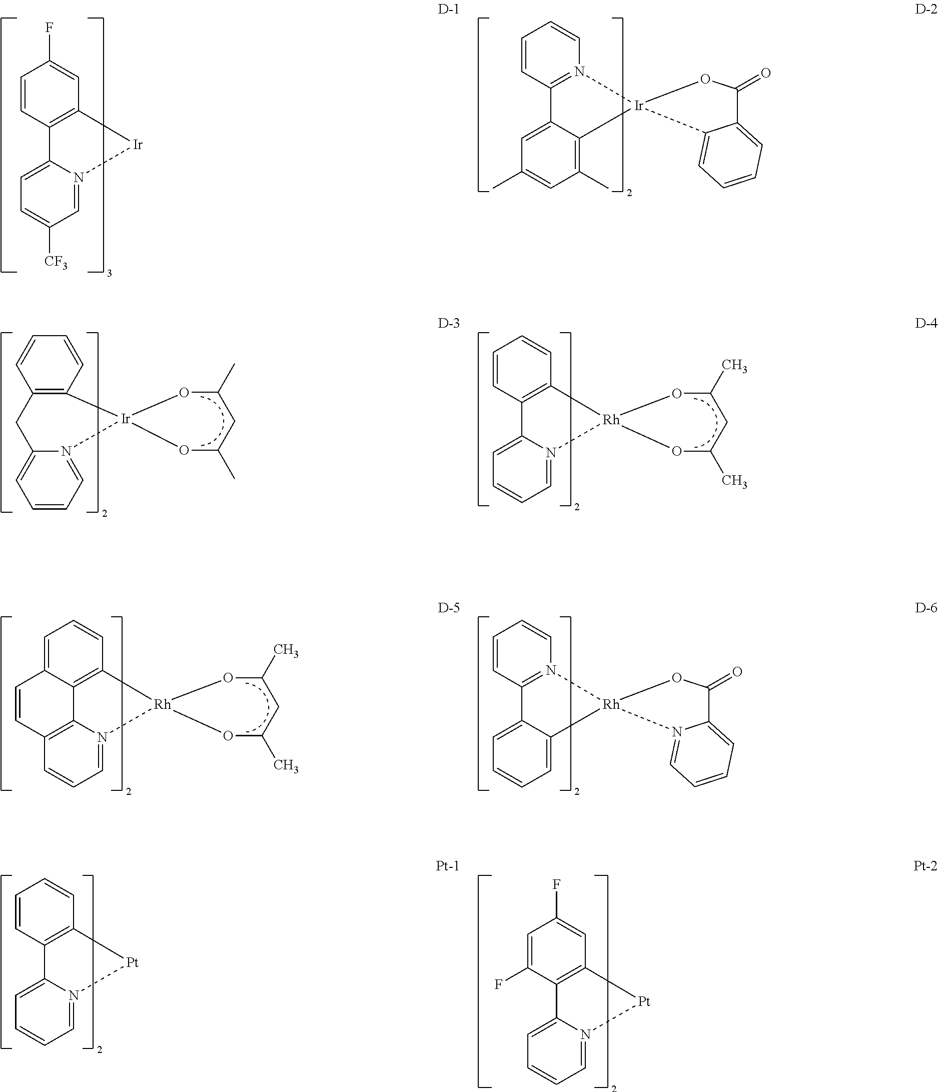

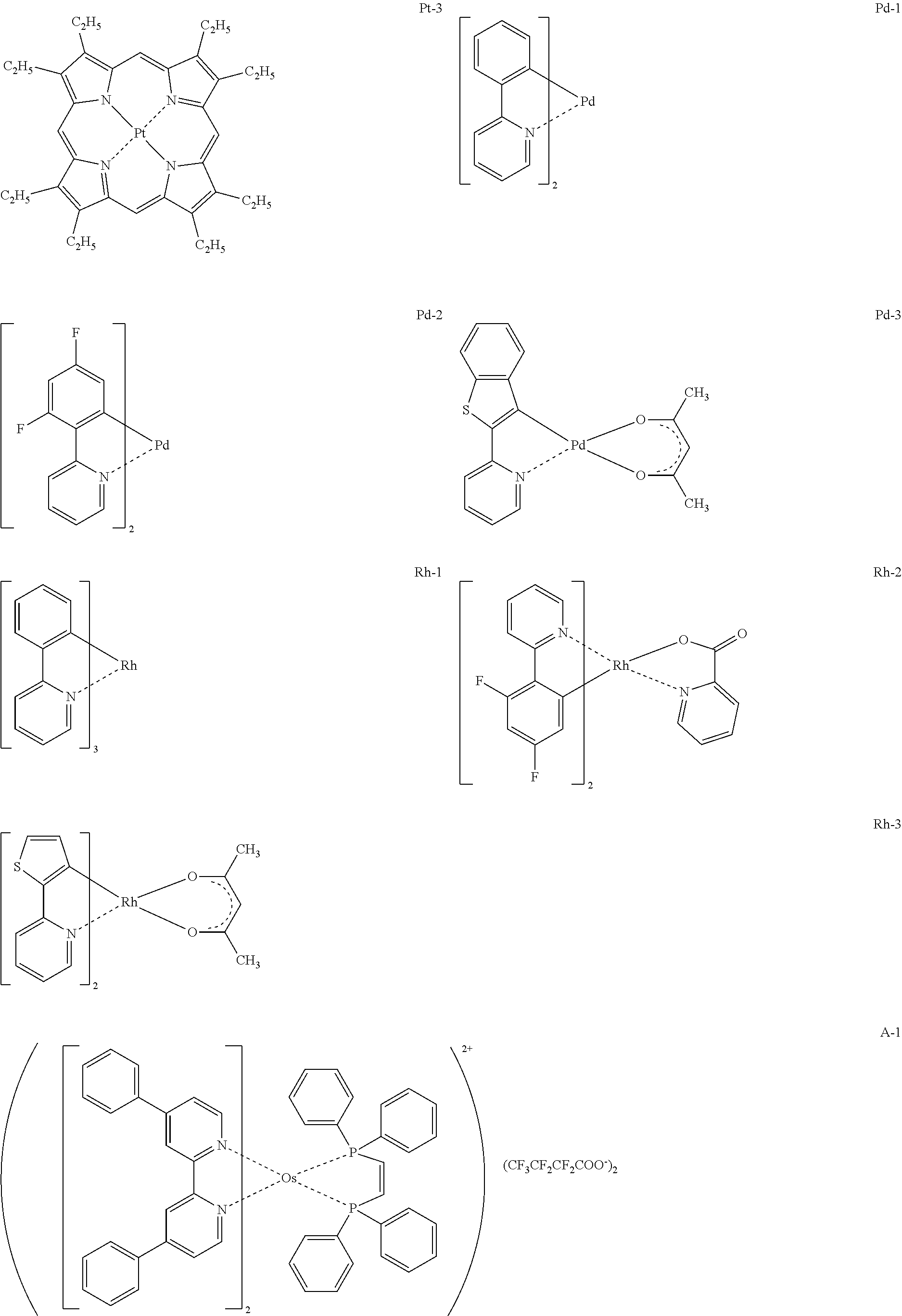

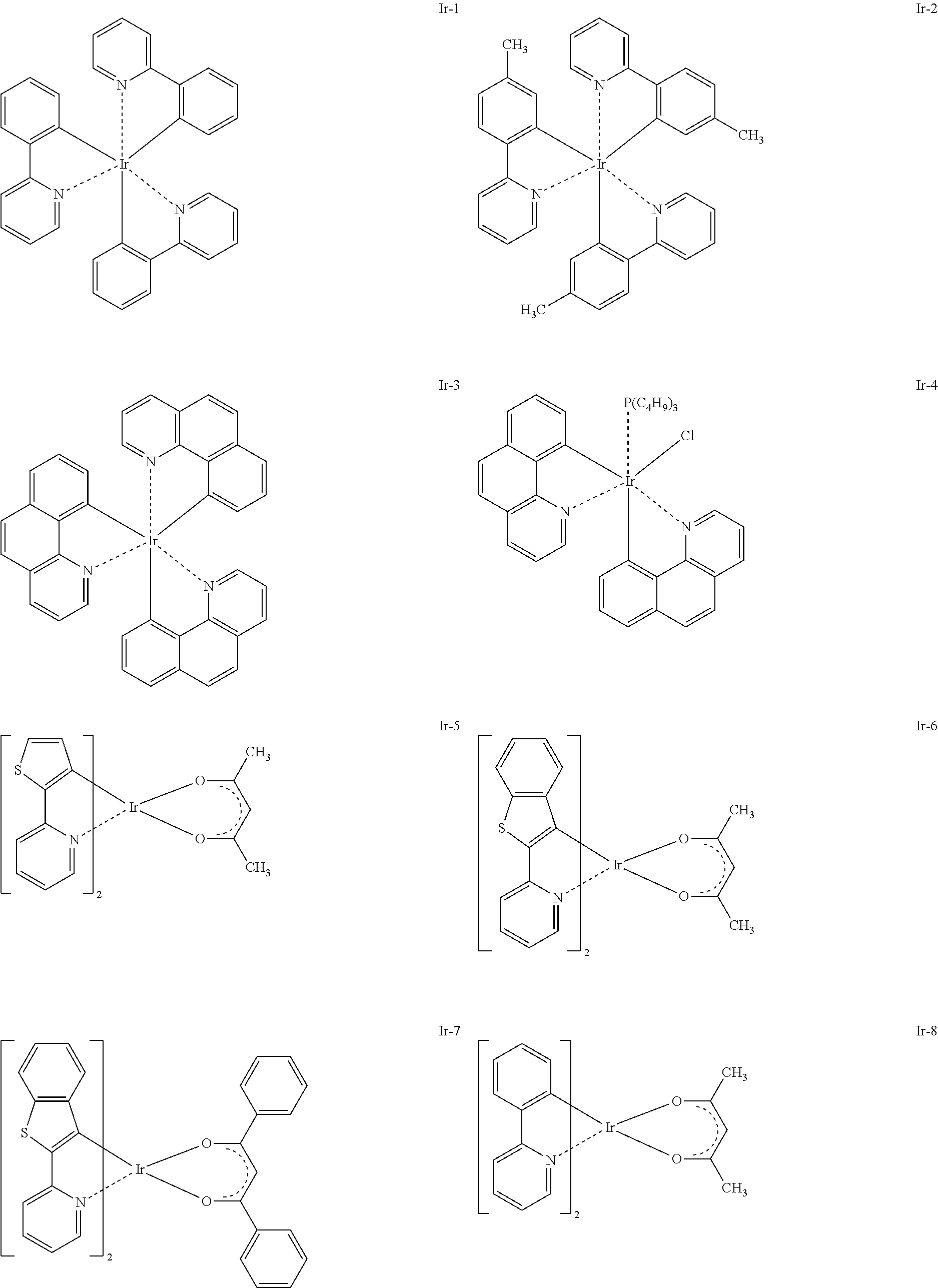

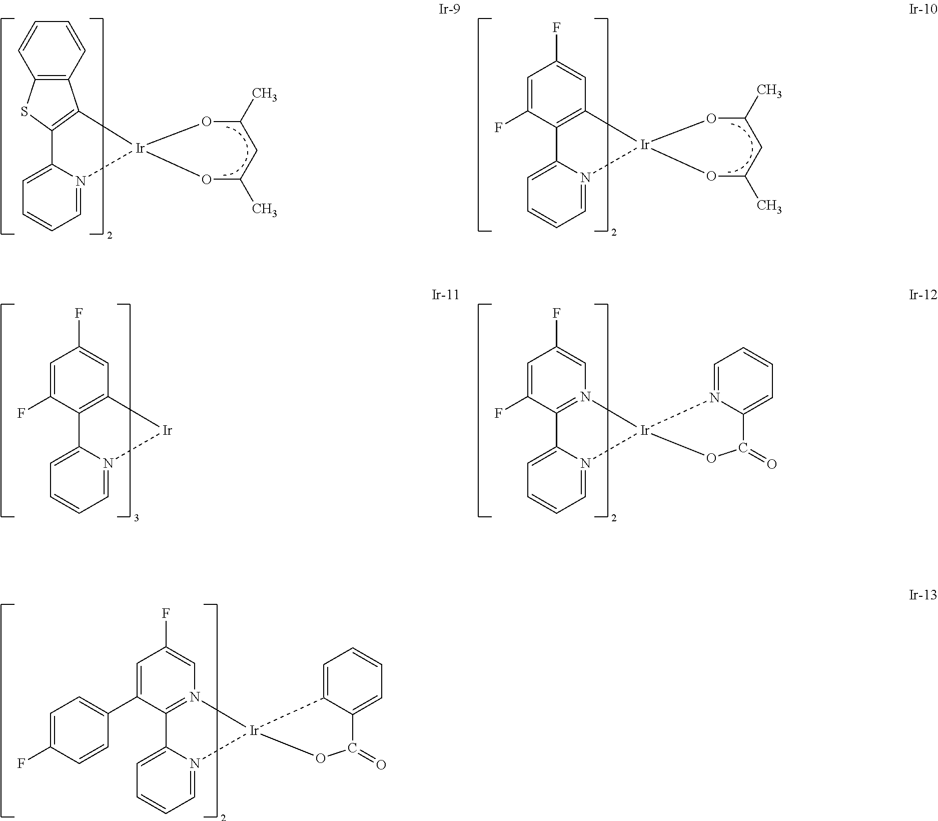

The light emitting layer may further contain a host compound.

In the present invention, the host compound represents a compound among the compounds contained in the light emitting layer, which exhibits a phosphorescent quantum yield of less than 0.01 at an ambient temperature (25° C.).

Known host compounds are applicable as the host compound, and a plurality of known host compounds may be used together. By using a plurality of host compounds, control of electron transfer becomes possible, whereby an organic EL element exhibiting a high efficiency can be obtained.

Among the host compounds known in the art, preferable is a compound having a hole transport ability, an electron transport ability and a high Tg (a glass-transition temperature) value, while preventing elongation of light emission wavelength.

Specific examples of the known host compounds include the compounds disclosed in the following documents:

JP-A No. 2001-257076, No. 2002-308855, No. 2001-313179, No. 2002-319491, No. 2001-357977, No. 2002-334786, No. 2002-8860, No. 2002-334787, No. 2002-15871, No. 2002-334788, No. 2002-43056, No. 2002-334789, No. 2002-75645, No. 2002-338579, No. 2002-105445, No. 2002-343568, No. 2002-141173, No. 2002-352957, No. 2002-203683, No. 2002-363227, No. 2002-231453, No. 2003-3165, No. 2002-234888, No. 2003-27048, No. 2002-255934, No. 2002-260861, No. 2002-280183, No. 2002-299060, No. 2002-302516, No. 2002-305083, No. 2002-305084, No. 2002-308837.

The light emitting layer may contain a host compound having a fluorescence maximum wavelength as a host compound. In this case, by a energy transfer from other host compound or a phosphorescent compound to a fluorescent compound, light emission from a host compound having a fluorescence maximum wavelength is obtained as the result of electroluminescence of an organic EL element. Preferable as a host compound having a fluorescence maximum wavelength is a compound having a high fluorescence quantum yield in the form of solution. Herein, the fluorescence quantum yield is preferably not less than 10%, and more preferably not less than 30%. Examples of the a host compound having a wavelength providing a fluorescence maximum wavelength include: a coumarin dye, cyanine dye, a chloconium dye, a squalenium dye, an oxobenzanthracene dye, a fluorescene dye, a rhodamine dye, pyrylium dye, a perylene dye, a stilbene dye, and a polythiophene dye. The fluorescence quantum yield can be measured according to a method described in the fourth edition, Jikken Kagaku Koza 7, Bunko II, p. 362 (1992) published by Maruzen.

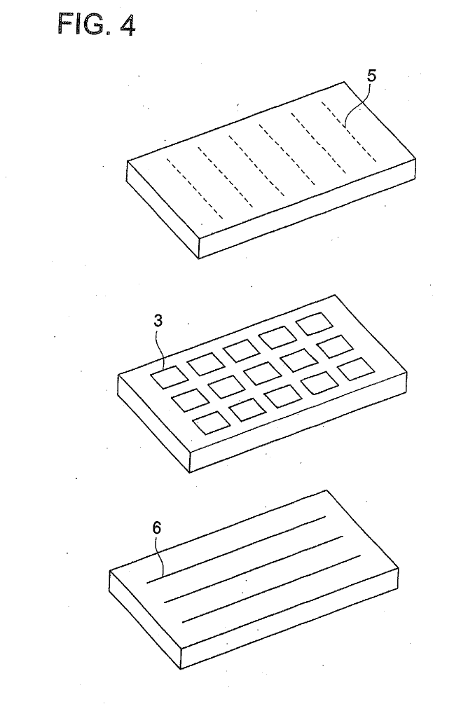

Color of light emitted from the organic EL element or the compound of the present invention is measured by a spectral light meter CS-1000, manufactured by Minolta Co., Ltd., and expressed according to CIE chromaticity diagram described in FIG. 4.16 on page 108 of “Shinpen Shikisai Kagaku Handbook” (Coloring Science Handbook, New Edition), edited by Nihon Shikisai Gakkai, published by Todai Shuppan Kai, 1985.

In the present invention, preferable is to use, as the light emitting material for the light emission layer, a multi-branched structure compound containing a phosphorescent compound as the light emitting material for the organic electroluminescent element to be encapsulated in the multi-branched structure compound of the present invention, whereby the light emission efficiency can be further improved.

When the above described multi-branched structure compound is used as a light emitting material, the maximum wavelength of the phosphorescent emission of the phosphorescent compound is preferably in the range of 380-480 nm. Organic EL elements emitting blue light or white light are cited as examples which have such a phosphorescent emission wavelength. Further, by employing a plurality of multi-branched structure compounds encapsulating phosphorescent compounds having different emission wavelengths, in a light emitting layer, an arbitrary color of light can be obtained. Emission of white light is possible, by adjusting kinds of phosphorescent compounds and amounts of multi-branched structure compounds, whereby application of such an organic EL element to an illuminating device or to a backlight becomes possible.

When white light is emitted in an organic EL element by mixing three primary colors of R (red), G (green) and B (blue), white light cannot be obtained merely by mixing emission compounds correspond to each of RGB according to the chromatic coordinates. The reason is as follows: Since, the excited energy levels of the three primary colors decrease in the order of blue, green and red, the energy transfers from blue to green which has a lower energy level than that of blue, and, further, transfers from green to red. As the result, only the emission of red color having the lowest energy level occurs. However, the energy transfer depends on the distances among molecules, namely, on the concentration. Accordingly, it has been known that emission of white light becomes possible by lowering the total concentration of dopants and, further, by increasing the concentration of a higher energy dopant compared to the concentration of a lower energy dopant, since the energy transfer becomes more difficult. As described above, there have been severe limitations on the total concentration of the dopants and the concentration of each of the RGB colors, when white light is emitted using the conventional light emission materials, which has been a big disturbance to obtain improved luminance and emission efficiency.

However, by employing the multibranched structure compounds of the present invention each encapsulating a light emission material, it has become unnecessary to apply gradient to dope concentrations of the colors as has been carried out so far, since the contact of the light emission dyes of the RGB colors is prevented in the light emission layer, whereby the energy transfer becomes more difficult. Also, improvement in luminance and emission efficiency become possible, since the concentration quenching effect is suppressed and the dopant concentration of each color can be increased.

The light emitting layer can be formed by using a film forming method known in the art, for example, a vacuum deposition method, a spin-coating method, a casting method, an LB method or an ink-jet method.

The light emitting layer is preferably formed by a coating method using the multi-branched structure compound of the present invention. Specifically, the multi-branched structure compound of the present invention is suitable for coating with a spin-coating method or an ink-jet coating method. These methods are preferable, because these makes the production process easier, specifically, makes the production process of a large screen organic EL device or a white light emitting organic EL element easier.

The thickness of the light emitting layer is not specifically limited, however, it is usually 5 nm to 5 μm, and preferably 5 nm to 200 nm.

### <<Hole Transport Layer>>

The hole transport layer is constitute of a material having a function of transporting positive holes. In a broad sense, a hole injection layer and an electron blocking layer is included in the hole transport layer. The hole transport layer or an electron transport may be provided as a single layer or as a plurality of layers.

The hole transport material is not specifically limited, and employable are the materials arbitrarily selected from those including known materials in the art as: positive hole injecting-transporting materials among photo conductive materials and materials used as a hole injecting layer or a hole transport layer in EL elements

In the present invention, as a hole transport material, preferable is a polymer containing at least one of the repeat units represented by Formula (2), wherein X represents a hole transport group, whereby higher luminance, higher luminous efficiency, longer emission life and more reduced driving power consumption are attained.

Other examples of a hole transport material include: a triazole derivative, an oxadiazole derivative, an imidazole derivative, a polyarylalkane derivative, a pyrazoline derivative and a pyrazolone derivative, a phenylenediamine derivative, an arylamine derivative, an amino substituted chalcone derivative, an oxazole derivative, a styryl anthracene derivative, a fluorenone derivative, a hydrazone derivative, a stilbene derivative, a silazane derivative, an aniline copolymer, and an oligomer of as electroconductive polymer, and specifically a thiophene oligomer.

As the hole transport material, those described above are used, however, a porphyrin compound, an aromatic tertiary amine compound or a styrylamine compound is preferably used, and, specifically, an aromatic tertiary amine compound is more preferably used.

Typical examples of the aromatic tertiary amine compound and styrylamine compound include: N,N,N′,N′-tetraphenyl-4,4′-diaminophenyl; N,N′-diphenyl-N,N′-bis(3-methylphenyl)-[1,1′-biphenyl]-4,4′-diamine (TPD); 2,2-bis(4-di-p-tolylaminophenyl)propane; 1,1-bis(4-di-p-tolylaminophenyl)cyclohexane; N,N,N′,N′-tetra-p-tolyl-4,4′-diaminobiphenyl; 1,1-bis(4-di-p-tolylaminophenyl)-4-phenylcyclohexane; bis(4-dimethylamino-2-methylphenyl) phenylmethane; bis(4-di-p-tolylaminophenyl)phenylmethane; N,N′-diphenyl-N,N′-di(4-methoxyphenyl)-4,4′-diaminobiphenyl; N,N,N′,N′-tetraphenyl-4,4′-diaminodiphenylether; 4,4′-bis(diphenylamino)quardriphenyl; N,N,N-tri(p-tolyl)amine; 4-(di-p-tolylamino)-4′-[4-(di-p-tolylamino)styryl]stilbene; 4-N,N-diphenylamino-(2-diphenylvinyl)benzene; 3-methoxy-4′-N,N-diphenylaminostylbene; N-phenylcarbazole; compounds described in U.S. Pat. No. 5,061,569 which have two condensed aromatic rings in the molecule thereof such as 4,4′-bis[N-(1-naphthyl)-N-phenylamino]biphenyl (NPD); and compounds described in JP-A No. 4-308688 such as 4,4′,4″-tris[N-(3-methylphenyl)-N-phenylamino]-triphenylamine (MTDATA) in which three triphenylamine units are bonded in a starburst form.

A polymer in which the material mentioned above is introduced in the polymer chain or a polymer having the material as the polymer main chain can be also used.

As the hole injecting material or the hole transport material, inorganic compounds such as p-Si and p-SiC are also usable.

In the present invention, the hole transport material in the hole transport layer preferably has a phosphorescent maximum wavelength of 415 nm or less, namely the hole transport material is preferably a material which prevents elongation of the wavelength of emitting light and has a higher Tg, while having a hole transport ability.

The hole transport layer can be formed by preparing a thin layer of the hole transport material using a known method such as a vacuum deposition method, a spin coat method, a casting method, an ink jet-method, and an LB method. The thickness of the hole transport layer is not specifically limited, however, it is ordinarily from 5 to 5000 nm. The hole transport layer may be composed of a single layer structure containing one or more of the materials mentioned above.

### <<Electron Transport Layer>>

The electron transport layer contains a material having an electron transporting ability, and in a broad sense an electron injecting layer or a hole blocking layer are included in an electron transport layer. The electron transport layer can be provided as a single layer or plural layers.

An electron transport material used in a single electron transport layer or in an electron transport layer provided adjacent to the light emitting layer on the cathode side surface when used in a plural layer construction, can be optionally selected from known compounds used in an electron transport layer.

In the present invention, as an electron transport material, preferable is a polymer containing at least one of the repeat units represented by Formula (2), wherein X represents an electron transport group, whereby higher luminance, higher luminous efficiency, longer emission life and more reduced driving power consumption are attained.

Other examples of a material used in the electron transport layer include a nitro-substituted fluorene derivative, a diphenylquinone derivative, a thiopyran dioxide derivative, carbodiimide, a fluolenylidenemethane derivative, anthraquinodimethane, an anthrone derivative, and an oxadiazole derivative. Further usable as the electron transport material are: a thiadiazole derivative which is formed by substituting the oxygen atom in the oxadiazole ring of the foregoing oxadiazole derivative with a sulfur atom, and a quinoxaline derivative having a quinoxaline ring known as an electron withdrawing group. These electron transport materials are also preferably usable as an electron transport group described above to obtain the effect of the present invention.

An electron transport layer is usable while it has a function to transport electrons injected from the cathode to the light emitting layer, materials of which can be optionally selected from the compounds known in the art.

A polymer in which the material mentioned above is introduced in the polymer chain or a polymer having the material as the polymer main chain can be also used.

A metal complex of an 8-quinolynol derivative such as aluminum tris(8-quinolynol) (Alq), aluminum tris(5,7-dichloro-8-quinolynol), aluminum tris(5,7-dibromo-8-quinolynol), aluminum tris(2-methyl-8-quinolynol), aluminum tris(5-methyl-8-quinolynol), or zinc bis(8-quinolynol) (Znq), and a metal complex formed by replacing the central metal of the foregoing complexes with another metal atom such as In, Mg, Cu, Ca, Sn, Ga or Pb, can be used as the electron transport material. Furthermore, a metal free or metal-containing phthalocyanine, and a derivative thereof, in which the molecular terminal is replaced by a substituent such as an alkyl group or a sulfonic acid group, are also preferably used as the electron transport material. The distyrylpyrazine derivative exemplified as a material for the light emitting layer may preferably be employed as the electron transport material. An inorganic semiconductor such as n-Si and n-SiC may also be used as the electron transport material in a similar way as in the hole injecting layer or in the hole transport layer.

In the present invention, the electron transport material in the electron transport layer preferably has a phosphorescent maximum wavelength of 415 nm or less, namely the hole transport material is preferably a material which prevents elongation of the wavelength of emitting light and has a higher Tg, while having an electron transport ability.

The electron transport layer can be formed by preparing a thin layer of the above described electron transport material using a known method such as a vacuum deposition method, a spin coat method, a casting method, a printing method including an ink-jet method or an LB method. The thickness of the electron transport layer is not specifically limited, however, it is ordinarily from 5 to 5000 nm. The electron transport layer may be composed of a single layer containing one or more of the electron transport material.

### <<Substrate (Also Referred to as Base Plate, Base or Support)>>

The substrate employed for the organic electroluminescent element of the present invention is not specifically limited such as to glasses or plastics, and there is no limitation provided that it is transparent. Examples of the substrate preferably used include: glass, quartz and light transmissible resin film. Specifically preferred is a resin film capable of providing flexibility to the organic EL element.

Examples of the resin film include films of, for example, polyethylene terephthalate (PET), polyethylene naphthalate (PEN), polyethersulfone (PES), polyetherimide, polyetheretherketone, polyphenylene sulfide, polyarylate, polyimide, polycarbonate (PC), cellulose triacetate (TAC) or cellulose acetate propionate (CAP).

The surface of the resin film may have a layer of an inorganic or organic compound or a hybrid layer of both compounds.

The external light emission efficiency of the organic electroluminescent element of the present invention is preferably not less than 1%, and more preferably not less than 2% at room temperature. Herein, external quantum yield (%) is represented by the following formula:

External quantum yield (%)={(the number of photons emitted to the exterior of the organic electroluminescent element)/(the number of electrons supplied to the organic electroluminescent element)}×100

A hue improving filter such as a color filter may be used in combination.

The multi-color display of the present invention contains at least two organic EL elements exhibiting different emission maximum wavelengths. Preferable examples of preparation methods of an organic EL elements will now be explained.

### <<Preparation of Organic EL Element>>

For one example, the preparation of the organic EL element, which has the following constitution will be described: Anode/Anode buffer layer/Hole transport layer/Light emitting layer/Electron transport layer/Cathode buffer layer/Cathode.

A thin layer of a desired material for an electrode such as a material of the anode is formed on a suitable substrate by a deposition or sputtering method to prepare the anode, so that the thickness of the layer is not more than 1 μm, and preferably within the range of from 10 to 200 nm. Then the anode buffer layer, the hole transport layer, the light emitting layer, the electron transport layer and the cathode buffer layer, which constitute the organic EL element, are formed on the resulting anode as organic compound thin layers.

As methods for formation of the thin layers, as the same as described above, there are a spin coat method, a casting method, an ink jet method, a vacuum deposition method, a printing method and a spray method, however, a vacuum deposition method, a spin coating method, an ink jet method and a spray method are specifically preferably used, since a uniform layer without a pinhole can be formed. Different methods may be used for formation of different layers. When the vacuum deposition method is used for the thin layer formation method, although conditions of the vacuum deposition differs due to kinds of materials used, the condition of vacuum deposition is preferably selected in the following ranges: a boat temperature of from 50 to 450° C., a degree of vacuum of from 10⁻⁶ to 10⁻² Pa, a deposition speed of from 0.01 to 50 nm/second, a substrate temperature of from −50 to 300° C. and a layer thickness of from 0.1 nm to 5 μm.

After these layers has been formed, a thin layer of a material for a cathode is formed thereon to prepare the cathode, employing, for example, a vacuum deposition method or sputtering method to give a thickness of not more than 1 μm, and preferably from 50 to 200 nm. Thus, a desired organic EL element is obtained. It is preferred that the layers from the hole injecting layer to the cathode are continuously formed under one time of vacuuming to obtain an organic EL element. However, on the way of the layer formation under vacuum, a different layer formation method by taking the layer out of the vacuum chamber may be inserted. When the different method is used, the process is required to be carried out under a dry inert gas atmosphere.

In the multicolor display of the present invention, the light emitting layer only is formed using a shadow mask, and the other layers, besides the light emitting layer, are formed all over the substrate employing a vacuum deposition method, a casting method, a spin coat method, an ink-jet method or a printing method, in which patterning employing the shadow mask is not required.

When pattering is carried out only for the light emitting layer, the method is not limited, however, preferable are a vacuum deposition method, an ink-jet method and a printing method. When a vacuum deposition method is used, the pattering is preferably carried out using a shadow mask.

Further, the organic EL element can be prepared in the reverse order, in which the cathode, the cathode buffer layer, the electron transport layer, the light emitting layer, the hole transport layer, the anode buffer, and the anode are formed in that order.

When a direct current voltage, a voltage of 2 to 40 V is applied to thus obtained multicolor display, setting the anode as a + polarity and the cathode as a − polarity, light emission occurs. When the voltage is applied with the reverse polarity, no current flow occurs and no light emission is observed. When an alternating current is applied, light emission is observed only when + polarity is applied to the anode and − polarity is applied to the cathode. Arbitrary wave shape of alternating current may be used.

The display of the present invention, containing the organic EL element of the present invention, can be used as a display device, a display, or various light emission sources. The display device or the display, which employs three kinds of organic EL elements emitting a blue light, a red light and a green light can present a full color image.

Examples of the display device or the display include a television, a personal computer, a mobile device, an AV device, a display for text broadcasting, and an information display used in a car. The display device may be used as specifically a display for reproducing a still image or a moving image. When the display device is used as a display for reproducing a moving image, the driving method may be either a simple matrix (passive matrix) method or an active matrix method.

The illuminator of the present invention, containing the organic EL element of the present invention, can emit white light by selecting phosphorescent compounds. Examples of an illuminator include a home lamp, a room lamp in a car, a backlight for a watch or a liquid crystal, a light source for boarding advertisement, a signal device, a light source for a photo memory medium, a light source for an electrophotographic copier, a light source for an optical communication instrument, and a light source for an optical sensor, however, are not limited-thereto.

The organic EL element of the present invention may be an organic EL element having a resonator structure.

The organic EL element having a resonator structure is applied to a light source for a photo-memory medium, a light source for an electrophotographic copier, a light source for an optical communication instrument, or a light source for a photo-sensor, however, its application is not limited thereto. In the above application, a laser oscillation may be carried out.

The organic EL element of the present invention can be applied as a lamp, for example, an illuminator or a developing light, as described above, or as a projection device which projects an image, or a display device by which a still image or a moving image is directly visible. When the display device is used as a display for reproducing a moving image, the driving method may be either a simple matrix (passive matrix) method or an active matrix method. A full color display device can be prepared by using three or more kinds of organic EL elements of the present invention having different emitting colors, or by changing the color of one kind of emission, for example white emission, using color filters to form RGB colors. When the color of an organic EL element is changed into different colors using color filters to obtain a full color image, λmax of the organic EL element is preferably 480 nm or less.

One example of the display containing the organic EL element of the present invention will be explained below employing Figures.

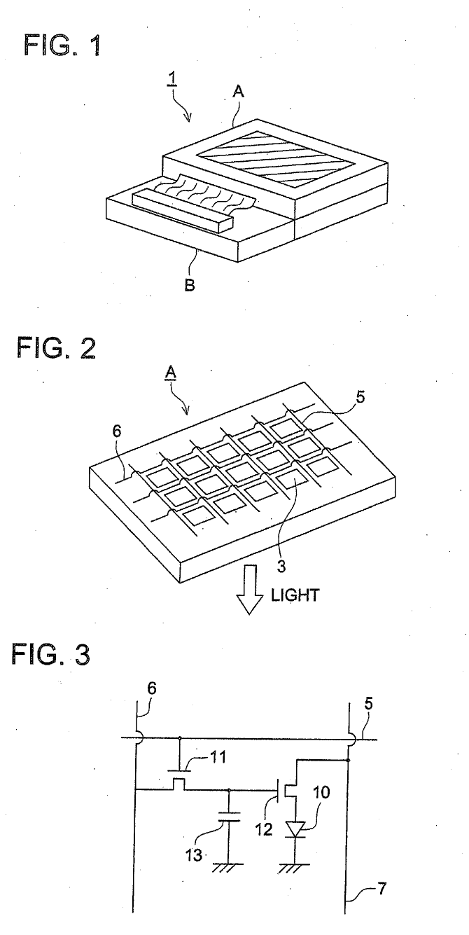

FIG. 1 is a schematic drawing of one example of a display containing an organic EL element. FIG. 1 is a display such as that of a cellular phone, displaying image information due to light emission from the organic EL.

A display 1 contains a display section A having plural pixels and a control section B carrying out image scanning based on image information to display an image in the display section A.

The control section B is electrically connected to the display section A, transmits a scanning signal and an image data signal to each of the plural pixels based on image information from the exterior, and conducts image scanning which emits light from each pixel due to the scanning signal according to the image data signal, whereby an image is displayed on the display section A.

FIG. 2 is a schematic drawing of a display section A.

The display section A contains, on a substrate, plural pixels 3, and a wiring section containing plural scanning lines 5 and plural data lines 6. The main members of the display section A will be explained below. In FIG. 2, light emitted from pixels 3 to the direction of the arrow (downward) is illustrated.

The plural scanning lines 5 and plural data lines 6 of the wiring section each are composed of an electroconductive material, the lines 5 and the lines 6 being crossed with each other at a right angle, and connected with the pixels 3 at the crossed points (not illustrated).

The plural pixels 3, when the scanning signal is applied from the scanning lines 5, receive the data signal from the data lines 6, and emit light corresponding to the image data received. Provision of red light emitting pixels, green light emitting pixels, and blue light emitting pixels side by side on the same substrate makes it possible to display a full color image.

Next, an emission process of pixels will be explained.

FIG. 3 is a schematic drawing of a pixel.

The pixel contains an organic EL element 10, a switching transistor 11, a driving transistor 12, and a capacitor 13. When a pixel with a red light emitting organic EL element, a pixel with a green light emitting organic EL element, and a pixel with a blue light emitting organic EL element are provided side by side on the same substrate, a full color image can be displayed.

In FIG. 3, an image signal from the control section B is applied to the drain of a switching transistor 11 through a data line 6, and a scanning signal from the control section B is applied to the gate of the switching transistor 11, then the switching transistor 11 is turned on and the image data applied to the drain of the switching transistor 11 is transmitted to the capacitor 13 and the gate of the driving transistor 12.

The capacitor 13 is charged according to the electric potential of the image data signal transmitted, and the driving transistor 12 is switched on. In the driving transistor 12, the drain is connected to an electric source line 7, and the source to an organic EL element 10. Current is supplied from the electric source line 7 to the organic EL element 10 according to the electric potential of the image data signal applied to the gate.

The scanning signal is transmitted to the next scanning line 5 according to the successive scanning of the control section B, the switching transistor 11 is switched off. Even if the switching transistor 11 is switched off, the driving transistor 12 is turned on since the capacitor 13 maintains a charged potential of image data signal, and light emission from the organic EL element 10 continues until the next scanning signal is applied. When the next scanning signal is applied according the successive scanning, the driving transistor 12 works according to an electric potential of the next image data signal synchronized with the scanning signal, and light is emitted from the organic EL element 10.

Namely, light is emitted from the organic EL element 10 in each of the plural pixels 3 due to the switching transistor 11 as an active element and the driving transistor 12 each being provided in the organic EL element 10 of each of the plural pixels 3. This emission process is called an active matrix process.

Herein, light emission from the organic EL element 10 may be emission with plural gradations according to image signal data of multiple value having plural gradation potentials, or emission due to on-off according to a binary value of the image data signals.

The electric potential of the capacitor 13 may maintain till the next application of the scanning signal, or may be discharged immediately before the next scanning signal is applied.

In the present invention, light emission may be carried out employing a passive matrix method as well as the active matrix method as described above.

FIG. 4 is a schematic drawing of a display employing a passive matrix method. In FIG. 4, pixels 3 are provided between the scanning lines 5 and the data lines 6, crossing with each other.

When a scanning signal is applied to scanning line 5 according to successive scanning, pixel 3 connecting the scanning line 5 emits light according to the image data signal. The passive matrix method has no active element in the pixel 3, which reduces manufacturing cost of a display.

### EXAMPLES

The present invention will now be explained in detail using examples, however the present invention is not limited thereto.

### Example 1

### Preparation and Evaluation of Organic EL Elements 1-1 to 1-13

### (1) Preparation of Multi-Branched Structure Compound Encapsulating Organic Electroluminescent Material

In 1 ml of THF, 0.2 mmol (1.3 g) of a multi-branched structure compound (multi-branched structure compound D-17, core linkage group C-10) and 1 mmol (0.13 g) of organic electroluminescent material PL-14 were dissolved, followed by slowly adding 50 ml of methanol so as not to cause precipitation. The solution was agitated at an ambient temperature for 24 hours. From the first fraction of the separation-purification process using a column of Sephadex-G25 (produced by Aldrich) wherein methanol was used as the eluent, multi-branched structure compound PD-7 encapsulating PL-14 (1.41 g) was obtained. The encapsulation of light emitting material PL-14 in the multi-branched structure compound was confirmed by the observation of the phosphorescent emission of PD-7 and by means of ICP-mass spectroscopy. Multi-branched structure compounds PD-1 to PD-6 and PD-8 to PD-13 were prepared in the similar manner.

TABLE 1

| | | |
|---|---|---|
| Multi-Branched | Multi-Branched Structure | Light Emitting |
| Structure | Compound | Material for |

| Compound for | Structure of | Structure of | Organic EL |
|---|---|---|---|
| Encapsulation | Branch | Core | Element |
| PD-1 | D-1 | C-2 | FL-2 |
| PD-2 | D-30 | C-5, n = 1 | FL-2 |
| PD-3 | D-34 | C-5, n = 1 | FL-6 |
| PD-4 | D-1 | C-5, n = 1 | PL-14 |
| PD-5 | D-7(G3) | C-11 | PL-14 |
| PD-6 | D-13 | C-11 | PL-14 |
| PD-7 | D-17 | C-10 | PL-14 |
| PD-8 | D-17 | C-10 | PL-33 |
| PD-9 | D-17 | C-10 | PL-23 |
| PD-10 | D-21, n = 1 | C-9 | PL-14 |
| PD-11 | D-28 | C-8 | PL-14 |
| PD-12 | D-30 | C-5, n = 1 | PL-14 |
| PD-13 | D-34 | C-8 | PL-14 |

### (2) Preparation of Organic EL Elements 1-1 to 1-13

A pattern was formed on a substrate (100 mm×100 mm×1.1 mm) composed of a glass plate and a 100 nm ITO (indium tin oxide) layer (NA-45 manufactured by NH Technoglass Co., Ltd.) as an anode. Then the resulting transparent substrate having the ITO transparent electrode was subjected to ultrasonic washing in i-propyl alcohol and dried by a dry nitrogen gas and subjected to UV-ozone cleaning for 5 minutes. On the transparent substrate, a solution of 30 mg of polyvinylcarbazole (PVK) and 1.0×10⁻⁴ mmol/1 mg PVK of PL-14 dissolved in 1 ml of dichlorobenzene was spin coated under a condition of 1000 rpm for 5 sec (thickness of about 100 nm), followed by drying at 60° C. for 1 hour under vacuum, to obtain a light emission layer.

Thus obtained transparent substrate was fixed in a vacuum evaporation apparatus. The vacuum chamber was evacuated to 4×10⁻⁴ Pa, and 0.5 nm of lithium fluoride as the cathode buffer layer and 110 nm of aluminum as the cathode were deposited. Finally, the element was sealed by glass to obtain Organic EL Element 2-1.

Organic EL Elements 1-2 to 1-13 were prepared in the same manner as Organic EL Element 1-1 except that PVK and PL-14 used in the light emission layer of Organic EL Element 1-1 were replaced with the materials shown in Table 2.

TABLE 2

| Organic EL Element | Light Emitting Layer | Remarks |
|---|---|---|
| 1 | PVK/PL-14 | Comparative |
| 2 | PVK/FL-2 | Comparative |
| 3 | PVK/PD-4 | Inventive |
| 4 | PVK/PD-5 | Inventive |
| 5 | PVK/PD-6 | Inventive |
| 6 | PVK/PD-7 | Inventive |
| 7 | PVK/PD-10 | Inventive |
| 8 | PVK/PD-11 | Inventive |
| 9 | PVK/PD-12 | Inventive |
| 10 | PVK/PD-13 | Inventive |
| 11 | PVK/PD-1 | Inventive |
| 12 | PVK/PD-2 | Inventive |
| 13 | PVK/PD-3 | Inventive |

### <Evaluation of Organic EL Elements 1-1 to 1-13>

The following evaluations were carried out on thus obtained Organic EL Elements 1-1 to 1-13.

### (External Quantum Efficiency)

Electric current of 2.5 mA/cm² was supplied to each of the prepared organic EL elements at 23° C. in an atmosphere of a dry nitrogen gas, and the external quantum efficiency (%) of each sample was measured. Spectral radiance meter CS-1000 produced by Minolta was used for the measurement.

### (Emission Life)

Electric current of 2.5 mA/cm² was supplied to each sample at 23° C. in an atmosphere of a dry nitrogen gas, and measured was the duration in which the luminance of each sample decreased to half of the initial luminance, which was designated as the half life of emission (τ0.5) and used as an index of emission life. Spectral radiance meter CS-1000 produced by Minolta was used for the measurement.

The values of measured external quantum efficiency and emission life for each of Organic EL Elements 1-1 and 1-3 to 1-10 were listed in Table 3 as relative values when each value of Organic EL Element 1-1 was set to 100. The values of measured external quantum efficiency and emission life for each of Organic EL Elements 1-2 and 1-11 to 1-13 were listed in Table 4 as relative values when each value of Organic EL Element 1-2 was set to 100.

TABLE 3

| | External | Emission | |
|---|---|---|---|
| Organic EL | Quantum Yield | Life | |
| Element | (Relative Value) | (Relative Value) | Remarks |
| 1 | 100 | 100 | Comparative |
| 3 | 215 | 635 | Inventive |
| 4 | 143 | 600 | Inventive |
| 5 | 161 | 540 | Inventive |
| 6 | 189 | 781 | Inventive |
| 7 | 139 | 590 | Inventive |
| 8 | 190 | 621 | Inventive |
| 9 | 217 | 582 | Inventive |
| 10 | 156 | 440 | Inventive |

TABLE 4

| | External | Emission | |
|---|---|---|---|
| Organic EL | Quantum Yield | Life | |
| Element | (Relative Value) | (Relative Value) | Remarks |
| 2 | 100 | 100 | Comparative |
| 11 | 200 | 579 | Inventive |
| 12 | 191 | 600 | Inventive |
| 13 | 148 | 502 | Inventive |

As shown in Tables 3 and 4, the organic EL elements of the present invention were found to exhibit notably improved emission efficiency and notably improved emission life.

### Example 2

### Full Color Display

### (Organic EL Element Emitting Blue Light)

Organic EL Element 1-6B was used, which was prepared in the same manner as Organic EL Element 1-6 except that PD-7 used in Organic EL Element 1-6 was changed to PD-8.

### (Organic EL Element Emitting Green Light)

Organic EL Element 1-6 prepared in Example 1 was used.

### (Organic EL Element Emitting Red Light)

Organic EL Element 1-6R was used, which was prepared in the same manner as Organic EL Element 1-6 except that PD-7 used in Organic EL Element 1-6 was changed to PD-9. (Organic EL element emitting red light)

Organic EL element 2-1-5R was used, which was prepared in the same manner as organic EL element 2-1-5 except that Poly-19 used in organic EL element 2-1-5 was replaced with Poly-48.

The above described organic EL elements emitting red light, green light and blue light were arrayed side by side on the same substrate to fabricate a full color display device driven by an active matrix method, as shown in FIG. 1. In FIG. 2, only a schematic figure the display section A of thus prepared display device was illustrated. Namely, on the same substrate, a wiring section containing plural scanning lines 5 and plural data lines 6 and plural pixels 3 arrayed side by side were placed. The scanning lines 5 and data lines 6 of the wiring section each were composed of an electroconductive material, the lines 5 and the lines 6 being crossed with each other at a right angle, and connected with the pixels 3 at the crossed points (not illustrated). The plural pixels 3 were driven by an active matrix method in which each pixel contained an organic EL element emitting one of the colors, a switching transistor and a driving transistor both of which are active elements, and when the scanning signal is applied from the scanning lines 5, the data signal from the data lines 6 was received, and light corresponding to the image data was emitted. A full color display device was prepared by providing red light emitting pixels, green light emitting pixels, and blue light emitting pixels side by side on the same substrate.

By driving the above described full color display, it was confirmed that a display for a full color moving picture exhibiting a high emission efficiency and a long emission life was obtained.

### Example 3

### Example for Illuminating Device, Using White Light Organic EL Element

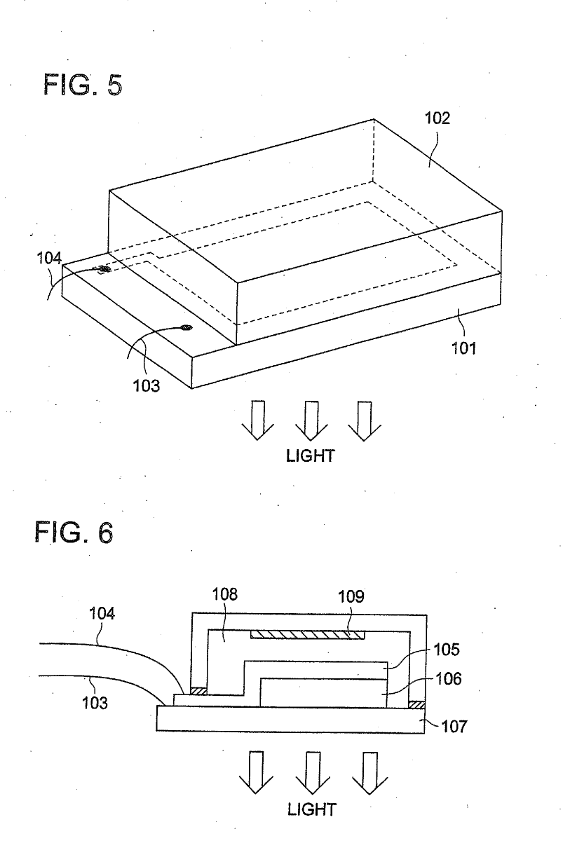

Organic EL Element 1-6W was used, which was prepared in the same manner as Organic EL Element 1-6 except that PD-7 used in Organic EL Element 1-6 was replaced with a mixture of PD-7, PD-8 and PD-9. The non-emitting surface of Organic EL Element 1-6W was covered with a glass case to form an illuminating device. The illuminating device served as a thin type illuminating device exhibiting a high emission efficiency and a long emission life. FIG. 5 is a schematic illustration of the illuminating device, and FIG. 6 illustrates a cross-section of the illuminating device. The Organic EL Element 101 was covered by the glass cover 102, and an electric wire 103 (for anode) and an electric wire 104 (for cathode) are connected. 105 represents the anode and 106 represents the organic EL layer. The inside of the glass cover 102 was filled with nitrogen gas 108 and a dehydrating agent 109 is provided.

### POSSIBILITY FOR INDUSTRIAL APPLICATION

According to the present invention, provided are a multi-branched structure compound which can be used as a material for an organic electroluminescent element exhibiting a high emission efficiency and a long emission life, the organic electroluminescent element being capable of easy production; an organic electroluminescent element employing the multi-branched structure compound; and a display or an illuminating device employing the organic electroluminescent element. Also provided is a method to produce the multi-branched structure compound.

What is claimed is:

1. A method to produce a multi-branched structure compound encapsulating an iridium phosphorescent compound comprising the following sequential steps:
(i) dissolving a multi-branched structure compound and an iridium phosphorescent compound in a first solvent;
(ii) adding a second solvent to encapsulate the iridium phosphorescent compound into the multi-branched structure compound; and
(iii) separating and purifying the multi-branched structure compound encapsulating the iridium phosphorescent compound,
wherein a core linkage group of the multi-branched structure compound is selected from the group consisting of

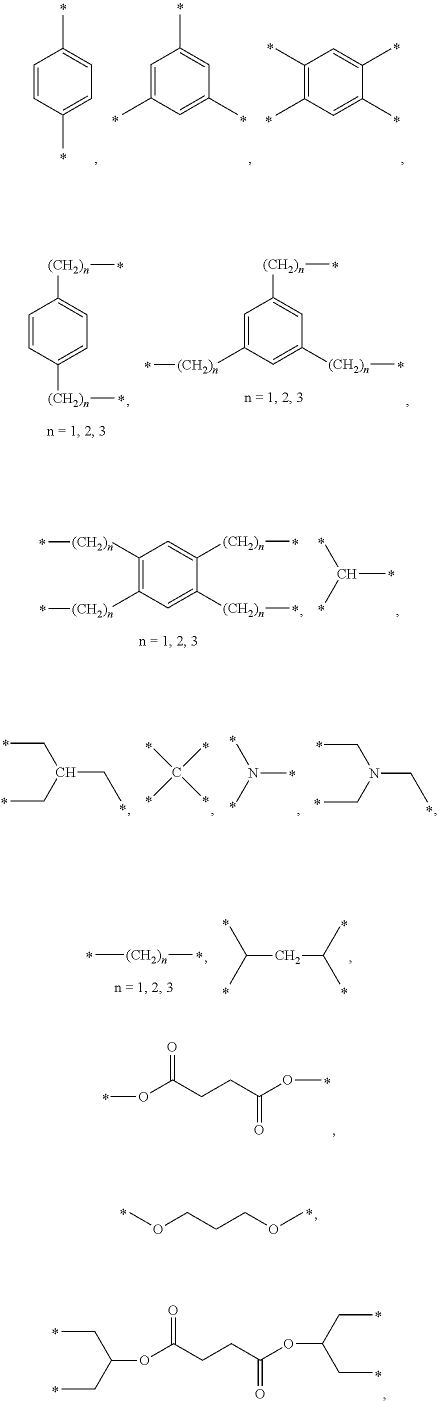

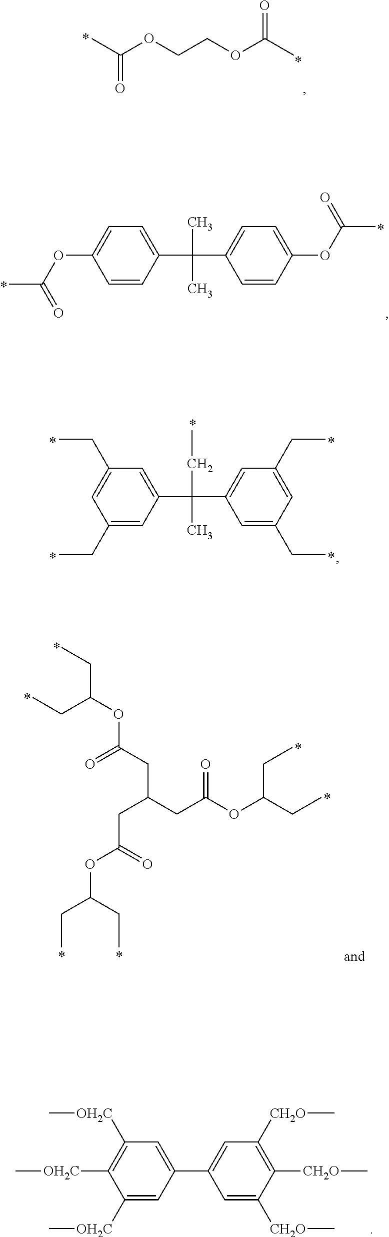

2. The method of claim 1, wherein the multi-branched structure compound has a substructure which exhibits a positive hole transporting property.

3. The method of claim 1, wherein the multi-branched structure compound has a substructure which exhibits an electron transporting property.
